(19) United States
(12) Patent Application Publication
(10) Pub. No.: US 2026/0152855 A1
(43) Pub. Date: Jun. 4, 2026

(54) DEPOSITION METHOD, DEPOSITION APPARATUS, AND ELECTRONIC DEVICE MANUFACTURED BY USING DEPOSITION APPARATUS

(71) Applicant: Samsung Display Co., LTD., Yongin-si (KR)

(72) Inventors: Duck Jung LEE, Yongin-si (KR); Jeong Kuk KIM, Yongin-si (KR); Jun Ho JO, Yongin-si (KR)

(21) Appl. No.: 19/281,698

(22) Filed: Jul. 27, 2025

(30) Foreign Application Priority Data
Dec. 2, 2024 (KR) 10-2024-0176104

(51) Int. Cl. C23C 16/52; C23C 16/04; G02B 27/01; H10K 71/10

(52) U.S. Cl. CPC C23C 16/52; C23C 16/042; H10K 71/10; G02B 27/0172; G02B 2027/0178

(57) ABSTRACT

A deposition method includes forming a capacitor between a substrate and a deposition mask, measuring a capacitance of the capacitor, aligning the substrate and the deposition mask with each other based on a measured capacitance of the capacitor, and providing a deposition material onto the substrate through the deposition mask to form a deposition material layer on the substrate.

This application claims priority to Korean Patent Application No. 10-2024-0176104, filed on Dec. 2, 2024, and all the benefits accruing therefrom under 35 U.S.C. § 119, the content of which in its entirety is herein incorporated by reference.

### BACKGROUND

### 1. Field

The disclosure relates to a deposition method, a deposition apparatus, and an electronic device manufactured by the deposition apparatus.

### 2. Description of the Related Art

Wearable devices in which a focus is formed at a distance close to user's eyes have been developed in the form of glasses or a helmet. For example, the wearable device may be a head mounted display (“HMD”) device or augmented reality (“AR”) glasses. The wearable device may provide an AR screen or a virtual reality (“VR”) screen to a user.

In the case of wearable devices such as the HMD device or the AR glasses, a display specification of approximately 3000 pixels per inch (PPI) or higher is desired to allow users to use them for a long time without symptoms of dizziness. To this end, organic light-emitting diode on silicon (“OLEDoS”) technology is emerging for use in a high-resolution relatively small organic light-emitting display device. The OLEDoS is a technology in which organic light-emitting diodes (“OLED”) are formed on a semiconductor substrate on which complementary metal oxide semiconductor (“CMOS”) elements are disposed.

In order to manufacture a display panel with a high resolution of about 3000 PPI or higher, a high-resolution deposition mask is desired. For example, the deposition mask may be manufactured by forming a membrane defining a plurality of pixel openings on a substrate such as a silicon wafer, and partially removing the substrate to define cell openings that expose the pixel openings.

In a deposition process for forming light-emitting layers of a display panel, a backplane substrate may be positioned on a deposition mask, and a vapor deposition material provided from a deposition source may be deposited on the backplane substrate through the pixel openings of the deposition mask. Substrate alignment keys may be disposed on the backplane substrate, and mask alignment keys may be disposed on the deposition mask. Positional information of/on the substrate alignment keys and the mask alignment keys may be acquired by high-resolution cameras and illumination devices, and the backplane substrate may be aligned on the deposition mask based on the positional information.

### SUMMARY

Advantages and features of embodiments of the disclosure provide a deposition method and a deposition apparatus capable of aligning a substrate and a deposition mask with each other without using a camera and an illumination device, and an electronic device manufactured by the deposition apparatus.

However, embodiments of the disclosure are not limited to those set forth herein. The above and other embodiments of the disclosure will become more apparent to one of ordinary skill in the art to which the disclosure pertains by referencing the detailed description of the disclosure given below.

In an embodiment of the disclosure, a deposition method may include forming a capacitor between a substrate and a deposition mask, measuring a capacitance of the capacitor, aligning the substrate and the deposition mask with each other based on the measured capacitance of the capacitor, and providing a deposition material onto the substrate through the deposition mask to form a deposition material layer on the substrate.

In an embodiment, the measuring the capacitance may include moving at least one of the substrate and the deposition mask, and measuring a change in the capacitance while moving the at least one of the substrate and the deposition mask.

In an embodiment, the moving the at least one of the substrate and the deposition mask may include rotating any one of the substrate and the deposition mask, and moving any one of the substrate and the deposition mask.

In an embodiment, a gap between the substrate and the deposition mask may be maintained constant while moving the at least one of the substrate and the deposition mask.

In an embodiment, the aligning the substrate and the deposition mask with each other may include moving at least one of the substrate and the deposition mask such that the capacitance becomes maximum.

In an embodiment, a deposition method may include preparing a substrate including at least one first measurement electrode, preparing a deposition mask including at least one second measurement electrode, placing the substrate on the deposition mask such that the at least one first measurement electrode and the at least one second measurement electrode face to each other, measuring a capacitance between the at least one first measurement electrode and the at least one second measurement electrode, aligning the substrate and the deposition mask with each other based on the measured capacitance, and providing a deposition material onto the substrate through the deposition mask to form a deposition material layer on the substrate.

In an embodiment, the measuring the capacitance may include rotating the substrate or the deposition mask, measuring a capacitance value between the at least one first measurement electrode and the at least one second measurement electrode while rotating the substrate or the deposition mask, moving the substrate or the deposition mask while maintaining a constant gap between the substrate and the deposition mask, and measuring a capacitance value between the at least one first measurement electrode and the at least one second measurement electrode while moving the substrate or the deposition mask.

In an embodiment, the aligning the substrate and the deposition mask with each other may include adjusting a position and an angle of the substrate or the deposition mask such that a capacitance value between the at least one first measurement electrode and the at least one second measurement electrode becomes maximum.

In an embodiment, the substrate may include a plurality of first measurement electrodes, and the deposition mask may include a plurality of second measurement electrodes. The substrate may be placed on the deposition mask such that the first measurement electrodes face the second measurement electrodes, respectively, and the first measurement electrodes and the second measurement electrodes may have the same shape.

In an embodiment, the measuring the capacitance may include rotating the substrate or the deposition mask, and measuring first capacitance values between the first measurement electrodes and the second measurement electrodes while rotating the substrate or the deposition mask. The aligning the substrate and the deposition mask with each other may include detecting an azimuth of the substrate or the deposition mask at which the first capacitance values between the first measurement electrodes and the second measurement electrodes become all equal, and adjusting an azimuth of the substrate or the deposition mask such that the substrate or the deposition mask has the detected azimuth.

In an embodiment, the measuring the capacitance may further include moving the substrate or the deposition mask while maintaining a constant gap between the substrate and the deposition mask, and measuring second capacitance values between the first measurement electrodes and the second measurement electrodes while moving the substrate or the deposition mask. The aligning the substrate and the deposition mask with each other may further include detecting a position of the substrate or the deposition mask at which the second capacitance values between the first measurement electrodes and the second measurement electrodes become all maximum, and moving the substrate or the deposition mask to the detected position.

In an embodiment, the measuring the capacitance may include moving the substrate or the deposition mask while maintaining a constant gap between the substrate and the deposition mask, and measuring first capacitance values between the first measurement electrodes and the second measurement electrodes while moving the substrate or the deposition mask. The aligning the substrate and the deposition mask with each other may include detecting a position of the substrate or the deposition mask at which the first capacitance values between the first measurement electrodes and the second measurement electrodes become all equal, and moving the substrate or the deposition mask to the detected position.

In an embodiment, the measuring the capacitance may further include rotating the substrate or the deposition mask, and measuring second capacitance values between the first measurement electrodes and the second measurement electrodes while rotating the substrate or the deposition mask. The aligning the substrate and the deposition mask with each other may further include detecting an azimuth of the substrate or the deposition mask at which the second capacitance values between the first measurement electrodes and the second measurement electrodes become all maximum, and adjusting an azimuth of the substrate or the deposition mask such that the substrate or the deposition mask has the detected azimuth.

In an embodiment, the substrate may include a plurality of first measurement electrodes and a plurality of third measurement electrodes, and the deposition mask may include a plurality of second measurement electrodes and a plurality of fourth measurement electrodes. The substrate may be placed on the deposition mask such that the first measurement electrodes face the second measurement electrodes, respectively, and the third measurement electrodes face the fourth measurement electrodes, respectively. The first measurement electrodes and the second measurement electrodes may extend in a first direction, and the third measurement electrodes and the fourth measurement electrodes may extend in a second direction perpendicular to the first direction.

In an embodiment, the measuring the capacitance may include rotating the substrate or the deposition mask, and measuring first capacitance values between the first measurement electrodes and the second measurement electrodes and second capacitance values between the third measurement electrodes and the fourth measurement electrodes while rotating the substrate or the deposition mask. The aligning the substrate and the deposition mask with each other may include detecting an azimuth of the substrate or the deposition mask at which the first capacitance values between the first measurement electrodes and the second measurement electrodes become equal to each other and the second capacitance values between the third measurement electrodes and the fourth measurement electrodes become equal to each other, and adjusting an azimuth of the substrate or the deposition mask such that the substrate or the deposition mask has the detected azimuth.

In an embodiment, the measuring the capacitance may further include moving the substrate or the deposition mask while maintaining a constant gap between the substrate and the deposition mask, and measuring third capacitance values between the first measurement electrodes and the second measurement electrodes and fourth capacitance values between the third measurement electrodes and the fourth measurement electrodes while moving the substrate or the deposition mask. The aligning the substrate and the deposition mask with each other may further include detecting a position of the substrate or the deposition mask at which the third capacitance values between the first measurement electrodes and the second measurement electrodes and the fourth capacitance values between the third measurement electrodes and the fourth measurement electrodes become all maximum and become all equal, and moving the substrate or the deposition mask to the detected position.

In an embodiment, the measuring the capacitance may include moving the substrate or the deposition mask while maintaining a constant gap between the substrate and the deposition mask, and measuring first capacitance values between the first measurement electrodes and the second measurement electrodes and second capacitance values between the third measurement electrodes and the fourth measurement electrodes while moving the substrate or the deposition mask. The aligning the substrate and the deposition mask with each other may include detecting a position of the substrate or the deposition mask at which the first capacitance values between the first measurement electrodes and the second measurement electrodes become equal to each other and the second capacitance values between the third measurement electrodes and the fourth measurement electrodes become equal to each other, and moving the substrate or the deposition mask to the detected position.

In an embodiment, the measuring the capacitance may further include rotating the substrate or the deposition mask, and measuring third capacitance values between the first measurement electrodes and the second measurement electrodes and fourth capacitance values between the third measurement electrodes and the fourth measurement electrodes while rotating the substrate or the deposition mask. The aligning the substrate and the deposition mask with each other may further include detecting an azimuth of the substrate or the deposition mask at which the third capacitance values between the first measurement electrodes and the second measurement electrodes and the fourth capacitance values between the third measurement electrodes and the fourth measurement electrodes become all maximum and become all equal, and adjusting an azimuth of the substrate or the deposition mask such that the substrate or the deposition mask has the detected azimuth.

In an embodiment, the substrate may include one first measurement electrode and at least one third measurement electrode, and the deposition mask may include one second measurement electrode and at least one fourth measurement electrode. The substrate may be placed on the deposition mask such that the first measurement electrode faces the second measurement electrode and the at least one third measurement electrode faces the at least one fourth measurement electrode. The first measurement electrode and the second measurement electrode may have the same circular ring shape, and the at least one third measurement electrode and the at least one fourth measurement electrode may have the same shape.

In an embodiment, the deposition method may further include adjusting a parallelism between the substrate and the deposition mask.

In an embodiment of the disclosure, a deposition apparatus may include a deposition source providing a deposition material, a substrate chuck disposed above the deposition source and supporting a substrate including at least one first measurement electrode, a mask chuck disposed between the deposition source and the substrate chuck and supporting a deposition mask including at least one second measurement electrode, a sensor measuring a capacitance between the at least one first measurement electrode and the at least one second measurement electrode, and a chuck driver aligning the substrate and the deposition mask with each other based on the capacitance measured by the sensor.

In an embodiment, the substrate may further include at least one first contact pad and at least one first connection line connecting the at least one first measurement electrode to the at least one first contact pad. The deposition mask may further include at least one second contact pad and at least one second connection line connecting the at least one second measurement electrode to the at least one second contact pad. The sensor may include at least one first probe pin connected to the at least one first contact pad and at least one second probe pin connected to the at least one second contact pad.

In an embodiment, the sensor may be disposed in the mask chuck, and the deposition mask may define a through-opening through which the at least one first probe pin passes.

In an embodiment, the deposition mask may include a mask substrate, and the at least one second measurement electrode, the at least one second contact pad and the at least one second connection line may be disposed on the mask substrate. The mask substrate may define a contact opening exposing the at least one second contact pad, and the at least one second probe pin may contact the at least one second contact pad through the contact opening.

In an embodiment, the chuck driver may move the substrate chuck or the mask chuck such that a capacitance between the at least one first measurement electrode and the at least one second measurement electrode becomes maximum to align the substrate and the deposition mask with each other.

In an embodiment, the substrate may include a plurality of first measurement electrodes, the deposition mask may include a plurality of second measurement electrodes, and the first measurement electrodes and the second measurement electrodes may have the same shape.

In an embodiment, the chuck driver may rotate or horizontally move the substrate chuck or the mask chuck such that capacitance values between the first measurement electrodes and the second measurement electrodes become all equal.

In an embodiment, the chuck driver may horizontally move or rotate the substrate chuck or the mask chuck such that capacitance values between the first measurement electrodes and the second measurement electrodes become all maximum.

In an embodiment, the substrate may include a plurality of first measurement electrodes and a plurality of third measurement electrodes, and the deposition mask may include a plurality of second measurement electrodes and a plurality of fourth measurement electrodes. The first measurement electrodes and the second measurement electrodes may extend in a first direction, and the third measurement electrodes and the fourth measurement electrodes may extend in a second direction perpendicular to the first direction.

In an embodiment, the chuck driver may rotate or horizontally move the substrate chuck or the mask chuck such that capacitance values between the first measurement electrodes and the second measurement electrodes become equal to each other and capacitance values between the third measurement electrodes and the fourth measurement electrodes become equal to each other.

In an embodiment, the chuck driver may horizontally move or rotate the substrate chuck or the mask chuck such that capacitance values between the first measurement electrodes and the second measurement electrodes and capacitance values between the third measurement electrodes and the fourth measurement electrodes become all maximum and become all equal.

In an embodiment, the substrate may include one first measurement electrode and at least one third measurement electrode, and the deposition mask may include one second measurement electrode and at least one fourth measurement electrode. The first measurement electrode and the second measurement electrode may have the same circular ring shape, and the at least one third measurement electrode and the at least one fourth measurement electrode may have the same shape.

In an embodiment, the chuck driver may horizontally move the substrate chuck or the mask chuck such that a capacitance value between the first measurement electrode and the second measurement electrode becomes maximum.

In an embodiment, the chuck driver may rotate the substrate chuck or the mask chuck such that a capacitance value between the at least one third measurement electrode and the at least one fourth measurement electrode becomes maximum.

In an embodiment, the deposition apparatus may further include gap sensors for measuring a gap between the substrate chuck and the mask chuck, and the chuck driver may adjust an inclination of the substrate chuck based on measurement values of the gap sensors.

In an embodiment of the disclosure, an electronic device may include a display panel. The display panel may include a substrate and light-emitting layers formed on the substrate by a deposition apparatus, and the substrate may include at least one first measurement electrode. The deposition apparatus may include a deposition source providing a deposition material, a substrate chuck disposed above the deposition source and supporting the substrate, a mask chuck disposed between the deposition source and the substrate chuck and supporting a deposition mask including at least one second measurement electrode, a sensor measuring a capacitance between the at least one first measurement electrode and the at least one second measurement electrode, and a chuck driver aligning the substrate and the deposition mask with each other based on the capacitance measured by the sensor.

In an embodiment of the disclosure, the electronic device may further include at least one of a processor, a memory, and a power module.

By the embodiments, the alignment between the substrate and the deposition mask may be performed based on the capacitance between the substrate and the deposition mask. As a result, the high-resolution cameras and the illumination devices used for detection of general alignment keys may be eliminated, thereby considerably reducing the manufacturing cost of a display panel, a display device, an electronic device, or the like.

Other features and embodiments may be apparent from the following detailed description and the drawings.

### BRIEF DESCRIPTION OF THE DRAWINGS

The above and other advantages and features of the disclosure will become more apparent by describing in detail embodiments thereof with reference to the attached drawings, in which:

FIG. 1 is a block diagram of an embodiment of an electronic device according to the disclosure;

FIG. 2 is a schematic diagram of embodiments of an electronic device according to the disclosure;

FIG. 3 is an exploded perspective view illustrating an embodiment of a display device according to the disclosure;

FIG. 4 is a block diagram illustrating the display device shown in FIG. 3;

FIG. 5 is an equivalent circuit diagram illustrating an embodiment of a first sub-pixel shown in FIG. 4;

FIG. 6 is a schematic plan view illustrating an embodiment of a display panel shown in FIG. 3;

FIG. 7 is a schematic enlarged plan view illustrating an embodiment of a display area shown in FIG. 6;

FIG. 8 is a schematic enlarged plan view illustrating another embodiment of the display area shown in FIG. 6;

FIG. 9 is a schematic cross-sectional view illustrating an embodiment of the display panel taken along line I1-I1′ shown in FIG. 7;

FIG. 10 is a schematic cross-sectional view illustrating another embodiment of the display panel taken along line I1-I1′ shown in FIG. 7;

FIG. 11 is a schematic perspective view illustrating an embodiment of a head mounted display;

FIG. 12 is a schematic exploded perspective view illustrating the head mounted display shown in FIG. 11;

FIG. 13 is a schematic perspective view illustrating another embodiment of the head mounted display;

FIG. 14 is a schematic diagram illustrating an embodiment of a deposition apparatus according to the disclosure;

FIG. 15 is a schematic bottom view illustrating a backplane substrate shown in FIG. 14;

FIG. 16 is a schematic plan view illustrating a deposition mask shown in FIG. 14;

FIG. 17 is a schematic enlarged plan view illustrating mask cell regions shown in FIG. 16;

FIG. 18 is a schematic cross-sectional view taken along line I2-I2′ shown in FIG. 17;

FIG. 19 is a schematic cross-sectional view illustrating a substrate chuck and a mask chuck shown in FIG. 14;

FIG. 20 is a schematic plan view illustrating the mask chuck shown in FIG. 19;

FIG. 21 is a schematic enlarged cross-sectional view illustrating a sensor shown in FIGS. 19 and 20;

FIG. 22 is a schematic enlarged cross-sectional view illustrating a through-opening shown in FIG. 21;

FIG. 23 is a schematic enlarged cross-sectional view illustrating a contact opening shown in FIG. 21;

FIGS. 24 and 25 are schematic diagrams illustrating states in which first measurement electrodes and second measurement electrodes illustrated in FIGS. 15 and 16 face each other;

FIGS. 26 to 29 are schematic plan views illustrating a method of aligning a backplane substrate and a deposition mask with each other using the first measurement electrodes and the second measurement electrodes illustrated in FIGS. 15 and 16;

FIG. 30 is a schematic bottom view illustrating another embodiment of the backplane substrate illustrated in FIG. 15;

FIG. 31 is a schematic plan view illustrating another embodiment of the deposition mask shown in FIG. 16;

FIG. 32 is a schematic plan view illustrating another embodiment of the sensor shown in FIG. 20;

FIGS. 33 to 36 are schematic plan views illustrating a method of aligning a backplane substrate and a deposition mask with each other using the first, second, third, and fourth measurement electrodes illustrated in FIGS. 30 and 31;

FIG. 37 is a schematic bottom view illustrating another embodiment of the backplane substrate illustrated in FIG. 15;

FIG. 38 is a schematic plan view illustrating another embodiment of the deposition mask shown in FIG. 16; and

FIG. 39 is a flowchart illustrating an embodiment of a deposition method according to the disclosure.

### DETAILED DESCRIPTION

The disclosure will now be described more fully hereinafter with reference to the accompanying drawings, in which various embodiments of the disclosure are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

It will also be understood that when an element or a layer is referred to as being “on” another element or layer, it may be directly on the other element or layer, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Drawing figures. It will be understood that relative terms are intended to encompass different orientations of the device in addition to the orientation depicted in the Drawing figures. For example, if the device in one of the drawing figures is turned over, elements described as being on the “lower” side of other elements would then be oriented on “upper” sides of the other elements. The term “lower,” may therefore, encompasses both an orientation of “lower” and “upper,” depending on the particular orientation of the figure. Similarly, if the device in one of the drawing figures is turned over, elements described as “below” or “beneath” other elements would then be oriented “above” the other elements. The terms “below” or “beneath” can, therefore, encompass both an orientation of above and below.

Features of each of various embodiments of the disclosure may be partially or entirely combined with each other and may technically variously interwork with each other, and respective embodiments may be implemented independently of each other or may be implemented together in association with each other.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the drawing figures are schematic in nature and their shapes are not intended to illustrate the precise shape of a region and are not intended to limit the scope of the claims.

Hereinafter, embodiments will be described in detail with reference to the accompanying drawings.

The display device in an embodiment of the disclosure may be applied to various electronic devices. The electronic device according to the an embodiment of the disclosure includes the display device described above, and may further include modules or devices having additional functions in addition to the display device.

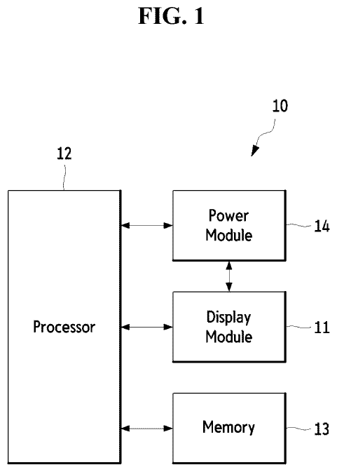

FIG. 1 is a block diagram of an embodiment of an electronic device according to the disclosure.

Referring to FIG. 1, the electronic device 10 in an embodiment of the disclosure may include a display module 11, a processor 12, a memory 13, and a power module 14.

The processor 12 may include at least one of a central processing unit (“CPU”), an application processor (“AP”), a graphic processing unit (“GPU”), a communication processor (“CP”), an image signal processor (“ISP”), and a controller.

The memory 13 may store data information desired for the operation of the processor 12 or the display module 11. When the processor 12 executes an application stored in the memory 13, an image data signal and/or an input control signal is transmitted to the display module 11, and the display module 11 may process the received signal and output image information through a display screen.

The power module 14 may include a power supply module such as, for example a power adapter or a battery, and a power conversion module that converts the power supplied by the power supply module to generate power desired for the operation of the electronic device 10.

At least one of the components of the electronic device 10 according to the an embodiment of the disclosure may be included in the display device 20 in the embodiments of the disclosure. In addition, some modules of the individual modules functionally included in one module may be included in the display device 20, and other modules may be provided separately from the display device 10. In an embodiment, the display device 20 may include the display module 11, and the processor 12, the memory 13, and the power module 14 may be provided in the form of other devices within the electronic device 10 other than the display device 20, for example.

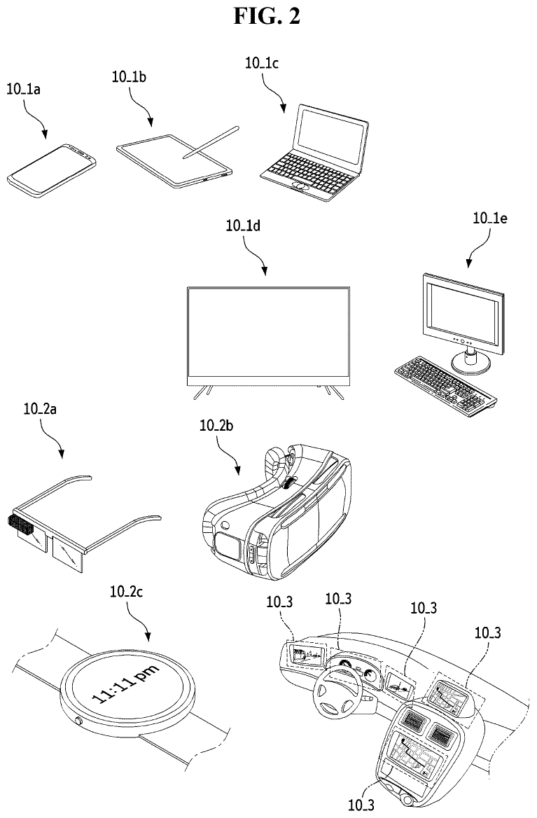

FIG. 2 is a schematic diagram of embodiments of an electronic device according to the disclosure.

Referring to FIG. 2, various electronic devices to which display devices 20 in embodiments of the disclosure are applied may include not only image display electronic devices such as a smart phone 10_1a, a tablet personal computer (“PC”) 10_1b, a laptop 10_1c, a television (“TV”) 10_1d, and a desk monitor 10_1e, but also wearable electronic devices including display modules such as, for example smart glasses 10_2a, a head mounted display 10_2b, and a smart watch 10_2c, and vehicle electronic devices 10_3 including display modules such as a Center Information Display (“CID”) and a room mirror display arranged on a dashboard, center fascia, and dashboard of an automobile.

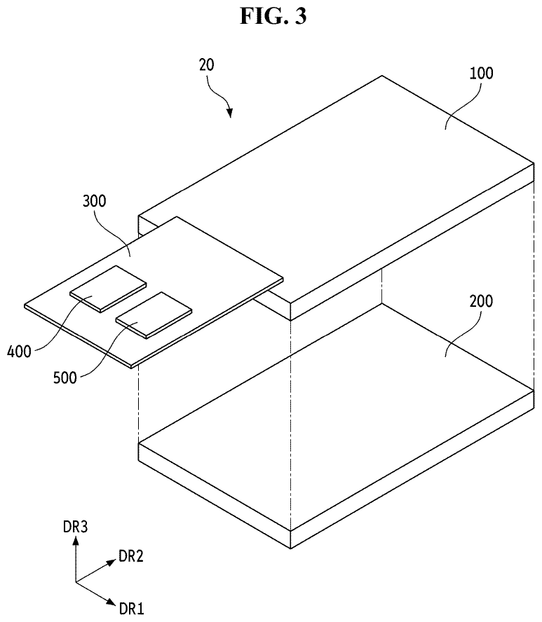

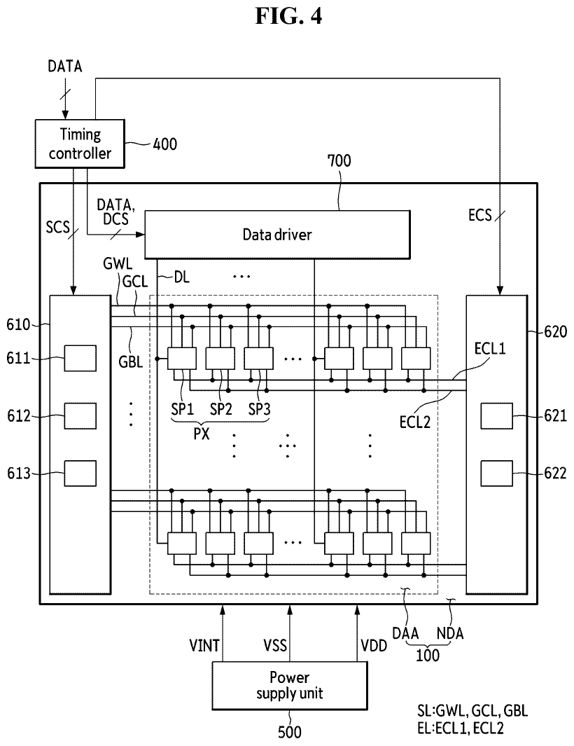

FIG. 3 is an exploded perspective view illustrating a display device according to the disclosure. FIG. 4 is a block diagram illustrating the display device shown in FIG. 3.

Referring to FIGS. 3 and 4, a display device 20 in an embodiment may be a device displaying a moving image or a still image. A display device 20 in an embodiment may be used as the electronic device 10 (refer to FIG. 1) or the display module 11 of the electronic device 10. In an embodiment, the display device 20 in an embodiment may be applied to portable electronic devices 10 such as a mobile phone, a smartphone, a tablet personal computer, a mobile communication terminal, an electronic organizer, an electronic book, a portable multimedia player (“PMP”), a navigation system, an ultra mobile PC (“UMPC”), or the like, for example. The display device 20 in an embodiment may be applied as a display module 11 of electronic devices 10 such as a television, a laptop, a monitor, a billboard, or an Internet-of-Things (“IoT”) terminal, or the like. The display device 20 in an embodiment may be applied to electronic devices 10 such as a smart watch, a watch phone, a head mounted display (“HMD”) for implementing virtual reality and augmented reality, or the like.

The display device 20 in an embodiment may include a display panel 100, a heat dissipation layer 200, a circuit board 300, a timing control circuit 400, and a power supply circuit 500.

The display panel 100 may have a planar shape similar to a quadrilateral shape. In an embodiment, the display panel 100 may have a planar shape similar to a quadrilateral shape, having a short side of a first direction DR1 and a long side of a second direction DR2 intersecting the first direction DR1, for example. In the display panel 100, a corner where a short side in the first direction DR1 and a long side in the second direction DR2 meet may be right-angled or rounded with a predetermined curvature. The planar shape of the display panel 100 is not limited to a quadrilateral shape, and may be a shape similar to another polygonal shape, a circular shape, or an elliptical shape. The planar shape of the display device 20 may conform to the planar shape of the display panel 100, but the disclosure is not limited thereto.

The display panel 100 may include a plurality of pixels PX, a plurality of scan lines SL, a plurality of emission control lines EL, a plurality of data lines DL, a scan driver 610, an emission driver 620, and a data driver 700. The display panel 100 may be divided into a display area DAA displaying an image and a non-display area NDA not displaying an image as shown in FIG. 4.

The plurality of pixels PX may be disposed in the display area DAA. The plurality of pixels PX may be arranged in a matrix form along the first direction DR1 and the second direction DR2. The plurality of scan lines SL and the plurality of emission control lines EL may extend in the first direction DR1, while being arranged in the second direction DR2. The plurality of data lines DL may extend in the second direction DR2, while being arranged in the first direction DR1.

The plurality of scan lines SL may include a plurality of write scan lines GWL, a plurality of control scan lines GCL, and a plurality of bias scan lines GBL. The plurality of emission control lines EL include a plurality of first emission control lines ECL1 and a plurality of second emission control lines ECL2.

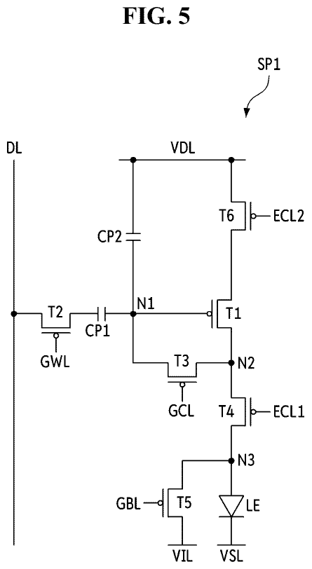

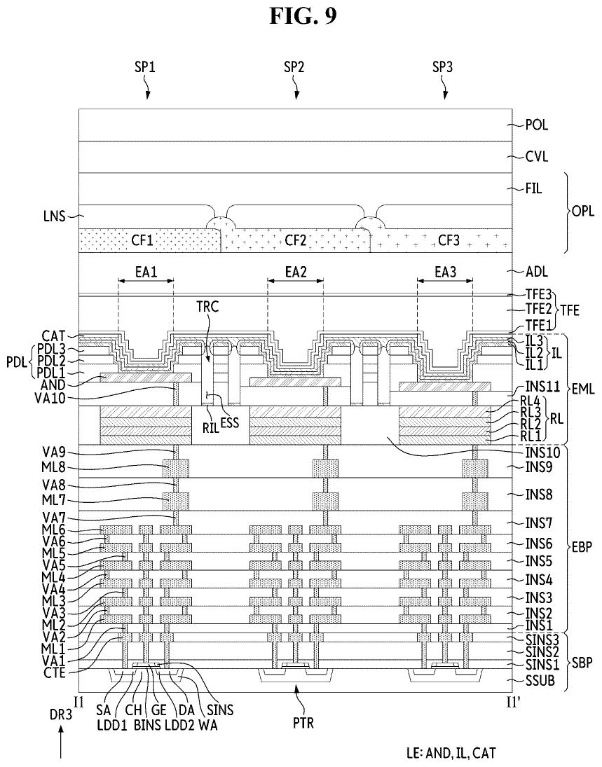

The plurality of pixels PX may include a plurality of sub-pixels SP1, SP2, and SP3. The plurality of sub-pixels SP1, SP2, and SP3 may include a plurality of pixel transistors as shown in FIG. 5, and the plurality of pixel transistors may be formed by a semiconductor process and disposed on a semiconductor substrate SSUB (refer to FIG. 9). In an embodiment, the plurality of pixel transistors of the data driver 700 may include or consist of complementary metal oxide semiconductor (“CMOS”), for example, but the disclosure is not limited thereto.

Each of the plurality of sub-pixels SP1, SP2, and SP3 may be connected to one write scan line GWL, one control scan line GCL, one bias scan line GBL, one first emission control line ECL1, one second emission control line ECL2, and one data line DL. Each of the plurality of sub-pixels SP1, SP2, and SP3 may receive a data voltage of the data line DL in response to a write scan signal of the write scan line GWL, and emit light from the light-emitting element according to the data voltage.

The scan driver 610, the emission driver 620, and the data driver 700 may be disposed in the non-display area NDA.

The scan driver 610 includes a plurality of scan transistors, and the emission driver 620 includes a plurality of light-emitting transistors. The plurality of scan transistors and the plurality of light-emitting transistors may be formed on the semiconductor substrate SSUB (refer to FIG. 9) through a semiconductor process. In an embodiment, the plurality of scan transistors and the plurality of light-emitting transistors may include or consist of CMOS, for example, but the disclosure is not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and output them sequentially to the write scan lines GWL. The control scan signal output unit 612 may generate control scan signals in response to the scan timing control signal SCS and sequentially output them to the control scan lines GCL. The bias scan signal output unit 613 may generate bias scan signals according to the scan timing control signal SCS and output them sequentially to the bias scan lines GBL.

The emission driver 620 includes a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output them to the first emission control lines ECL1. The second emission control driver 622 may generate second emission control signals according to the emission timing control signal ECS and sequentially output them to the second emission control lines ECL2.

The data driver 700 may include a plurality of data transistors, and the plurality of data transistors may be formed on the semiconductor substrate SSUB (refer to FIG. 9) through a semiconductor process. In an embodiment, the plurality of data transistors may include or consist of CMOS, for example, but the disclosure is not limited thereto.

The data driver 700 may receive digital video data DATA and a data timing control signal DCS from the timing control circuit 400. The data driver 700 converts the digital video data DATA into analog data voltages according to the data timing control signal DCS and outputs the analog data voltages to the data lines DL. In this case, the sub-pixels SP1, SP2, and SP3 may be selected by the write scan signal of the scan driver 610, and data voltages may be supplied to the selected sub-pixels SP1, SP2, and SP3.

The heat dissipation layer 200 may overlap the display panel 100 in a third direction DR3, which is a thickness direction of the display panel 100. The heat dissipation layer 200 may be disposed on one surface of the display panel 100, e.g., on the rear surface thereof. The heat dissipation layer 200 serves to dissipate heat generated from the display panel 100. The heat dissipation layer 200 may include a metal layer having relatively high thermal conductivity, such as graphite, silver (Ag), copper (Cu), or aluminum (Al).

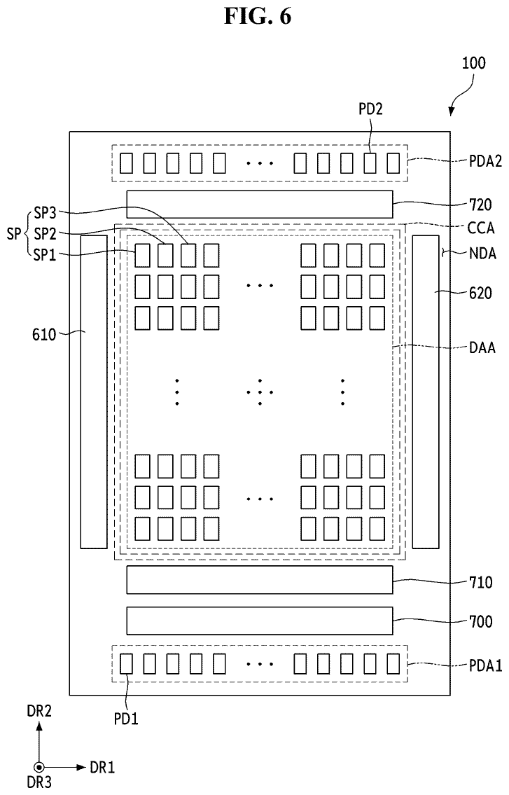

The circuit board 300 may be electrically connected to a plurality of first pads PD1 (refer to FIG. 6) of a first pad portion PDA1 (refer to FIG. 6) of the display panel 100 by a conductive adhesive member such as an anisotropic conductive film. The circuit board 300 may be a flexible printed circuit board with a flexible material, or a flexible film. Although the circuit board 300 is illustrated in FIG. 3 as being unfolded, the circuit board 300 may be bent. In this case, one end of the circuit board 300 may be disposed on the rear surface of the display panel 100 and/or the rear surface of the heat dissipation layer 200. An opposite end of the circuit board 300 may be connected to the plurality of first pads PD1 (refer to FIG. 6) of the first pad portion PDA1 (refer to FIG. 6) of the display panel 100 by a conductive adhesive member. One end of the circuit board 300 may be an opposite end of an opposite end of the circuit board 300.

The timing control circuit 400 may receive digital video data and timing signals inputted from the outside. The timing control circuit 400 may generate the scan timing control signal SCS, the emission timing control signal ECS, and the data timing control signal DCS for controlling the display panel 100 in response to the timing signals. The timing control circuit 400 may output the scan timing control signal SCS to the scan driver 610, and output the emission timing control signal ECS to the emission driver 620. The timing control circuit 400 may output the digital video data and the data timing control signal DCS to the data driver 700.

The power supply circuit 500 may generate a plurality of panel driving voltages according to a power voltage from the outside. In an embodiment, the power supply circuit 500 may generate a first driving voltage VSS, a second driving voltage VDD, and a third driving voltage VINT and supply them to the display panel 100, for example. The first driving voltage VSS, the second driving voltage VDD, and the third driving voltage VINT will be described later in conjunction with FIG. 5.

Each of the timing control circuit 400 and the power supply circuit 500 may be formed as an integrated circuit (“IC”) and attached to one surface of the circuit board 300. In this case, the scan timing control signal SCS, the emission timing control signal ECS, the digital video data DATA, and the data timing control signal DCS of the timing control circuit 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

In an alternative embodiment, each of the timing control circuit 400 and the power supply circuit 500 may be disposed in the non-display area NDA of the display panel 100, similarly to the scan driver 610, the emission driver 620, and the data driver 700. In this case, the timing control circuit 400 may include a plurality of timing transistors, and each power supply circuit 500 may include a plurality of power transistors. The plurality of timing transistors and the plurality of power transistors may be formed on the semiconductor substrate SSUB (refer to FIG. 9) through a semiconductor process. In an embodiment, the plurality of timing transistors and the plurality of power transistors may include or consist of CMOS, for example, but the disclosure is not limited thereto. Each of the timing control circuit 400 and the power supply circuit 500 may be disposed between the data driver 700 and the first pad portion PDA1 (refer to FIG. 6).

FIG. 5 is an equivalent circuit diagram illustrating an embodiment of a first sub-pixel shown in FIG. 4.

Referring to FIG. 5, the first sub-pixel SP1 may be connected to the write scan line GWL, the control scan line GCL, the bias scan line GBL, the first emission control line ECL1, the second emission control line ECL2, and the data line DL. Further, the first sub-pixel SP1 may be connected to a first driving voltage line VSL to which the first driving voltage VSS corresponding to a relatively low potential voltage is applied, a second driving voltage line VDL to which the second driving voltage VDD corresponding to a relatively high potential voltage is applied, and a third driving voltage line VIL to which the third driving voltage VINT corresponding to an initialization voltage is applied.

The first sub-pixel SP1 may include a plurality of transistors T1 to T6, a light-emitting element LE, a first capacitor CP1, and a second capacitor CP2.

The light-emitting element LE emits light in response to a driving current flowing through the channel of the first transistor T1. The emission amount of the light-emitting element LE may be proportional to the driving current. The first electrode of the light-emitting element LE may be an anode electrode, and the second electrode of the light-emitting element LE may be a cathode electrode. The light-emitting element LE may be an organic light-emitting diode including a first electrode, a second electrode, and an organic light-emitting layer disposed between the first electrode and the second electrode, but the disclosure is not limited thereto. In an embodiment, the light-emitting element LE may be an inorganic light-emitting element including a first electrode, a second electrode, and an inorganic semiconductor disposed between the first electrode and the second electrode, in which case the light-emitting element LE may be a micro light-emitting diode, for example.

The first transistor T1 may be a driving transistor that controls a source-drain current (hereinafter referred to as “driving current”) flowing between the source electrode and the drain electrode thereof according to a voltage applied to the gate electrode thereof.

A second transistor T2 may be disposed between one electrode of the first capacitor CP1 and the data line DL. The second transistor T2 is turned on by the write scan signal of the write scan line GWL to connect the one electrode of the first capacitor CP1 to the data line DL. Accordingly, the data voltage of the data line DL may be applied to the one electrode of the first capacitor CP1.

A third transistor T3 may be disposed between the first node N1 and the second node N2. The third transistor T3 is turned on by the control scan signal of the control scan line GCL to connect the first node N1 to the second node N2. For this reason, when the gate electrode and the source electrode of the first transistor T1 are connected, the first transistor T1 may operate like a diode.

The fourth transistor T4 may be connected between the second node N2 and a third node N3. The fourth transistor T4 is turned on by the first emission control signal of the first emission control line ECL1 to connect the second node N2 to the third node N3. Accordingly, the driving current of the first transistor T1 may be supplied to the light-emitting element LE. A fifth transistor T5 may be disposed between the third node N3 and the third driving voltage line VIL. The fifth transistor T5 is turned on by the bias scan signal of the bias scan line GBL to connect the third node N3 to the third driving voltage line VIL. Accordingly, the third driving voltage VINT of the third driving voltage line VIL may be applied to the first electrode of the light-emitting element LE.

The sixth transistor T6 may be disposed between the source electrode of the first transistor T1 and the second driving voltage line VDL. The sixth transistor T6 is turned on by the second emission control signal of the second emission control line ECL2 to connect the source electrode of the first transistor T1 to the second driving voltage line VDL. Accordingly, the second driving voltage VDD of the second driving voltage line VDL may be applied to the source electrode of the first transistor T1.

The first capacitor CP1 is formed between the first node N1 and the drain electrode of the second transistor T2. The second capacitor CP2 is formed between the gate electrode of the first transistor T1 and the second driving voltage line VDL.

Each of the first to sixth transistors T1 to T6 may be a metal-oxide-semiconductor field effect transistor (“MOSFET”). In an embodiment, each of the first to sixth transistors T1 to T6 may be a P-type MOSFET, for example, but the disclosure is not limited thereto. Each of the first to sixth transistors T1 to T6 may be an N-type MOSFET. In an alternative embodiment, some of the first to sixth transistors T1 to T6 may be P-type MOSFETs, and each of the remaining transistors may be an N-type MOSFET.

Although it is illustrated in FIG. 5 that the first sub-pixel SP1 includes six transistors T1 to T6 and two capacitors CP1 and CP2, it should be noted that the equivalent circuit diagram of the first sub-pixel SP1 is not limited to that shown in FIG. 5. In an embodiment, the number of transistors and the number of capacitors of the first sub-pixel SP1 are not limited to those shown in FIG. 5, for example.

Further, the equivalent circuit diagram of the second sub-pixel SP2 and the equivalent circuit diagram of the third sub-pixel SP3 may be substantially the same as the equivalent circuit diagram of the first sub-pixel SP1 described in conjunction with FIG. 5. Therefore, the description of the equivalent circuit diagram of the second sub-pixel SP2 and the equivalent circuit diagram of the third sub-pixel SP3 is not repeated in the disclosure.

FIG. 6 is a schematic plan view illustrating an embodiment of a display panel shown in FIG. 3.

Referring to FIG. 6, the display area DAA of the display panel 100 in an embodiment includes the plurality of pixels PX arranged in a matrix form. The non-display area NDA of the display panel 100 in an embodiment includes the scan driver 610, the emission driver 620, the data driver 700, a first distribution circuit 710, a second distribution circuit 720, the first pad portion PDA1, and a second pad portion PDA2.

The scan driver 610 may be disposed on the first side of the display area DAA, and the emission driver 620 may be disposed on the second side of the display area DAA. In an embodiment, the scan driver 610 may be disposed on one side of the display area DAA in the first direction DR1, and the emission driver 620 may be disposed on an opposite side of the display area DAA in the first direction DR1, for example. However, the disclosure is not limited thereto, and the scan driver 610 and the emission driver 620 may be disposed on both the first side and the second side of the display area DAA.

The first pad portion PDA1 may include the plurality of first pads PD1 connected to pads or bumps of the circuit board 300 through a conductive adhesive member. The first pad portion PDA1 may be disposed on the third side of the display area DAA. In an embodiment, the first pad portion PDA1 may be disposed on one side of the display area DAA in the second direction DR2, for example. The first pad portion PDA1 may be disposed outside the data driver 700 in the second direction DR2.

The second pad portion PDA2 may include a plurality of second pads PD2 corresponding to inspection pads that test whether the display panel 100 operates normally. The plurality of second pads PD2 may be connected to a jig or a probe pin during an inspection process, or may be connected to a circuit board for inspection. The circuit board for inspection may be a printed circuit board including or consisting of a rigid material or a flexible printed circuit board including or consisting of a flexible material.

The second pad portion PDA2 may be disposed on the fourth side of the display area DAA. In an embodiment, the second pad portion PDA2 may be disposed on an opposite side of the display area DAA in the second direction DR2, for example. The second pad portion PDA2 may be disposed outside the second distribution circuit 720 in the second direction DR2.

The first distribution circuit 710 distributes data voltages applied through the first pad portion PDA1 to the plurality of data lines DL. In an embodiment, the first distribution circuit 710 may distribute the data voltages applied through one first pad PD1 of the first pad portion PDA1 to the P (P is a positive integer of 2 or more) data lines DL, and as a result, the number of the plurality of first pads PD1 may be reduced, for example. The first distribution circuit 710 may be disposed on the third side of the display area DAA of the display panel 100. In an embodiment, the first distribution circuit 710 may be disposed on one side of the display area DAA in the second direction DR2, for example.

The second distribution circuit 720 distributes signals applied through the second pad portion PDA2 to the scan driver 610, the emission driver 620, and the data lines DL. The second pad portion PDA2 and the second distribution circuit 720 may inspect the operation of each of the pixels PX in the display area DAA. The second distribution circuit 720 may be disposed on the fourth side of the display area DAA of the display panel 100. In an embodiment, the second distribution circuit 720 may be disposed on an opposite side of the display area DAA in the second direction DR2, for example.

A cathode connection part CCA may be a region where a second electrode CAT (refer to FIG. 9) of a display element layer EML (refer to FIG. 9) is connected to the first driving voltage line VSL of the non-display area NDA. The cathode connection part CCA may be disposed outside at least one side of the display area DAA. In an embodiment, the cathode connection part CCA may be disposed outside at least on one side among the left side, the right side, the upper side, and the lower side of the display area DAA, for example. In an alternative embodiment, the cathode connection part CCA may be disposed to surround the display area DAA as shown in FIG. 6 in order to minimize a deviation in the first driving voltage VSS caused by voltage drop (IR drop) or voltage rise (IR rising) of the second electrode CAT in the display area DAA, for example.

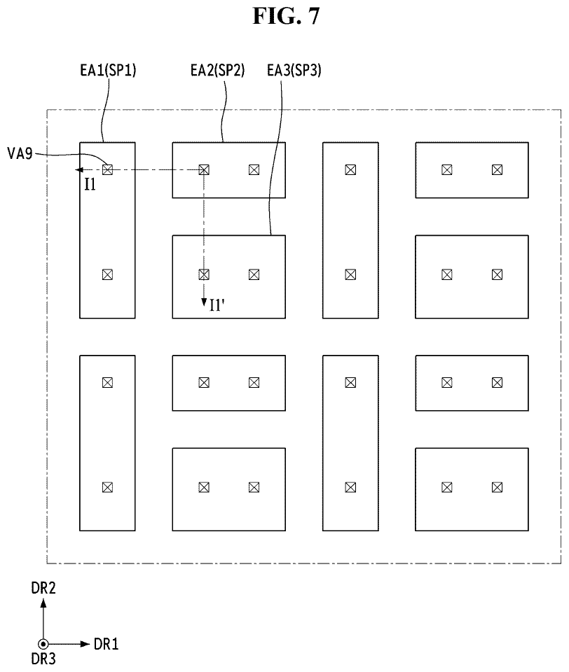

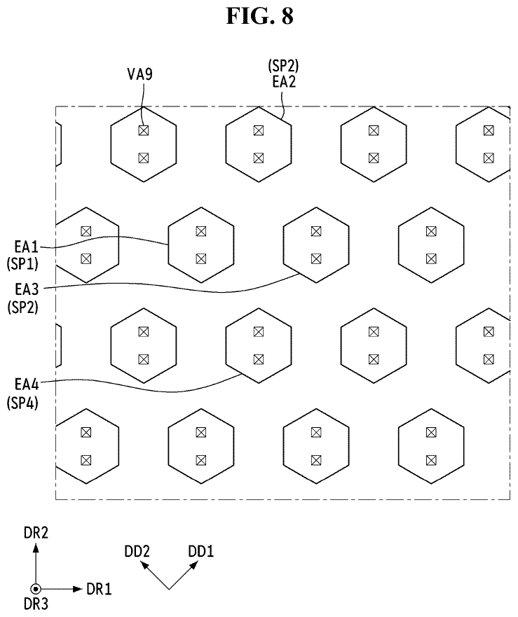

FIG. 7 is a schematic enlarged plan view illustrating an embodiment of a display area shown in FIG. 6. FIG. 8 is a schematic enlarged plan view illustrating another embodiment of the display area shown in FIG. 6.

Referring to FIGS. 7 and 8, each of the pixels PX includes the first emission area EA1 that is an emission area of the first sub-pixel SP1, the second emission area EA2 that is an emission area of the second sub-pixel SP2, and the third emission area EA3 that is an emission area of the third sub-pixel SP3.

The first emission area EA1, the second emission area EA2, and the third emission area EA3 may have, in a plan view, a quadrilateral or hexagonal shape as shown in FIGS. 7 and 8, but the disclosure is not limited thereto. The first emission area EA1, the second emission area EA2, and the third emission area EA3 may have a polygonal shape other than a quadrangle or hexagon, a circular shape, an elliptical shape, or an atypical shape in a plan view.

As shown in FIG. 7, in each of the plurality of pixels PX, the first emission area EA1 and the second emission area EA2 may be next (adjacent) to each other in the first direction DR1. Further, the first emission area EA1 and the third emission area EA3 may be next (adjacent) to each other in the first direction DR1. In addition, the second emission area EA2 and the third emission area EA3 may be next (adjacent) to each other in the second direction DR2. The area of the first emission area EA1, the area of the second emission area EA2, and the area of the third emission area EA3 may be different.

In an alternative embodiment, as shown in FIG. 8, the emission areas EA1, EA2, EA3, and EA4 may have a hexagonal shape in a plan view. In this case, the first emission area EA1 and the third emission area EA3 may be next (adjacent) to each other in the first direction DR1, and the second emission area EA2 and the fourth emission area EA4 may be next (adjacent) to each other in the second direction DR2. Additionally, the first emission area EA1 and the second emission area EA2 may be next (adjacent) to each other in a first diagonal direction DD1, and the second emission area EA2 and the third emission area EA3 may be next (adjacent) to each other in a second diagonal direction DD2. Additionally, the first emission area EA1 and the fourth emission area EA4 may be next (adjacent) to each other in the second diagonal direction DD2, and the third emission area EA3 and the fourth emission area EA4 may be next (adjacent) to each other in the first diagonal direction DD1. The first diagonal direction DD1 may be a direction between the first direction DR1 and the second direction DR2, and may refer to a direction inclined by 45 degrees with respect to the first direction DR1 and the second direction DR2, and the second diagonal direction DD2 may be a direction perpendicular to the first diagonal direction DD1.

The first sub-pixel SP1 may emit first light, the second sub-pixel SP2 may emit second light, and the third sub-pixel SP3 may emit third light. Here, the first light may be light of a blue wavelength band, the second light may be light of a green wavelength band, and the third light may be light of a red wavelength band. In an embodiment, the blue wavelength band may be a wavelength band of light whose main peak wavelength is in the range of approximately 370 nanometers (nm) to 460 nm, the green wavelength band may be a wavelength band of light whose main peak wavelength is in the range of approximately 480 nm to 560 nm, and the red wavelength band may be a wavelength band of light whose main peak wavelength is in the range of approximately 600 nm to 750 nm, for example.

As shown in FIG. 7, each of the plurality of pixels PX may include three emission areas EA1, EA2, and EA3, or may include four emission areas EA1, EA2, EA3, and EA4 as shown in FIG. 8. In this case, the fourth emission area EA4 may emit the same second light as the second emission area EA2, but the disclosure is not limited thereto.

The emission areas of the plurality of pixels PX may be arranged in a stripe structure in which the emission areas are arranged in the first direction DR1, a PenTile® structure in which the emission areas EA1, EA2, EA3, and EA4 are arranged in a rhombic shape as shown in FIG. 8, or a hexagonal structure in which the emission areas are arranged in a hexagonal shape.

FIG. 9 is a schematic cross-sectional view illustrating an embodiment of the display panel taken along line I1-I1′ shown in FIG. 7.

Referring to FIG. 9, the display panel 100 includes a semiconductor backplane SBP, a light-emitting element backplane EBP, the display element layer EML, an encapsulation layer TFE, an optical layer OPL, a cover layer CVL, and a polarizing plate POL.

The semiconductor backplane SBP includes the semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 5.

The semiconductor substrate SSUB may be a silicon substrate, a germanium substrate, or a silicon-germanium substrate. The semiconductor substrate SSUB may be a substrate doped with a first type impurity. A plurality of well regions WA may be disposed on the top surface of the semiconductor substrate SSUB. The plurality of well regions WA may be regions doped with a second type impurity. The second type impurity may be different from the first type impurity. In an embodiment, when the first type impurity is a p-type impurity, the second type impurity may be an n-type impurity, for example. In an alternative embodiment, when the first type impurity is an n-type impurity, the second type impurity may be a p-type impurity.

Each of the plurality of well regions WA includes a source region SA corresponding to the source electrode of the pixel transistor PTR, a drain region DA corresponding to the drain electrode thereof, and a channel region CH disposed between the source region SA and the drain region DA.

A lower insulating film BINS may be disposed between a gate electrode GE and the well region WA. A side insulating film SINS may be disposed on the side surface of the gate electrode GE. The side insulating film SINS may be disposed on the lower insulating film BINS.

Each of the source region SA and the drain region DA may be a region doped with the first type impurity. The gate electrode GE of the pixel transistor PTR may overlap the well region WA in the third direction DR3, which is the thickness direction of the semiconductor substrate SSUB. The channel region CH may overlap the gate electrode GE in the third direction DR3. The source region SA may be disposed on one side of the gate electrode GE, and the drain region DA may be disposed on an opposite side of the gate electrode GE.

Each of the plurality of well regions WA further includes a first low-concentration impurity region LDD1 disposed between the channel region CH and the source region SA, and a second low-concentration impurity region LDD2 disposed between the channel region CH and the drain region DA. The first low-concentration impurity region LDD1 may be a region having a lower impurity concentration than the source region SA due to the lower insulating film BINS. The second low-concentration impurity region LDD2 may be a region having a lower impurity concentration than the drain region DA due to the lower insulating film BINS. The distance between the source region SA and the drain region DA may increase due to the first low-concentration impurity region LDD1 and the second low-concentration impurity region LDD2, thereby increasing the length of the channel region CH of each of the pixel transistors PTR.

A first semiconductor insulating film SINS1 may be disposed on the semiconductor substrate SSUB. A second semiconductor insulating film SINS2 may be disposed on the first semiconductor insulating film SINS1.

The plurality of contact terminals CTE may be disposed on the second semiconductor insulating film SINS2. Each of the plurality of contact terminals CTE may be connected to any one of the gate electrode GE, the source region SA, and the drain region DA of each of the pixel transistors PTR through a hole penetrating the first semiconductor insulating film SINS1 and the second semiconductor insulating film SINS2. The plurality of contact terminals CTE may include or consist of any one of copper (Cu), aluminum (Al), tungsten (W), molybdenum (Mo), chromium (Cr), gold (Au), titanium (Ti), nickel (Ni), and neodymium (Nd), or an alloy including any one of them.

A third semiconductor insulating film SINS3 may be disposed on a side surface of each of the plurality of contact terminals CTE. The top surface of each of the plurality of contact terminals CTE may be exposed without being covered by the third semiconductor insulating film SINS3.

Each of the first semiconductor insulating film SINS1, the second semiconductor insulating film SINS2, and the third semiconductor insulating film SINS3 may include or consist of silicon carbonitride (SiCN) or a silicon oxide (SiOx)-based inorganic film, but the disclosure is not limited thereto.

The semiconductor substrate SSUB may be replaced with a glass substrate or a polymer resin substrate such as polyimide. In this case, thin film transistors may be disposed on the glass substrate or the polymer resin substrate. The glass substrate may be a rigid substrate that does not bend, and the polymer resin substrate may be a flexible substrate that may be bent or curved.

The light-emitting element backplane EBP includes a plurality of conductive layers ML1 to ML8, a plurality of vias VA1 to VA9, and a plurality of inter-insulating films INS1 to INS9.

The first to ninth inter-insulating films INS1 to INS9 serve to insulate the first to eighth conductive layers ML1 to ML8. The first to eighth conductive layers ML1 to ML8 serve to connect the plurality of contact terminals CTE exposed from the semiconductor backplane SBP to thereby implement the circuit of the first sub-pixel SP1 shown in FIG. 5.

In an embodiment, the first to sixth transistors T1 to T6 are merely formed in the semiconductor backplane SBP, and the connection of the first to sixth transistors T1 to T6 and the first and second capacitors CP1 and CP2 is accomplished through the first to eighth conductive layers ML1 to ML8, for example. In addition, the connection between the drain region corresponding to the drain electrode of the fourth transistor T4, the source region corresponding to the source electrode of the fifth transistor T5, and a first electrode AND of the light-emitting element LE is also accomplished through the first to eighth conductive layers ML1 to ML8.

The first to eighth conductive layers ML1 to ML8 and the first to eighth vias VA1 to VA8 may include or consist of substantially the same material as each other. The first to eighth conductive layers ML1 to ML8 and the first to eighth vias VA1 to VA8 may include or consist of any one of copper (Cu), aluminum (Al), tungsten (W), molybdenum (Mo), chromium (Cr), gold (Au), titanium (Ti), nickel (Ni), and neodymium (Nd), or an alloy including any one of them. The first to eighth vias VA1 to VA8 may include or consist of substantially the same material as each other. First to eighth inter-insulating films INS1 to INS8 may include or consist of a silicon oxide (SiOx)-based inorganic layer, but the disclosure is not limited thereto.

A ninth inter-insulating film INS9 may be disposed on the eighth inter-insulating film INS8 and the eighth conductive layer ML8. The ninth inter-insulating film INS9 may include or consist of a silicon oxide (SiOx)-based inorganic film, but the disclosure is not limited thereto.

Each of the ninth vias VA9 may penetrate the ninth inter-insulating film INS9 and be connected to the exposed eighth conductive layer ML8. The ninth vias VA9 may include or consist of any one of copper (Cu), aluminum (Al), tungsten (W), molybdenum (Mo), chromium (Cr), gold (Au), titanium (Ti), nickel (Ni), and neodymium (Nd), or an alloy including any one of them.

The display element layer EML may be disposed on the light-emitting element backplane EBP. The display element layer EML may include the tenth and eleventh inter-insulating films INS10 and INS11, reflective electrodes RL, the first electrodes AND, a light-emitting stack IL, the second electrode CAT, a pixel defining film PDL, and a plurality of trenches TRC.

The reflective electrodes RL may be disposed on the ninth inter-insulating film INS9. Each of the reflective electrodes RL may include at least one reflective electrode RL1, RL2, RL3, and RL4. In an embodiment, each of the reflective electrodes RL may include the first to fourth reflective electrodes RL1, RL2, RL3, and RL4 as shown in FIG. 9, for example.

The first reflective electrodes RL1 may be disposed on the ninth inter-insulating film INS9, and may be connected to the ninth via VA9. Each of the second reflective electrodes RL2 may be disposed on the first reflective electrode RL1 corresponding thereto. Each of the third reflective electrodes RL3 may be disposed on the second reflective electrode RL2 corresponding thereto. Each of the fourth reflective electrodes RL4 may be disposed on the third reflective electrode RL3 corresponding thereto.

Since the second reflective electrode RL2 is an electrode that substantially reflects light from the light-emitting elements LE, the thickness of the second reflective electrode RL2 may be greater than the thickness of each of the first reflective electrode RL1, the third reflective electrode RL3, and the fourth reflective electrode RL4.

The first reflective electrodes RL1 may include or consist of any one of copper (Cu), aluminum (Al), tungsten (W), molybdenum (Mo), chromium (Cr), gold (Au), titanium (Ti), nickel (Ni), and neodymium (Nd), or an alloy including any one of them. In an embodiment, the first reflective electrodes RL1 may include or consist of titanium nitride (TiN), the second reflective electrodes RL2 may include or consist of aluminum (Al), the third reflective electrodes RL3 may include or consist of titanium nitride (TiN), and the fourth reflective electrodes RL4 may include titanium (Ti), for example.

The tenth inter-insulating film INS10 may be disposed on the ninth inter-insulating film INS9. The tenth inter-insulating film INS10 may be disposed between the reflective electrodes RL next (adjacent) to each other. The tenth inter-insulating film INS10 may be a film for flattening a stepped portion caused by the reflective electrodes RL. The eleventh inter-insulating film INS11 may be disposed on the tenth inter-insulating film INS10 and the reflective electrodes RL.

The tenth inter-insulating film INS10 and the eleventh inter-insulating film INS11 may include or consist of a silicon oxide (SiOx)-based inorganic film, but the disclosure is not limited thereto.

The eleventh inter-insulating film INS11 may be an optical auxiliary layer for adjusting the resonance distance of light emitted from the light-emitting stack IL in at least one of the first sub-pixel SP1, the second sub-pixel SP2, or the third sub-pixel SP3. The thickness of the eleventh inter-insulating film INS11 may be different in the first sub-pixel SP1, the second sub-pixel SP2, and the third sub-pixel SP3. That is, in order to adjust a distance from the reflective electrode RL to the second electrode CAT according to a main wavelength of light emitted from each of the first sub-pixel SP1, the second sub-pixel SP2, and the third sub-pixel SP3, the thickness of the eleventh inter-insulating film INS11 may be set for each of the first sub-pixel SP1, the second sub-pixel SP2, and the third sub-pixel SP3.

In an embodiment, as shown in FIG. 9, the thickness of the eleventh inter-insulating film INS11 in the first sub-pixel SP1 may be greater than the thickness of the eleventh inter-insulating film INS11 in the second sub-pixel SP2, and the thickness of the eleventh inter-insulating film INS11 in the second sub-pixel SP2 may be greater than the thickness of the eleventh inter-insulating film INS11 in the third sub-pixel SP3, for example. In this case, the distance between the first electrode AND and the reflective electrode RL in the first sub-pixel SP1 is greater than the distance between the first electrode AND and the reflective electrode RL in the second sub-pixel SP2. In addition, the distance between the first electrode AND and the reflective electrode RL in the second sub-pixel SP2 is greater than the distance between the first electrode AND and the reflective electrode RL in the third sub-pixel SP3.

Each of the tenth vias VA10 may penetrate the eleventh inter-insulating film INS11 and be connected to the exposed fourth reflective electrode RL4. The tenth vias VA10 may include or consist of any one of copper (Cu), aluminum (Al), tungsten (W), molybdenum (Mo), chromium (Cr), gold (Au), titanium (Ti), nickel (Ni), and neodymium (Nd), or an alloy including any one of them. The thickness of the tenth via VA10 in the first sub-pixel SP1 may be greater than the thickness of the tenth via VA10 in the second sub-pixel SP2, and the thickness of the tenth via VA10 in the second sub-pixel SP2 may be greater than the thickness of the tenth via VA10 in the third sub-pixel SP3.

The first electrode AND of each of the light-emitting elements LE may be disposed on the eleventh inter-insulating film INS11 and connected to the tenth via VA10. The first electrode AND of each of the light-emitting elements LE may be connected to the drain region DA or source region SA of the pixel transistor PTR through the tenth via VA10, the reflective electrode RL, the first to ninth vias VA1 to VA9, the first to eighth metal layers ML1 to ML8, and the contact terminal CTE. The first electrode AND of each of the light-emitting elements LE may include or consist of any one of copper (Cu), aluminum (Al), tungsten (W), molybdenum (Mo), chromium (Cr), gold (Au), titanium (Ti), nickel (Ni), and neodymium (Nd), or an alloy including any one of them. In an embodiment, the first electrode AND of each of the light-emitting elements LE may be titanium nitride (TiN), for example.

The pixel defining film PDL may be disposed on a part of the first electrode AND of each of the light-emitting elements LE. The pixel defining film PDL may cover the edge of the first electrode AND of each of the light-emitting elements LE. The pixel defining film PDL may partition the first emission areas EA1, the second emission areas EA2, and the third emission areas EA3. Each of the first emission area EA1, the second emission area EA2, and the third emission area EA3 may be an area where the light-emitting element LE including the first electrode AND, the light-emitting stack IL, and the second electrode CAT is disposed.

The first emission area EA1 may be defined as an area in which the first electrode AND, the light-emitting stack IL, and the second electrode CAT are sequentially stacked in the first sub-pixel SP1 to emit light. The second emission area EA2 may be defined as an area in which the first electrode AND, the light-emitting stack IL, and the second electrode CAT are sequentially stacked in the second sub-pixel SP2 to emit light. The third emission area EA3 may be defined as an area in which the first electrode AND, the light-emitting stack IL, and the second electrode CAT are sequentially stacked in the third sub-pixel SP3 to emit light.

The pixel defining film PDL may include first to third pixel defining films PDL1, PDL2, and PDL3. The first pixel defining film PDL1 may be disposed on the edge of the first electrode AND of each of the light-emitting elements LE, the second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may include or consist of a silicon oxide (SiOx)-based inorganic film. In an alternative embodiment, the first pixel defining film PDL1 and the third pixel defining film PDL3 may include or consist of a silicon nitride (SiNx)-based inorganic film, whereas the second pixel defining film PDL2 may include or consist of a silicon oxide (SiOx)-based inorganic film. The first pixel defining film PDL1, the second pixel defining film PDL2, and the third pixel defining film PDL3 may each have a thickness of about 500 angstroms (Å).

In order to reduce or prevent the likelihood of the first encapsulation inorganic film TFE1 being cut off due to the step coverage, the first pixel defining film PDL1, the second pixel defining film PDL2, and the third pixel defining film PDL3 may have a cross-sectional structure having a stepped portion. Step coverage refers to the ratio of the degree of thin film coated on an inclined portion to the degree of thin film coated on a flat portion. The lower the step coverage, the more likely it is that the thin film will be cut off at inclined portions.

Each of the plurality of trenches TRC may penetrate the first pixel defining film PDL1, the second pixel defining film PDL2, and the third pixel defining film PDL3. The eleventh inter-insulating film INS11 may be partially recessed at each of the plurality of trenches TRC.

At least one trench TRC may be disposed between the neighboring sub-pixels SP1, SP2, and SP3. Although FIG. 9 illustrates that two trenches TRC are disposed between the neighboring sub-pixels SP1, SP2, and SP3, the disclosure is not limited thereto.

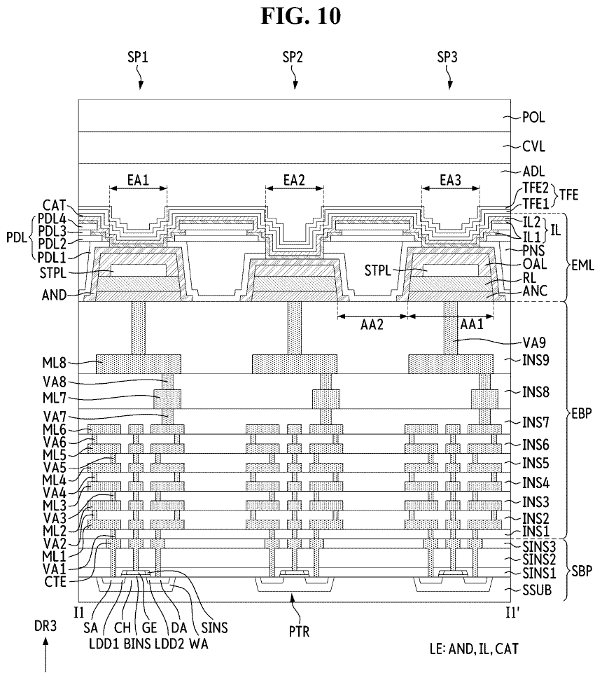

The light-emitting stack IL may include a plurality of stack layers IL1, IL2, and IL3. FIG. 9 illustrates that the light-emitting stack IL has a three-tandem structure including a first stack layer IL1, a second stack layer IL2, and a third stack layer IL3, but the disclosure is not limited thereto. In an embodiment, the light-emitting stack IL may have a two-tandem structure including two stack layers as shown in FIG. 10, for example.

In the three-tandem structure, the light-emitting stack IL may have a tandem structure including a plurality of intermediate layers IL1, IL2, and IL3 that emit different lights. In an embodiment, the light-emitting stack IL may include the first stack layer IL1 that emits first light, the second stack layer IL2 that emits second light, and the third stack layer IL3 that emits third light, for example. The first stack layer IL1, the second stack layer IL2, and the third stack layer IL3 may be sequentially stacked.

The first stack layer IL1 may have a structure in which a first hole transport layer, a first light-emitting layer that emits the first light, and a first electron transport layer are sequentially stacked. The second stack layer IL2 may have a structure in which a second hole transport layer, a second light-emitting layer that emits the second light, and a second electron transport layer are sequentially stacked. The third stack layer IL3 may have a structure in which a third hole transport layer, a third light-emitting layer that emits the third light, and a third electron transport layer are sequentially stacked.

A first charge generation layer for supplying charges to the second stack layer IL2 and supplying electrons to the first stack layer IL1 may be disposed between the first stack layer IL1 and the second stack layer IL2. The first charge generation layer may include an N-type charge generation layer that supplies electrons to the first stack layer IL1 and a P-type charge generation layer that supplies holes to the second stack layer IL2. The N-type charge generation layer may include a dopant of a metal material.

A second charge generation layer for supplying charges to the third stack layer IL3 and supplying electrons to the second stack layer IL2 may be disposed between the second stack layer IL2 and the third stack layer IL3. The second charge generation layer may include an N-type charge generation layer that supplies electrons to the second stack layer IL2 and a P-type charge generation layer that supplies holes to the third stack layer IL3.

The first stack layer IL1 may be disposed on the first electrodes AND and the pixel defining film PDL, and a residual film RIL disposed on the bottom surface of each trench TRC may be the same material as that of the first stack layer IL1. Due to the trench TRC, the first stack layer IL1 may be cut off between the neighboring sub-pixels SP1, SP2, and SP3. The second stack layer IL2 may be disposed on the first stack layer IL1. Due to the trench TRC, the second stack layer IL2 may be cut off between the neighboring sub-pixels SP1, SP2, and SP3. A cavity ESS or an empty space may be defined between the residual film IL and the second stack layer IL2 in the trench TRC. The third stack layer IL3 may be disposed on the second stack layer IL2. The third stack layer IL3 is not cut off by the trench TRC and may be disposed to cover the second stack layer IL2 in each of the trenches TRC.

In the three-tandem structure, each of the plurality of trenches TRC may be a structure for cutting off the first to third hole transport layers, the first charge generation layer, and the second charge generation layer of the first to third stack layers IL1, IL2, and IL3 of the display element layer EML between the neighboring sub-pixels SP1, SP2, and SP3. In addition, in the two-tandem structure, each of the plurality of trenches TRC may be a structure for cutting off the charge generation layer and the lower stack layer disposed between the lower stack layer and the upper stack layer.

In order to stably cut off the first and second stack layers IL1 and IL2 of the display element layer EML between the neighboring sub-pixels SP1, SP2, and SP3, the height of each of the plurality of trenches TRC may be greater than the height of the pixel defining film PDL. The height of each of the plurality of trenches TRC refers to the length of each of the plurality of trenches TRC in the third direction DR3. The height of the pixel defining film PDL refers to the length of the pixel defining film PDL in the third direction DR3. In order to cut off the charge generation layers and the hole transport layers of the light-emitting stack IL of the display element layer EML between the neighboring sub-pixels SP1, SP2, and SP3, a different structure may be instead of the trench TRC. In an embodiment, instead of the trench TRC, a reverse tapered partition wall may be disposed on the pixel defining film PDL, for example.

In addition, FIG. 9 illustrates that the light-emitting stack IL that emits light is disposed in the first emission area EA1, the second emission area EA2, and the third emission area EA3, but the disclosure is not limited thereto. In an embodiment, instead of the light-emitting stack IL, the first light-emitting layer may be disposed in the first emission area EA1, and may be omitted from the second emission area EA2 and the third emission area EA3. Furthermore, the second light-emitting layer may be disposed in the second emission area EA2 and may be omitted from the first emission area EA1 and the third emission area EA3. Furthermore, the third light-emitting layer may be disposed in the third emission area EA3 and may be omitted from the first emission area EA1 and the second emission area EA2. In this case, first to third color filters CF1, CF2, and CF3 of the optical layer OPL may be omitted.

The second electrode CAT may be disposed on the light-emitting stack IL. That is, the second electrode CAT may be disposed on the third stack layer IL3. The second electrode CAT may include or consist of a transparent conductive material (“TCO”) such as indium tin oxide (“ITO”) or indium zinc oxide (“IZO”) that may transmit light or a semi-transmissive conductive material such as magnesium (Mg), silver (Ag), or an alloy of Mg and Ag. When the second electrode CAT includes or consists of a semi-transmissive conductive material, the light emission efficiency may be improved in each of the first to third sub-pixels SP1, SP2, and SP3 due to a micro-cavity effect.

The encapsulation layer TFE may be disposed on the display element layer EML. The encapsulation layer TFE may include at least one inorganic film TFE1 and TFE3 to prevent oxygen or moisture from permeating into the display element layer EML. The first encapsulation inorganic film TFE1 may be disposed on the second electrode CAT, and the second encapsulation inorganic film TFE3 may be disposed above the first encapsulation inorganic film TFE1. The first encapsulation inorganic film TFE1 and the second encapsulation inorganic film TFE3 may include or consist of multiple layers in which one or more inorganic films of silicon nitride (SiNx), silicon oxynitride (SiON), silicon oxide (SiOx), titanium oxide (TiOx), and aluminum oxide (AlOx) layers are alternately stacked.

In addition, the encapsulation layer TFE may include at least one encapsulating organic film TFE2 to protect the display element layer EML from foreign substances such as dust. The encapsulating organic film TFE2 may be disposed between the first encapsulating inorganic film TFE1 and the second encapsulating inorganic film TFE3. The encapsulation organic film TFE2 may be a monomer. In an alternative embodiment, the encapsulation organic film TFE2 may be an organic film such as acryl resin, epoxy resin, phenolic resin, polyamide resin, polyimide resin or the like.

An adhesive layer ADL may be a layer for bonding the encapsulation layer TFE to the optical layer OPL. The adhesive layer ADL may be a double-sided adhesive member. In addition, the adhesive layer ADL may be a transparent adhesive member such as a transparent adhesive or a transparent adhesive resin.

The optical layer OPL includes a plurality of color filters CF1, CF2, and CF3, a plurality of lenses LNS, and a filling layer FIL. The plurality of color filters CF1, CF2, and CF3 may include the first to third color filters CF1, CF2, and CF3. The first to third color filters CF1, CF2, and CF3 may be disposed on the adhesive layer ADL.

The first color filter CF1 may overlap the first emission area EA1 of the first sub-pixel SP1. The first color filter CF1 may transmit light of the first color, i.e., light of a blue wavelength band. The blue wavelength band may be about 370 nm to about 460 nm. Thus, the first color filter CF1 may transmit light of the first color among light emitted from the first emission area EA1.

The second color filter CF2 may overlap the second emission area EA2 of the second sub-pixel SP2. The second color filter CF2 may transmit light of the second color, i.e., light of a green wavelength band. The green wavelength band may be about 480 nm to about 560 nm. Thus, the second color filter CF2 may transmit light of the second color among light emitted from the second emission area EA2.

The third color filter CF3 may overlap the third emission area EA3 of the third sub-pixel SP3. The third color filter CF3 may transmit light of the third color, i.e., light of a red wavelength band. The red wavelength band may be about 600 nm to about 750 nm. Thus, the third color filter CF3 may transmit light of the third color among light emitted from the third emission area EA3.

The plurality of lenses LNS may be disposed on the first color filter CF1, the second color filter CF2, and the third color filter CF3, respectively. Each of the plurality of lenses LNS may be a structure for increasing the proportion of light directed to the front of the display device 10. Each of the plurality of lenses LNS may have a cross-sectional shape that is convex in an upward direction.

The filling layer FIL may be disposed on the plurality of lenses LNS. The filling layer FIL may have a predetermined refractive index such that light travels in the third direction DR3 at an interface between the filling layer FIL and the plurality of lenses LNS. Further, the filling layer FIL may be a planarization layer. The filling layer FIL may be an organic film such as acrylic resin, epoxy resin, phenolic resin, polyamide resin, or polyimide resin.

The cover layer CVL may be disposed on the filling layer FIL. The cover layer CVL may be a glass substrate or a polymer resin. When the cover layer CVL is a glass substrate, it may be attached onto the filling layer FIL. In this case, the filling layer FIL may serve to bond the cover layer CVL. When the cover layer CVL is a glass substrate, it may serve as an encapsulation substrate. When the cover layer CVL is a polymer resin, it may be directly applied onto the filling layer FIL.

The polarizing plate may be disposed on one surface of the cover layer CVL. The polarizing plate may be a structure for reducing or preventing visibility degradation caused by reflection of external light. The polarizing plate may include a linear polarizing plate and a phase retardation film. In an embodiment, the phase retardation film may be a λ/4 plate (quarter-wave plate), for example, but the disclosure is not limited thereto. However, when visibility degradation caused by reflection of external light is sufficiently overcome by the first to third color filters CF1, CF2, and CF3, the polarizing plate may be omitted.

FIG. 10 is a schematic cross-sectional view illustrating another embodiment of the display panel taken along line I1-I1′ shown in FIG. 7.

The embodiment of FIG. 10 differs from the embodiment of FIG. 9 in that the first electrode AND of each of the light-emitting elements LE contacts and electrically connected to the side surface of a connection electrode ANC connected to the eighth conductive layer ML8. The embodiment of FIG. 10 also differs from the embodiment of FIG. 9 in that the trench TRC is omitted, and instead, the third pixel defining film PDL3 and a fourth pixel defining film PDL4 have an eave-shaped or mushroom-shaped cross-sectional structure. In the embodiment of FIG. 10, redundant description of parts already described in the embodiment of FIG. 9 will be omitted.

Referring to FIG. 10, the plurality of connection electrodes ANC may be respectively disposed on first portions AA1 of the ninth inter-insulating film INS9. Each of the plurality of connection electrodes ANC may be disposed on the first portion AA1 of the ninth inter-insulating film INS9 corresponding thereto. A plurality of connection electrodes ANC may include or consist of any one of copper (Cu), aluminum (Al), tungsten (W), molybdenum (Mo), chromium (Cr), gold (Au), titanium (Ti), nickel (Ni), and neodymium (Nd), an alloy including any one of them, or a transparent conductive oxide. In an embodiment, the plurality of connection electrodes ANC may include titanium (Ti), titanium nitride (TiN), indium tin oxide (“ITO”), or indium zinc oxide (“IZO”), for example, but the disclosure is limited thereto.

A plurality of reflective electrodes RL may be respectively disposed on the plurality of connection electrodes ANC. Each of the plurality of reflective electrodes RL may be disposed on the connection electrode ANC corresponding thereto. The plurality of reflective electrodes RL may include or consist of any one of copper (Cu), aluminum (Al), tungsten (W), molybdenum (Mo), chromium (Cr), gold (Au), titanium (Ti), nickel (Ni), and neodymium (Nd), or an alloy including any one of them. In an embodiment, each of the plurality of reflective electrodes RL may include aluminum (Al) having relatively high reflectivity, for example.

A plurality of optical auxiliary films OAL may be respectively disposed on the plurality of reflective electrodes RL. Each of the plurality of optical auxiliary films OAL may be disposed on the reflective electrode RL corresponding thereto. The plurality of optical auxiliary films OAL may include or consist of a silicon oxide (SiOx)-based inorganic film, but the disclosure is not limited thereto.

In each of the first emission area EA1 and the third emission area EA3, a step layer STPL may be disposed on the reflective electrode RL, and the optical auxiliary film OAL may be disposed on the step layer STPL. In the second emission area EA2, only the optical auxiliary film OAL may be disposed on the reflective electrode RL. The thicknesses of the optical auxiliary film OAL may be substantially the same in the first emission area EA1, the second emission area EA2, and the third emission area EA3.

Due to the step layer STPL, the distance between the reflective electrode RL and the first electrode AND in the first emission area EA1 and the third emission area EA3 may be greater than the distance between the reflective electrode RL and the first electrode AND in the second emission area EA2. The thickness of the step layer STPL and the thickness of the optical auxiliary film OAL may be set in consideration of the wavelength and resonance distance of light emitted from the first stack layer IL1 of the light-emitting stack IL, and the wavelength and resonance distance of light emitted from the second stack layer IL2 thereof.

Each of the light-emitting elements LE may include the first electrode AND, a light-emitting stack IL, and a second electrode CAT.

The first electrode AND of each of the light-emitting elements LE may be disposed on the optical auxiliary film OAL corresponding thereto. Since the connection electrode ANC, the reflective electrode RL, and the optical auxiliary film OAL are sequentially stacked, the first electrode AND of each of the light-emitting elements LE may be disposed on the top surface and the side surface of the optical auxiliary film OAL, the side surface of the reflective electrode RL, and the side surface of the connection electrode ANC. Accordingly, the first electrode AND of each of the light-emitting elements LE may contact and electrically connected to the side surface of the reflective electrode RL and the side surface of the connection electrode ANC. Therefore, compared to when the first electrode AND of each of the light-emitting elements LE is connected to the reflective electrode RL exposed through a through-hole penetrating the optical auxiliary film OAL, the number of mask processes may be reduced, thereby lowering manufacturing cost and increasing manufacturing efficiency.

The first electrode AND of each of the light-emitting elements LE may be connected to the drain region DA or the source region SA of the pixel transistor PTR through the connection electrode ANC, the first to ninth vias VA1 to VA9, the first to eighth conductive layers ML1 to ML8, and the contact terminal CTE.

The ninth inter-insulating film INS9 may include the first portion AA1 that overlaps the connection electrode ANC in the third direction DR3 and a second portion AA2 that does not overlap the connection electrode ANC in the third direction DR3. The thickness of the first portion AA1 and the thickness of the second portion AA2 of the ninth inter-insulating film INS9 may be substantially the same.

In an alternative embodiment, the thickness of the first portion AA1 of the ninth inter-insulating film INS9 may be greater than the thickness of the second portion AA2 thereof. In this case, the side surface of the first portion AA1 of the ninth inter-insulating film INS9 may be exposed, and the first electrode AND of each of the light-emitting elements LE may be disposed on the exposed side surface of the first portion AA1 of the ninth inter-insulating film INS9.

The first electrode AND of each of the light-emitting elements LE may include or consist of any one of copper (Cu), aluminum (Al), tungsten (W), molybdenum (Mo), chromium (Cr), gold (Au), titanium (Ti), nickel (Ni), and neodymium (Nd), an alloy including any one of them, or a transparent conductive oxide. In an embodiment, the first electrode AND of each of the light-emitting elements LE may include titanium (Ti), titanium nitride (TiN), indium tin oxide (“ITO”), or indium zinc oxide (“IZO”), for example, but the disclosure is limited thereto.

The pixel defining film PDL may be disposed on a part of the first electrode AND of each of the light-emitting elements LE. The pixel defining film PDL may cover the edge of the first electrode AND of each of the light-emitting elements LE. The pixel defining film PDL may partition the first emission areas EA1, the second emission areas EA2, and the third emission areas EA3.

The pixel defining film PDL may include first to fourth pixel defining films PDL1, PDL2, PDL3, and PDL4.

The first pixel defining film PDL1 may be disposed on the first electrode AND of each of the light-emitting elements LE. Specifically, the first pixel defining film PDL1 may cover a part of the top surface of the first electrode AND disposed on the optical auxiliary film OAL. Further, the first pixel defining film PDL1 may cover the first electrode AND disposed on the side surface of the connection electrode ANC, the side surface of the reflective electrode RL, and the side surface of the optical auxiliary film OAL. The first pixel defining film PDL1 may be disposed on the top surface of the second portion AA2 of the ninth inter-insulating film INS9.

A planarization film PNS is a film for flattening the stepped portion caused by the connection electrode ANC, the reflective electrode RL, and the optical auxiliary film OAL.

The planarization film PNS may be disposed on the first pixel defining film PDL1 covering the first electrode AND disposed on the side surface of the connection electrode ANC, the side surface of the reflective electrode RL, and the side surface of the optical auxiliary film OAL. The planarization film PNS may be disposed on the first pixel defining film PDL1 disposed on the second portion AA2 of the ninth inter-insulating film INS9.

The planarization film PNS may be disposed between the connection electrodes ANC next (adjacent) to each other in the first direction DR1 or the second direction DR2. The planarization film PNS may be disposed between the reflective electrodes RL next (adjacent) to each other in the first direction DR1 or the second direction DR2. The planarization film PNS may be disposed between the optical auxiliary films OAL next (adjacent) to each other in the first direction DR1 or the second direction DR2.

The step layer STPL is not in the second emission area EA2, whereas the step layer STPL is in each of the first emission area EA1 and the third emission area EA3. Accordingly, the heights of the connection electrode ANC, the reflective electrode RL, and the optical auxiliary film OAL in the second emission area EA2 may be less than the heights of the connection electrode ANC, the reflective electrode RL, the step layer STPL, and the optical auxiliary film OAL in the first emission area EA1 and the third emission area EA3. Therefore, the planarization film PNS may cover the top surface of the first pixel defining film PDL1 disposed on the top surface of the first electrode AND disposed in the second emission area EA2.

In contrast, the top surface of the planarization film PNS may be flatly connected to the top surface of the first pixel defining film PDL1 disposed on the top surface of the first electrode AND disposed in the first emission area EA1 and the third emission area EA3. That is, the planarization film PNS may not cover the top surface of the first pixel defining film PDL1 disposed on the top surface of the first electrode AND disposed in each of the first emission area EA1 and the third emission area EA3.

The second pixel defining film PDL2 may be disposed on the first pixel defining film PDL1 and the planarization film PNS, the third pixel defining film PDL3 may be disposed on the second pixel defining film PDL2, and the fourth pixel defining film PDL4 may be disposed on the third pixel defining film PDL3. The first pixel defining film PDL1 and the third pixel defining film PDL3 may include or consist of a silicon nitride (SiNx)-based inorganic film, whereas the second pixel defining film PDL2, the fourth pixel defining film PDL4, and the planarization film PNS may include or consist of a silicon oxide (SiOx)-based inorganic film. The first pixel defining film PDL1 includes or consists of a material different from that of the planarization film PNS, and thus may serve as a stopper in a chemical mechanical polishing process for the planarization film PNS.

When the planarization film PNS and the second pixel defining film PDL2 are both formed as a silicon oxide (SiOx)-based inorganic film, the planarization film PNS and the second pixel defining film PDL2 may be formed as a single film.

Since the length of the third pixel defining film PDL3 in one direction is less than the length of the fourth pixel defining film PDL4 in one direction, the bottom surface of the fourth pixel defining film PDL4 may be exposed without being covered by the third pixel defining film PDL3. That is, the third pixel defining film PDL3 and the fourth pixel defining film PDL4 may have an eaves-shaped or mushroom-shaped cross-sectional structure.

The light-emitting stack IL may be disposed on the first electrode AND and the pixel defining film PDL. The light-emitting stack IL may include the first stack layer IL1 and the second stack layer IL2 that emit different lights. When the light-emitting stack IL has a two-tandem structure, one of the first stack layer IL1 and the second stack layer IL2 may emit light that includes the wavelength range of any one of the first light, the second light, and the third light, and a remaining (the other) one of the first stack layer IL1 and the second stack layer IL2 may emit light that includes the wavelength ranges of remaining (the other) two lights. In an embodiment, the first stack layer IL1 may emit light that includes the wavelength range of the first light and the wavelength range of the third light, and the second stack layer IL2 may emit light that includes the wavelength range of the second light, for example. Here, the first light may be light of a blue wavelength band, the second light may be light of a green wavelength band, and the third light may be light of a red wavelength band.

A charge generation layer for supplying charges to the second stack layer IL2 and supplying electrons to the first stack layer IL1 may be disposed between the first stack layer IL1 and the second stack layer IL2. The charge generation layer may include an n-type charge generation layer that supplies electrons to the first stack layer IL1 and a p-type charge generation layer that supplies holes to the second stack layer IL2. The N-type charge generation layer may include a dopant of a metal material.

The first stack layer IL1 is not formed on the bottom surface of the fourth pixel defining film PDL4 that is exposed without being covered by the third pixel defining film PDL3, and thus may be cut off by the eaves-shaped or mushroom-shaped cross-sectional structure of the third pixel defining film PDL3 and the fourth pixel defining film PDL4. In this case, the first hole transport layer of the first stack layer IL1, and a charge generation layer disposed between the first stack layer IL1 and the second stack layer IL2 may also be cut off. Further, although FIG. 10 illustrates that the second stack layer IL2 is connected without being cut off, the second hole transport layer of the second stack layer IL2 may be cut off, and the second electron transport layer of the second stack layer IL2 may be connected without being cut off. Therefore, it is possible to prevent a leakage current from flowing through the first hole transport layer of the first stack layer IL1, the second hole transport layer of the second stack layer IL2, and the charge generation layer between the neighboring (adjacent) emission areas EA1, EA2, and EA3. Accordingly, it is possible to prevent the light-emitting stack IL in the neighboring (adjacent) emission areas EA1, EA2, and EA3 from emitting light other than the originally intended light due to the influence of the above current.

Although FIG. 10 illustrates a two-tandem structure in which the light-emitting stack IL includes two stack layers IL1 and IL2, the disclosure is not limited thereto. In an embodiment, the light-emitting stack IL may have a three-tandem structure including three stack layers as shown in FIG. 9, for example. In this case, it may be designed such that the charge generation layer between the first stack layer IL1 and the second stack layer IL2, and the charge generation layer between the second stack layer IL2 and the third stack layer IL3 are cut off by adjusting the height of the third pixel defining film PDL3. In an alternative embodiment, as shown in FIG. 9, the trench TRC penetrating the first pixel defining film PDL1, the planarization film PNS, the second pixel defining film PDL2, and the third pixel defining film PDL3 may be added. In this case, the trench TRC may penetrate at least a part of the ninth inter-insulating film INS9, but the disclosure is not limited thereto.

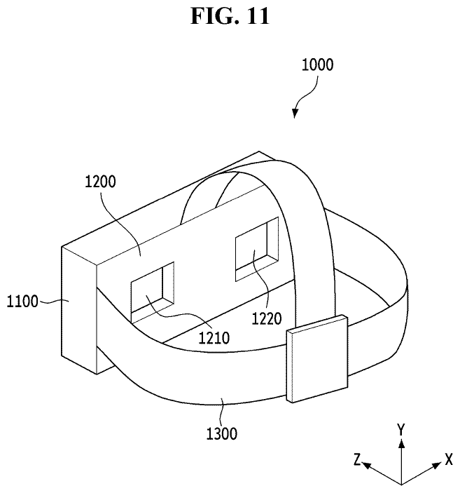

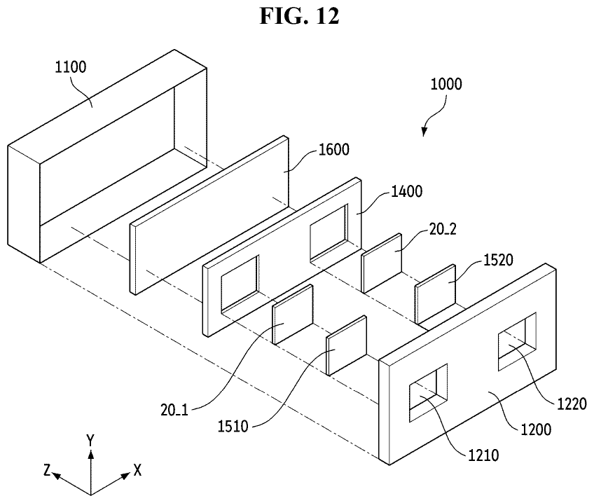

FIG. 11 is a schematic perspective view illustrating one embodiment of a head mounted display. FIG. 12 is a schematic exploded perspective view illustrating the head mounted display shown in FIG. 11.

Referring to FIGS. 11 and 12, a head mounted display 1000 in an embodiment includes a first display device 20_1, a second display device 20_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 20_1 provides an image to the user's left eye, and the second display device 20_2 provides an image to the user's right eye. Since each of the first display device 20_1 and the second display device 20_2 is substantially the same as the display device 20 described in conjunction with FIGS. 3 to 10, the description of the first display device 20_1 and the second display device 20_2 will be omitted.

The first optical member 1510 may be disposed between the first display device 20_1 and the first eyepiece 1210. The second optical member 1520 may be disposed between the second display device 20_2 and the second eyepiece 1220. Each of the first optical member 1510 and the second optical member 1520 may include at least one convex lens.

The middle frame 1400 may be disposed between the first display device 20_1 and the control circuit board 1600 and between the second display device 20_2 and the control circuit board 1600. The middle frame 1400 serves to support and fix the first display device 20_1, the second display device 20_2, and the control circuit board 1600.

The control circuit board 1600 may be disposed between the middle frame 1400 and the display device housing 1100. The control circuit board 1600 may be connected to the first display device 20_1 and the second display device 20_2 through the connector. The control circuit board 1600 may convert an image source inputted from the outside into the digital video data DATA, and transmit the digital video data DATA to the first display device 20_1 and the second display device 20_2 through the connector.

The control circuit board 1600 may transmit the digital video data DATA corresponding to a left-eye image optimized for the user's left eye to the first display device 20_1, and may transmit the digital video data DATA corresponding to a right-eye image optimized for the user's right eye to the second display device 20_2. In an alternative embodiment, the control circuit board 1600 may transmit the same digital video data DATA to the first display device 20_1 and the second display device 20_2.

The display device housing 1100 serves to accommodate the first display device 20_1, the second display device 20_2, the middle frame 1400, the first optical member 1510, the second optical member 1520, and the control circuit board 1600. The housing cover 1200 is disposed to cover one open surface of the display device housing 1100. The housing cover 1200 may include the first eyepiece 1210 at which the user's left eye is disposed and the second eyepiece 1220 at which the user's right eye is disposed. FIGS. 11 and 12 illustrate that the first eyepiece 1210 and the second eyepiece 1220 are disposed separately, but the disclosure is not limited thereto. The first eyepiece 1210 and the second eyepiece 1220 may be combined into one.

The first eyepiece 1210 may be aligned with the first display device 20_1 and the first optical member 1510, and the second eyepiece 1220 may be aligned with the second display device 20_2 and the second optical member 1520. Therefore, the user may view, through the first eyepiece 1210, the image of the first display device 20_1 magnified as a virtual image by the first optical member 1510, and may view, through the second eyepiece 1220, the image of the second display device 20_2 magnified as a virtual image by the second optical member 1520.

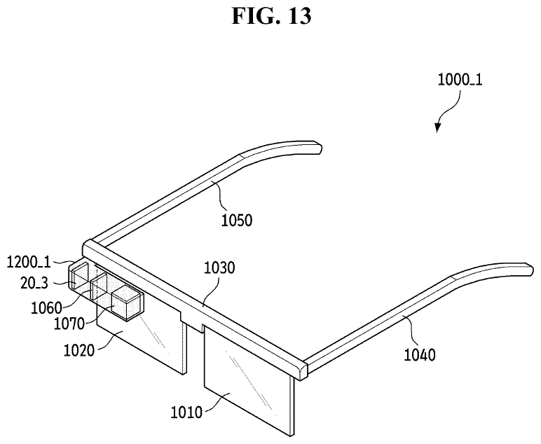

The head mounted band 1300 serves to secure the display device housing 1100 to the user's head such that the first eyepiece 1210 and the second eyepiece 1220 of the housing cover 1200 remain disposed on the user's left and right eyes, respectively. When the housing cover 1200 is implemented to be lightweight and compact, the head mounted display 1000 may be provided with, as shown in FIG. 13, an eyeglass frame instead of the head mounted band 1300.

FIG. 13 is a schematic perspective view illustrating another embodiment of a head mounted display.

Referring to FIG. 13, a head mounted display 1000_1 in an embodiment may be an eyeglasses-type display device in which a display device housing 1200_1 is implemented in a lightweight and compact manner. The head mounted display 1000_1 in an embodiment may include a display device 20_3, a left eye lens 1010, a right eye lens 1020, a support frame 1030, temples 1040 and 1050, an optical member 1060, an optical path changing member 1070, and the display device housing 1200_1.

The display device housing 1200_1 may include the display device 20_3, the optical member 1060, and the optical path changing member 1070. The image displayed on the display device 20_3 may be magnified by the optical member 1060, and may be provided to the user's right eye through the right eye lens 1020 after the optical path thereof is changed by the optical path changing member 1070. As a result, the user may view an augmented reality image, through the right eye, in which a virtual image displayed on the display device 20_3 and a real image seen through the right eye lens 1020 are combined.

FIG. 13 illustrates that the display device housing 1200_1 is disposed at the right end of the support frame 1030, but the disclosure is not limited thereto. In an embodiment, the display device housing 1200_1 may be disposed at the left end of the support frame 1030, and in this case, the image of the display device 20_3 may be provided to the user's left eye, for example. In an alternative embodiment, the display device housing 1200_1 may be disposed at both the left and right ends of the support frame 1030, and in this case, the user may view the image displayed on the display device 20_3 through both the left and right eyes.

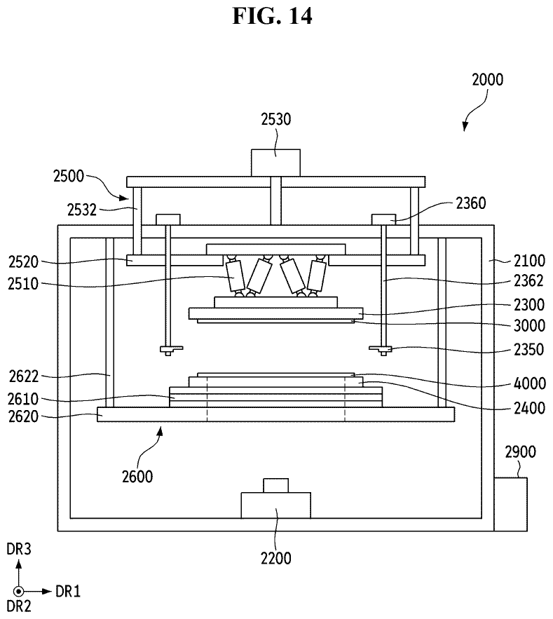

FIG. 14 is a schematic diagram illustrating an embodiment of a deposition apparatus.

Referring to FIG. 14, a deposition apparatus 2000 in an embodiment may be used to form a deposition material layer on a substrate 3000. In an embodiment, the deposition apparatus 2000 in an embodiment may be used to form light-emitting layers on a backplane substrate 3000 (or also referred to as a substrate) in a manufacturing process of the display panel 100 (refer to FIG. 3), for example. In an embodiment, as illustrated in FIG. 9, the semiconductor backplane SBP and the light-emitting element backplane EBP may be disposed on the backplane substrate 3000, and reflective electrodes RL and the insulating films INS10 and INS11 may be disposed on the light-emitting element backplane EBP, for example. Electrode patterns, e.g., the first electrodes AND functioning as anode electrodes and the pixel defining film PDL defining openings exposing the first electrodes AND may be disposed on the insulating film INS11, and the first electrodes AND may be electrically connected to the reflective electrodes RL through the vias VA10. In an embodiment, the deposition apparatus 2000 may form first light-emitting layers on the first electrodes AND of the first emission areas EA1. In another embodiment, the deposition apparatus 2000 may form second light-emitting layers on the first electrodes AND of the second emission areas EA2. As another example, the deposition apparatus 2000 may form third light-emitting layers on the first electrodes AND of the third emission areas EA3.

The deposition apparatus 2000 may include a deposition source 2200 for providing a vapor deposition material onto the backplane substrate 3000, a substrate chuck 2300 for supporting the backplane substrate 3000 to face the deposition source 2200, and a mask chuck 2400 disposed between the deposition source 2200 and the substrate chuck 2300 to support a deposition mask 4000 to face the backplane substrate 3000. The deposition source 2200, the substrate chuck 2300, and the mask chuck 2400 may be disposed in a process chamber (or an evaporation chamber) 2100.

The process chamber 2100 may have an internal space, and a deposition process for forming a deposition material layer on the backplane substrate 3000 may be performed in the internal space of the process chamber 2100. The process chamber 2100 may be connected to a vacuum pump (not shown), and a vacuum atmosphere may be created in the internal space of the process chamber 2100 by the vacuum pump. An opening (not shown) for loading/unloading of the backplane substrate 3000 and the deposition mask 4000 may be provided on one wall of the process chamber 2100, and the opening may be opened and closed by a gate valve (not shown).

The deposition source 2200 may be disposed in the process chamber 2100, and a deposition material may be stored in the deposition source 2200. The deposition source 2200 may evaporate a deposition material such as an organic material, an inorganic material, a conductive material, or the like toward the backplane substrate 3000, and the evaporated deposition material may be deposited on the backplane substrate 3000 through the deposition mask 4000. In an embodiment, the deposition source 2200 may evaporate an organic light-emitting material for forming light-emitting layers on the backplane substrate 3000, and may be provided with a heater (not shown) for evaporating the organic light-emitting material, for example. The evaporated organic light-emitting material may be deposited on electrode patterns on the backplane substrate 3000 through the deposition mask 4000, thereby forming light-emitting layers on the electrode patterns of the backplane substrate 3000. As shown in FIG. 14, the deposition source 2200 may be disposed on the central portion of the bottom surface of the process chamber 2100, but the deposition source 2200 may move horizontally by a separate driver (not shown).

The substrate chuck 2300 may be disposed above the deposition source 2200 and may support the backplane substrate 3000 such that the backplane substrate 3000 faces the deposition source 2200. In an embodiment, the substrate chuck 2300 may be an electrostatic chuck that holds the rear surface of the backplane substrate 3000 using an electrostatic force, for example. Specifically, the electrode patterns, e.g., first electrodes AND, may be disposed on the front surface of the backplane substrate 3000, and the substrate chuck 2300 may hold the rear surface of the backplane substrate 3000 such that the front surface of the backplane substrate 3000 faces downward, that is, faces the deposition source 2200.

A plurality of lift fingers 2350 for loading the backplane substrate 3000 onto the substrate chuck 2300 may be arranged in the process chamber 2100. The lift fingers 2350 may be arranged around the substrate chuck 2300 and the mask chuck 2400, and may be respectively moved vertically by finger drivers 2360. In an embodiment, three or four lift fingers 2350 may be arranged around the substrate chuck 2300 and the mask chuck 2400, and may be moved in the third direction DR3 by the finger drivers 2360, for example.

The backplane substrate 3000 may be loaded into the process chamber 2100 by a transfer robot (not shown), and may be transferred from the transfer robot onto the lift fingers 2350 under the substrate chuck 2300. In this case, the rear surface of the backplane substrate 3000 may face the bottom surface of the substrate chuck 2300, and the lift fingers 2350 may support the front edge portions of the backplane substrate 3000. The finger drivers 2360 may raise the lift fingers 2350 such that the backplane substrate 3000 becomes closer (adjacent) to the bottom surface of the substrate chuck 2300, and the rear surface of the backplane substrate 3000 may be held on the bottom surface of the substrate chuck 2300 by an electrostatic force.

The finger drivers 2360 may be arranged on the upper lid of the process chamber 2100 and may be respectively connected to the lift fingers 2350 through driving shafts 2362 that extend vertically through the upper lid of the process chamber 2100. The finger drivers 2360 may vertically move the lift fingers 2350 to load or unload the backplane substrate 3000. In addition, the finger drivers 2360 may rotate the lift fingers 2350 with respect to each of the driving shafts 2362. In an embodiment, the finger drivers 2360 may rotate the lift fingers 2350 such that the ends of the lift fingers 2350 do not overlap the substrate chuck 2300 and the mask chuck 2400, thereby enabling vertical movement of the lift fingers 2350, for example. In addition, the finger drivers 2360 may rotate the lift fingers 2350 such that the ends of the lift fingers 2350 overlap the edge portions of the backplane substrate 3000 to support the edge portions of the backplane substrate 3000.

The deposition mask 4000 may be loaded into the process chamber 2100 by the transfer robot, and may be transferred onto the lift fingers 2350 above the mask chuck 2400. The edge portions of the deposition mask 4000 may be placed on the ends of the lift fingers 2350, and the finger drivers 2360 may lower the lift fingers 2350 to load the deposition mask 4000 onto the mask chuck 2300. In this case, recesses (not shown) into which ends of lift fingers 2350 are inserted may be provided at the edge portions of the mask chuck 2400, and the finger drivers 2360 may rotate the lift fingers 2350 such that the lift fingers 2350 do not overlap the mask chuck 2400 after the deposition mask 4000 is loaded on the mask chuck 2400.

The mask chuck 2400 may support the edge portion of the deposition mask 4000. In an embodiment, the mask chuck 2400 may be an electrostatic chuck configured to hold the edge portion of the deposition mask 4000 using an electrostatic force, for example. In particular, the mask chuck 2400 may define a circular opening to expose the deposition mask 4000 toward the deposition source 2200. In an embodiment, the mask chuck 2400 may have a disk shape or a quadrilateral plate shape with a circular opening, for example.

The deposition apparatus 2000 may include a chuck driver for adjusting the position and posture of the backplane substrate 3000 and the deposition mask 4000. In an embodiment, the deposition apparatus 2000 may include a substrate chuck driver 2500 for moving the substrate chuck 2300 and a mask chuck driver 2600 for moving the mask chuck 2400, for example.

The substrate chuck driver 2500 may move the substrate chuck 2300 in the first direction DR1, the second direction DR2, and the third direction DR3 to adjust the position of the backplane substrate 3000. In this case, the first direction DR1 may be the first horizontal direction, the second direction DR2 may be the second horizontal direction perpendicular to the first direction DR1, and the third direction DR3 may be the vertical direction. In an embodiment, the first direction DR1, the second direction DR2, and the third direction DR3 may be an X-axis direction, a Y-axis direction, and a Z-axis direction, respectively, for example.

The substrate chuck driver 2500 may rotate the substrate chuck 2300 around the Z-axis to adjust the azimuth of the backplane substrate 3000, that is, the angle at which the backplane substrate 3000 is held on the bottom surface of the substrate chuck 2300. Further, the substrate chuck driver 2500 may rotate the substrate chuck 2300 around the X-axis, and may also rotate the substrate chuck 2300 around the Y-axis in order to adjust the inclination of the backplane substrate 3000. In an embodiment, the substrate chuck driver 2500 may include a hexapod actuator 2510 that provides a motion of six degrees of freedom (X, Y, Z, θx, θy, and θz), for example.

The substrate chuck driver 2500 may include a substrate stage 2520 to which the hexapod actuator 2510 is disposed (e.g., mounted), and a second actuator 2530 connected to the substrate stage 2520. The substrate stage 2520 may be disposed horizontally in the process chamber 2100, and the second actuator 2530 may be disposed above the process chamber 2100. The second actuator 2530 may be connected to the substrate stage 2520 by a plurality of driving shafts 2532 extending in the third direction DR3, i.e., the vertical direction (Z-axis direction) through the upper lid of the process chamber 2100, and may move the substrate stage 2520 in the central axis direction of the hexapod actuator 2510, i.e., the vertical direction. In an embodiment, the second actuator 2530 may be configured using a brushless direct current (“DC”) motor, a linear motor, a direct drive (“DD”) motor, or the like, and may adjust the height of the substrate chuck 2300 for loading or unloading the backplane substrate 3000, for example.

The hexapod actuator 2510 may include a first platform connected to the substrate chuck 2300, a second platform disposed (e.g., mounted) to the substrate stage 2520, and six sub-actuators disposed between the first platform and the second platform. In an embodiment, the six sub-actuators may each be configured using a brushless DC motor, a voice coil linear motor, a step motor, a DD motor, a servo motor, or the like, and may move and rotate the first platform to adjust the horizontal position, vertical position, azimuth, and inclination of the backplane substrate 3000, for example.

The mask chuck driver 2600 may move and rotate the mask chuck 2400 to adjust the horizontal position of the deposition mask 4000 and the azimuth angle of the deposition mask 4000, that is, the angle at which the deposition mask 4000 is placed on the mask chuck 2400. The mask chuck driver 2600 may move the mask chuck 2400 in a direction parallel to the deposition mask 4000 and rotate the mask chuck 2400 with respect to the central axis of the mask chuck 2400. In an embodiment, the mask chuck driver 2600 may move the mask chuck 2400 in the first direction DR1 (X-axis) and the second direction DR2 (Y-axis), and may rotate the mask chuck 2400 with respect to the third direction DR3 (Z-axis), for example. The mask chuck driver 2600 may include, e.g., a piezo actuator 2610 that provides a motion of three degrees of freedom (X, Y, and θz). The piezo actuator 2610 may define an opening communicating with the circular opening of the mask chuck 2400.

The mask chuck driver 2600 may include a mask stage 2620 that is horizontally disposed in the process chamber 2100 and supports the piezo actuator 2610. In an embodiment, the mask stage 2620 may define an opening that communicates with the opening of the piezo actuator 2610 and may be supported by a plurality of posts 2622 that are connected to the upper lid of the process chamber 2100, for example.

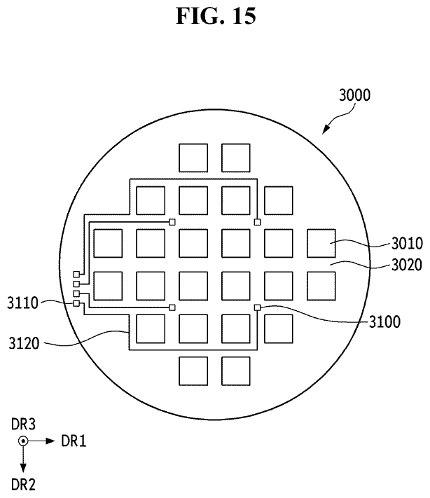

FIG. 15 is a schematic bottom view illustrating the backplane substrate shown in FIG. 14.

Referring to FIG. 15, the backplane substrate 3000 may include a plurality of display cell regions 3010 and a scribe lane region 3020 disposed between the display cell regions 3010. The display cell regions 3010 may be arranged in a matrix form along the first direction DR1 and the second direction DR2 as illustrated in FIG. 15, and may be individualized into display panels 100 (refer to FIG. 3) by a dicing process after the display manufacturing process is completed. In an embodiment, the first direction DR1 may be a first horizontal direction, and the second direction DR2 may be a second horizontal direction perpendicular to the first direction DR1, for example. In addition, each of the display cell regions 3010 may have, e.g., a quadrilateral shape as shown in the drawing.

In an embodiment, each of the display cell regions 3010 may include the semiconductor backplane SBP, the light-emitting element backplane EBP disposed on the semiconductor backplane SBP, the reflective electrodes RL disposed on the light-emitting element backplane EBP, and the insulating films INS10 and INS11 as shown in FIG. 9, for example. In addition, each of the display cell regions 3010 may include the plurality of electrode patterns, e.g., the plurality of first electrodes AND disposed on the insulating film INS11, and the first electrodes AND may be connected to the reflective electrodes RL through the plurality of vias VA10. In this case, the electrode patterns of the display cell regions 3010 may be arranged on the front surface of the backplane substrate 3000, and the substrate chuck 2300 may hold the rear surface of the backplane substrate 3000 such that the electrode patterns of the display cell regions 3010 face downward, i.e., face the deposition source 2200.

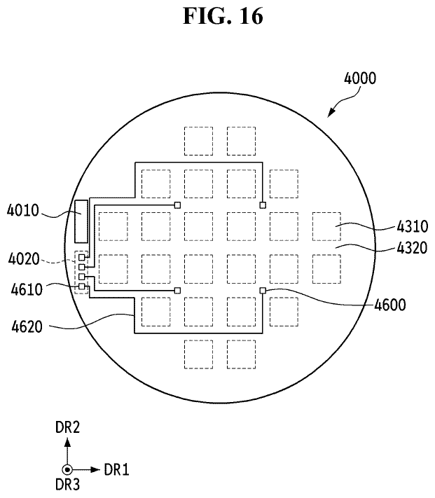

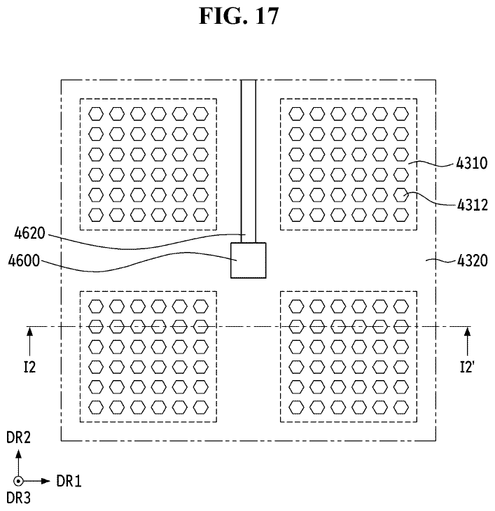

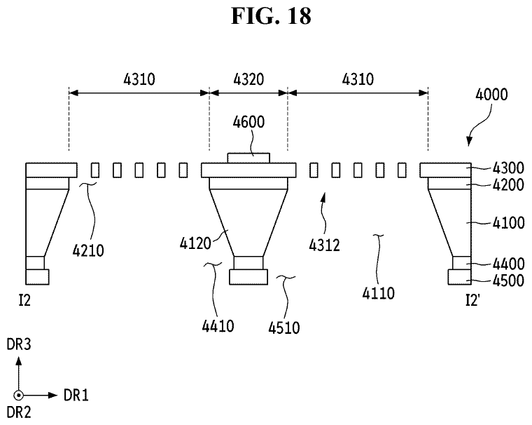

FIG. 16 is a schematic plan view illustrating the deposition mask shown in FIG. 14. FIG. 17 is a schematic enlarged plan view illustrating the mask cell regions shown in FIG. 16. FIG. 18 is a schematic cross-sectional view taken along line I2-I2′ shown in FIG. 17.

Referring to FIGS. 16 to 18, the deposition mask 4000 may include mask cell regions 4310 respectively corresponding to the display cell regions 3010 of the backplane substrate 3000, and a grid region 4320 corresponding to the scribe lane region 3020 of the backplane substrate 3000. Each of the mask cell regions 4310 may define a plurality of pixel openings 4312 exposing the first electrodes AND of the backplane substrate 3000 in a deposition process. In an embodiment, the deposition mask 4000 may include a mask substrate 4100, an intermediate inorganic film 4200 disposed on the mask substrate 4100, and a membrane 4300 disposed on the intermediate inorganic film 4200, for example. In this case, the membrane 4300 may include the plurality of mask cell regions 4310 and the grid region 4320 surrounding the mask cell regions 4310, and each of the mask cell regions 4310 may define the plurality of pixel openings 4312.

The mask substrate 4100 may define cell openings 4110 respectively corresponding to the mask cell regions 4310, and may include a rib region 4120 defining the cell openings 4110. The intermediate inorganic film 4200 may define intermediate openings 4210 respectively arranged on the cell openings 4110. In this case, the mask cell regions 4310 of the membrane 4300 may be respectively arranged above the intermediate openings 4210, and the pixel openings 4312 of the membrane 4300 may communicate with the cell openings 4110 through the intermediate openings 4210.

In an embodiment, the mask cell regions 4310 of the membrane 4300 may be exposed toward the deposition source 2200 through the cell openings 4110 of the mask substrate 4100 and the intermediate openings 4210 of the intermediate inorganic film 4200, and the pixel openings 4312 may be formed to penetrate the mask cell regions 4310. In this case, while performing the deposition process, the vapor deposition material provided from the deposition source 2200 may be deposited on the first electrodes AND of the backplane substrate 3000 through the cell openings 4110, the intermediate openings 4210, and the pixel openings 4312.

As shown in FIG. 16, the mask cell regions 4310 may be arranged in a matrix form along the first direction DR1 and the second direction DR2. In an embodiment, the first direction DR1 may be the first horizontal direction, and the second direction DR2 may be the second horizontal direction perpendicular to the first direction DR1, for example. The mask cell regions 4310 may have a quadrilateral shape as shown in the drawing, for example, and the pixel openings 4312 may be arranged to correspond to the first electrodes AND of any of the first emission areas EA1, the second emission areas EA2, and the third emission areas EA3.

The mask substrate 4100 may include single crystal silicon. In an embodiment, a single crystal silicon substrate having a thickness in the range of about 700 micrometers (μm) to about 800 μm, e.g., about 775 μm, may be used as the mask substrate 4100, for example.

The intermediate inorganic film 4200 and the membrane 4300 may be disposed on the front surface of the mask substrate 4100, and a second intermediate inorganic film 4400 and a rear inorganic film 4500 may be disposed on the rear surface of the mask substrate 4100. In an embodiment, the second intermediate inorganic film 4400 may be disposed on the rear surface of the mask substrate 4100, and the rear inorganic film 4500 may be disposed on the second intermediate inorganic film 4400, for example. The second intermediate inorganic film 4400 and the rear inorganic film 4500 may define second intermediate openings 4410 and rear openings 4510 communicating with the cell openings 4110, respectively, and the rear inorganic film 4500 may function as an etching mask in an etching process for defining the cell openings 4110. In this case, the mask cell regions 4310 may be exposed toward the deposition source 2200 through the intermediate openings 4210, the cell openings 4110, the second intermediate openings 4410, and the rear openings 4510.

In an embodiment, the membrane 4300 may include a material having etching selectivity with respect to the intermediate inorganic film 4200 and the mask substrate 4100. In an embodiment, the intermediate inorganic film 4200 may include silicon oxide (SiOx), and the membrane 4300 may include silicon nitride (SiNx), for example. In an embodiment, the intermediate inorganic film 4200 may include the same material as that of the second intermediate inorganic film 4400, and the membrane 4300 may include the same material as that of the rear inorganic film 4500. In an embodiment, the intermediate inorganic film 4200 and the second intermediate inorganic film 4400 may be formed simultaneously by a thermal oxidation process, and the membrane 4300 and the rear inorganic film 4500 may be formed simultaneously by a chemical vapor deposition (“CVD”) process, for example.

The pixel openings 4312 of the membrane 4300 may be defined by an anisotropic etching process, e.g., a reactive ion etching (“RIE”) process. In an embodiment, after forming, on the membrane 4300, a photoresist pattern exposing the portions where the pixel openings 4312 are to be defined, an RIE process using the photoresist pattern as an etching mask may be performed to define the pixel openings 4312 that expose the intermediate inorganic film 4200, for example. In this case, the pixel openings 4312 may be defined to penetrate the membrane 4300, and the intermediate inorganic film 4200 may function as an etch stop film in the RIE process.

The second intermediate openings 4410 and the rear openings 4510 may be defined by an anisotropic etching process, e.g., an RIE process. In an embodiment, after forming, on the rear inorganic film 4500, a photoresist pattern that exposes portions where the rear openings 4510 are to be defined, an RIE process that uses the photoresist pattern as an etching mask may be performed to define the second intermediate openings 4410 and the rear openings 4510 that expose the rear surface of the mask substrate 4100, for example.

The cell openings 4110 of the mask substrate 4100 may be defined to expose the intermediate inorganic film 4200 by an anisotropic etching process using the second intermediate inorganic film 4400 and the rear inorganic film 4500 as an etching mask. In an embodiment, a single crystal silicon substrate may be used as the mask substrate 4100, and the cell openings 4110 may be defined by a wet etching process using an etchant such as a tetramethylammonium hydroxide (“TMAH”) solution, or a potassium hydroxide (“KOH”) solution, for example. In this case, the <100>crystal direction of the single crystal silicon substrate used as the mask substrate 4100 may be the third direction DR3, and accordingly, the cell openings 4110 may have a width that gradually decreases from the rear surface of the mask substrate 4100 toward the front surface of the mask substrate 4100 through the wet etching process. In an embodiment, the inner side surfaces of the cell openings 4110 may have an inclination of about 54.74° with respect to the rear surface of the mask substrate 4100, for example.

In another embodiment, the cell openings 4110 of the mask substrate 4100 may be defined by a deep DRIE process or a cryogenic etching process. In this case, the cell openings 4110 may extend in the third direction DR3 and may have a constant width.

The intermediate openings 4210 of the intermediate inorganic film 4200 may be defined by a wet etching process after defining the cell openings 4110 of the mask substrate 4100. In an embodiment, when the intermediate inorganic film 4200 includes silicon oxide (SiOx), the intermediate openings 4210 may be defined by a wet etching process that uses an etchant such as buffered oxide etchant (“BOE”), diluted hydrofluoric acid (“HF”), or the like, for example. As a result, the pixel openings 4312 of the membrane 4300 may communicate with the cell openings 4110 of the mask substrate 4100 through the intermediate openings 4210 of the intermediate inorganic film 4200.

In another embodiment, the second intermediate inorganic film 4400 may be omitted. In this case, the rear inorganic film 4500 may be disposed on the rear surface of the mask substrate 4100. Additionally, the intermediate inorganic film 4200 may be formed by a thermal oxidation process or a CVD process, and the rear inorganic film 4500 may be formed simultaneously with the membrane 4300 or separately from the membrane 4300. As another example, both the intermediate inorganic film 4200 and the second intermediate inorganic film 4400 may be omitted. In this case, the membrane 4300 may be disposed on the front surface of the mask substrate 4100, and the rear inorganic film 4500 may be disposed on the rear surface of the mask substrate 4100. Additionally, the rear inorganic film 4500 may be formed simultaneously with the membrane 4300 or may be formed separately from the membrane 4300.

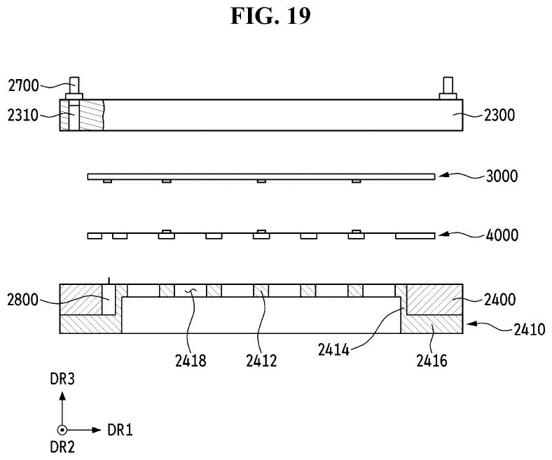

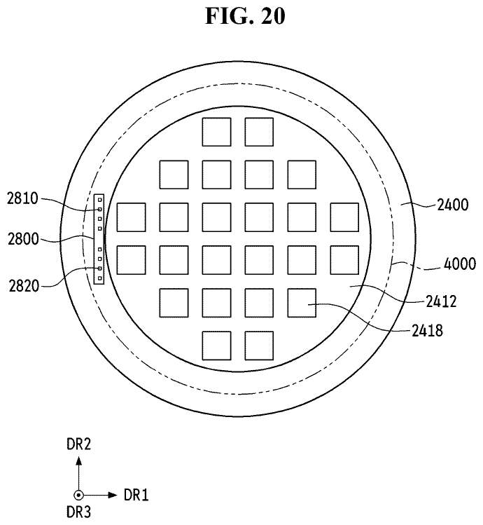

FIG. 19 is a schematic cross-sectional view illustrating the substrate chuck and mask chuck shown in FIG. 14. FIG. 20 is a schematic plan view illustrating the mask chuck shown in FIG. 19.

Referring to FIGS. 14, 19, and 20, the deposition apparatus 2000 in an embodiment may include a lattice support 2410 for supporting the mask cell regions 4310 and the grid region 4320 of the deposition mask 4000. In an embodiment, the lattice support 2410 may include a lattice plate 2412 for supporting the rib region 4120 of the mask substrate 4100, a support ring 2414 extending downward from the edge portion of the lattice plate 2412, and a flange 2416 surrounding the lower portion of the support ring 2414, for example. In an embodiment, the lattice plate 2412 may have a disc shape and may define openings 2418 corresponding to the cell openings 4110 of the mask substrate 4100, for example. In this case, the lattice plate 2412 and the support ring 2414 may be disposed in the mask chuck 2400, and the mask chuck 2400 may be disposed on the flange 2416. Further, the flange 2416 of the lattice support 2410 may be disposed on the piezo actuator 2610 of the mask chuck driver 2600.

After the backplane substrate 3000 and the deposition mask 4000 are loaded onto the substrate chuck 2300 and the mask chuck 2400, respectively, the substrate chuck driver 2500 may position the backplane substrate 3000 on the deposition mask 4000. In an embodiment, the second actuator 2530 may lower the substrate chuck 2300 such that the backplane substrate 3000 becomes closer (adjacent) to the deposition mask 4000, for example. The hexapod actuator 2510 may adjust the gap between the backplane substrate 3000 and the deposition mask 4000, and may adjust the inclination of the substrate chuck 2300 to adjust the parallelism between the substrate chuck 2300 and the mask chuck 2400.

In an embodiment, the deposition apparatus 2000 may include a plurality of gap sensors 2700 for measuring the gaps between the substrate chuck 2300 and the mask chuck 2400. In an embodiment, a plurality of gap sensors 2700 for measuring gaps between the substrate chuck 2300 and the mask chuck 2400 may be arranged on the edge portions of the substrate chuck 2300, and the gap sensors 2700 may measure distances to the mask chuck 2400 via through-holes 2310 penetrating the edge portions of the substrate chuck 2300, for example.

The hexapod actuator 2510 may adjust the parallelism between the substrate chuck 2300 and the mask chuck 2400 based on the measurement values of the gap sensors 2700. In an embodiment, the hexapod actuator 2510 may adjust the height of the substrate chuck 2300 to a first height such that the gap between the backplane substrate 3000 and the deposition mask 4000 becomes several hundreds of μm, e.g., about 100 μm to about 200 μm, and may adjust the inclination of the substrate chuck 2300 based on the measurement values of the gap sensors 2700, for example. In an embodiment, capacitive proximity sensors or confocal sensors may be used as the gap sensors 2700, and the hexapod actuator 2510 may adjust the parallelism between the substrate chuck 2300 and the mask chuck 2400 by adjusting the inclination of the substrate chuck 2300, for example. As a result, the parallelism between the backplane substrate 3000 supported by the substrate chuck 2300 and the deposition mask 4000 supported by the mask chuck 2400 may be adjusted.

In an embodiment, at least one first measurement electrode 3100 may be disposed on the backplane substrate 3000, and at least one second measurement electrode 4600 corresponding to the first measurement electrode 3100 of the backplane substrate 3000 may be disposed on the deposition mask 4000. In an embodiment, four first measurement electrodes 3100 may be arranged on the backplane substrate 3000 as illustrated in FIG. 15, and four second measurement electrodes 4600 may be arranged on the deposition mask 4000 as illustrated in FIG. 16, for example. However, the number of first measurement electrodes 3100 and the number of second measurement electrodes 4600 may be variously changed, and the scope of the disclosure is not limited thereby.

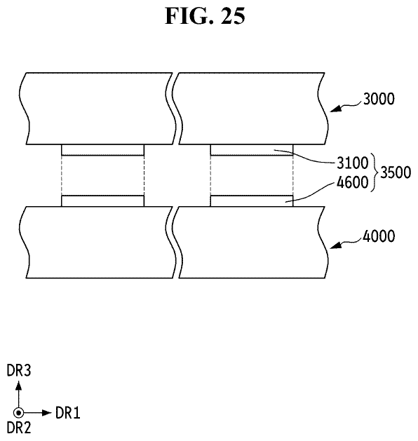

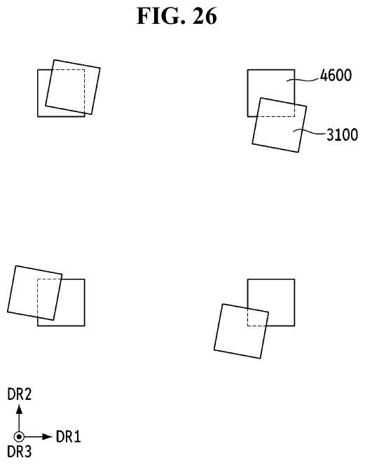

In an embodiment, when the backplane substrate 3000 is disposed on the deposition mask 4000, a capacitor may be formed between the backplane substrate 3000 and the deposition mask 4000. In an embodiment, capacitors 3500 (refer to FIGS. 25 and 26) including the first measurement electrodes 3100 and the second measurement electrodes 4600 may be formed between the backplane substrate 3000 and the deposition mask 4000, for example. In an embodiment, the backplane substrate 3000 and the deposition mask 4000 may be aligned with each other based on the capacitance between the first measurement electrodes 3100 and the second measurement electrodes 4600.

In an embodiment, as illustrated in FIG. 15, the first measurement electrodes 3100 may be arranged on the scribe lane region 3020 of the backplane substrate 3000. In an embodiment, the first measurement electrodes 3100 may be arranged on a pixel defining film PDL of the backplane substrate 3000, and may have a thickness of about several tens to hundreds of nm, for example. The first measurement electrodes 3100 may include a conductive material such as metal, metal oxide, metal nitride, or the like. In an embodiment, the first measurement electrodes 3100 may include any one of copper (Cu), aluminum (Al), tungsten (W), molybdenum (Mo), chromium (Cr), gold (Au), titanium (Ti), nickel (Ni), and neodymium (Nd), or an alloy including any one of them, for example. In an embodiment, the first measurement electrodes 3100 may include aluminum (Al) or a transparent conductive oxide such as ITO, ZnO, IZO, or the like, for example. Further, e.g., each of the first measurement electrodes 3100 may have a quadrilateral shape, a quadrangular shape, e.g., rectangular shape, a circular shape, a bar shape extending in the first direction DR1 or the second direction DR2, or the like in a plan view.

First contact pads 3110 may be arranged on the edge portion of the backplane substrate 3000, and the first measurement electrodes 3100 and the first contact pads 3110 may be connected to each other by first connection lines 3120. In an embodiment, the first connection lines 3120 may extend along the scribe lane region 3020 of the backplane substrate 3000, for example. The first contact pads 3110 and the first connection lines 3120 may include the same material as that of the first measurement electrodes 3100. In an embodiment, the first contact pads 3110 and the first connection lines 3120 may be formed simultaneously with the first measurement electrodes 3100, for example.

In an embodiment, a conductive material layer (not shown) may be formed on the pixel defining film PDL, and the first measurement electrodes 3100, the first contact pads 3110, and the first connection lines 3120 may be formed on the pixel defining film PDL by patterning the conductive material layer, for example. The conductive material layer may be patterned by a photolithography process and an anisotropic etching process. In another embodiment, the first measurement electrodes 3100, the first contact pads 3110, and the first connection lines 3120 may be formed by a damascene process.

In another embodiment, the first measurement electrodes 3100, the first contact pads 3110, and the first connection lines 3120 may include the same material as that of the first electrodes AND of the light-emitting elements LE. In an embodiment, the first measurement electrodes 3100, the first contact pads 3110, and the first connection lines 3120 may be formed simultaneously with the first electrodes AND of the light-emitting elements LE, for example. In this case, the pixel defining film PDL may be disposed on the first measurement electrodes 3100, the first contact pads 3110, and the first connection lines 3120, and may define openings (not shown) exposing the first contact pads 3110.

In an embodiment, as illustrated in FIG. 16, the second measurement electrodes 4600 corresponding to the first measurement electrodes 3100 may be arranged on the deposition mask 4000. The position of the second measurement electrodes 4600 on the deposition mask 4000 may be the same as the position of the first measurement electrodes 3100 on the backplane substrate 3000. In an embodiment, the second measurement electrodes 4600 may be arranged on the grid region 4320 of the deposition mask 4000 to respectively correspond to the first measurement electrodes 3100, and may have a thickness of several tens to several hundreds of nm, for example.

The second measurement electrodes 4600 may include a conductive material such as metal, metal oxide, metal nitride, or the like. In an embodiment, the second measurement electrodes 4600 may include any one of copper (Cu), aluminum (Al), tungsten (W), molybdenum (Mo), chromium (Cr), gold (Au), titanium (Ti), nickel (Ni), and neodymium (Nd), or an alloy including any one of them, for example. In an embodiment, the second measurement electrodes 4600 may include aluminum (Al) or a transparent conductive oxide such as ITO, ZnO, IZO, or the like, for example. Further, the second measurement electrodes 4600 may have the same shape and the same area as the first measurement electrodes 3100. In an embodiment, each of the second measurement electrodes 4600 may have a quadrilateral shape, a quadrangular shape, e.g., rectangular shape, a circular shape, a bar shape extending in the first direction DR1 or the second direction DR2, or the like in a plan view, for example.

Second contact pads 4610 may be arranged on the edge portion of the deposition mask 4000, and the second measurement electrodes 4600 and the second contact pads 4610 may be connected to each other by second connection lines 4620. In an embodiment, the second connection lines 4620 may extend along the grid region 4320 of the deposition mask 4000, for example. The second contact pads 4610 and the second connection lines 4620 may include the same material as that of the second measurement electrodes 4600. In an embodiment, the second contact pads 4610 and the second connection lines 4620 may be formed simultaneously with the second measurement electrodes 4600, for example.

In an embodiment, a conductive material layer (not shown) may be formed on the membrane 4300, and the second measurement electrodes 4600, the second contact pads 4610, and the second connection lines 4620 may be formed on the membrane 4300 by patterning the conductive material layer, for example. The conductive material layer may be patterned by a photolithography process and an anisotropic etching process. In another embodiment, the second measurement electrodes 4600, the second contact pads 4610, and the second connection lines 4620 may be formed by a damascene process.

In another embodiment, the second measurement electrodes 4600, the second contact pads 4610, and the second connection lines 4620 may be arranged on the intermediate inorganic film 4200. In an embodiment, a conductive material layer (not shown) may be formed on the intermediate inorganic film 4200, and the second measurement electrodes 4600, the second contact pads 4610, and the second connection lines 4620 may be formed on the intermediate inorganic film 4200 by patterning the conductive material layer, for example. In this case, the membrane 4300 may be disposed on the second measurement electrodes 4600, the second contact pads 4610, the second connection lines 4620, and the intermediate inorganic film 4200.

Referring to FIGS. 19 and 20, the deposition apparatus 2000 may include a sensor 2800 (or capacitive sensor) for measuring the capacitance between the first measurement electrodes 3100 and the second measurement electrodes 4600. In an embodiment, the sensor 2800 may be disposed in the mask chuck 2400 and may be electrically connected to the first contact pads 3110 and the second contact pads 4610, for example.

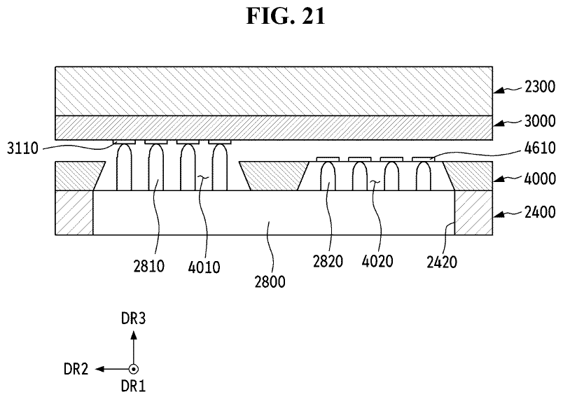

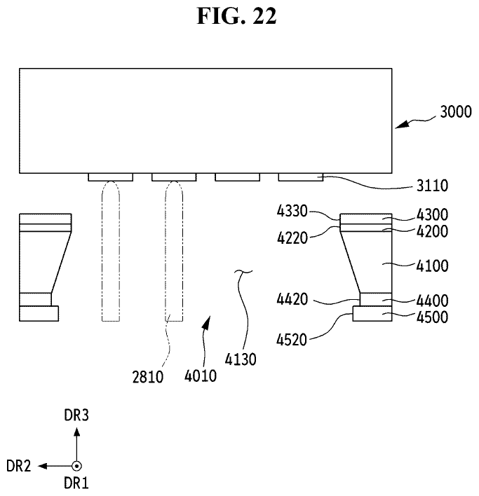

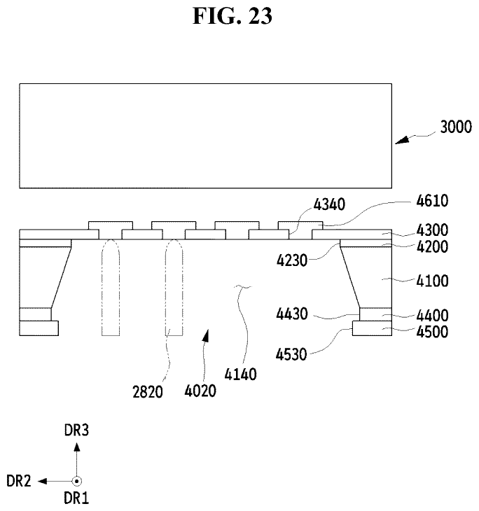

FIG. 21 is a schematic enlarged cross-sectional view illustrating a sensor shown in FIGS. 19 and 20. FIG. 22 is a schematic enlarged cross-sectional view illustrating a through-opening shown in FIG. 21. FIG. 23 is a schematic enlarged cross-sectional view illustrating a contact opening shown in FIG. 21.

Referring to FIGS. 19 to 23, a slot 2420 into which the sensor 2800 is inserted may be provided at the edge portion of the mask chuck 2400. In an embodiment, the sensor 2800 may include first probe pins 2810 for connection with the first measurement electrodes 3100 and second probe pins 2820 for connection with the second measurement electrodes 4600. Further, the deposition mask 4000 may define a through-opening 4010 into which the first probe pins 2810 are inserted and a contact opening 4020 into which the second probe pins 2820 are inserted. In an embodiment, the deposition mask 4000 may be placed on the mask chuck 2400 such that the through-opening 4010 and the contact opening 4020 are defined on the sensor 2800, and the first probe pins 2810 and the second probe pins 2820 may be inserted into the through-opening 4010 and the contact opening 4020, respectively, for example.

The through-opening 4010 may penetrate the edge portion of the deposition mask 4000. When the backplane substrate 3000 is disposed on the deposition mask 4000, the first probe pins 2810 may pass through the through-opening 4010 to contact the first contact pads 3110 of the backplane substrate 3000, so that the first measurement electrodes 3100 and the sensor 2800 may be electrically connected to each other. The through-opening 4010 may penetrate the rear inorganic film 4500, the second intermediate inorganic film 4400, the mask substrate 4100, the intermediate inorganic film 4200, and the membrane 4300 of the deposition mask 4000. In an embodiment, as illustrated in FIG. 22, the through-opening 4010 may define a first through-opening 4520 penetrating the rear inorganic film 4500, a second through-opening 4420 penetrating the second intermediate inorganic film 4400, a third through-opening 4130 penetrating the mask substrate 4100, a fourth through-opening 4220 penetrating the intermediate inorganic film 4200, and a fifth through-opening 4330 penetrating the membrane 4300, for example. In an embodiment, the fifth through-opening 4330 may be defined simultaneously with the pixel openings 4312, the first through-opening 4520 and the second through-opening 4420 may be defined simultaneously with the rear openings 4510 and the second intermediate openings 4410, for example. The third through-opening 4130 may be defined simultaneously with the cell openings 4110, and the fourth through-opening 4220 may be defined simultaneously with the intermediate openings 4210.

In another embodiment, although not shown, the through-opening 4010 may be pre-provided at a single crystal silicon substrate used as the mask substrate 4100. In an embodiment, the through-opening 4010 may be pre-defined by a laser cutting process when the single crystal silicon substrate is in a bare wafer state, for example. In another embodiment, the through-opening 4010 may be defined by a laser cutting process after the deposition mask 4000 is manufactured. In another embodiment, although not shown, a recess (not shown) may be defined at the side portion of the deposition mask 4000 by a laser cutting process, instead of the through-opening 4010.

The contact opening 4020 may be defined next (adjacent) to the through-opening 4010. The contact opening 4020 may penetrate the rear inorganic film 4500, the second intermediate inorganic film 4400, the mask substrate 4100, and the intermediate inorganic film 4200 of the deposition mask 4000, and may expose the membrane 4300 and the second contact pads 4610. In an embodiment, as illustrated in FIG. 23, the contact opening 4020 may include a first contact opening 4530 penetrating the rear inorganic film 4500, a second contact opening 4430 penetrating the second intermediate inorganic film 4400, a third contact opening 4140 penetrating the mask substrate 4100, and a fourth contact opening 4230 penetrating the intermediate inorganic film 4200, for example. In an embodiment, the first contact opening 4530 and the second contact opening 4430 may be defined simultaneously with the rear openings 4510 and the second intermediate openings 4410, for example. The third contact opening 4140 may be defined simultaneously with the cell openings 4110, and the fourth contact opening 4230 may be defined simultaneously with the intermediate openings 4210.

In an embodiment, the membrane 4300 may define pad openings 4340. In an embodiment, the pad openings 4340 may be defined by an anisotropic etching process such as an RIE process to expose the intermediate inorganic film 4200, and a conductive material layer for forming the second contact pads 4610 may be formed to fill the pad openings 4340, for example. The conductive material layer may be patterned such that the second contact pads 4610 are disposed on the pad openings 4340, and the contact opening 4020 may be defined to expose the second contact pads 4610. In an embodiment, after the second contact pads are formed, the first, second, third, and fourth contact openings 4530, 4430, 4140, and 4230 may be sequentially defined, for example.

In an embodiment, the deposition mask 4000 may be placed on the mask chuck 2400 such that the second probe pins 2820 are inserted into the contact opening 4020. In this case, the second probe pins 2820 may be brought into contact with the second contact pads 4610 exposed through the contact opening 4020, so that the second measurement electrodes 4600 and the sensor 2800 may be electrically connected to each other.

In an embodiment, as shown in FIGS. 20 and 21, the sensor 2800 has a bar shape extending in the second direction, but the shape of the sensor 2820 may be variously changed and the scope of the disclosure is not be limited by the shape of the sensor 2820.

In an embodiment, after the parallelism between the substrate chuck 2300 and the mask chuck 2400 is adjusted, the hexapod actuator 2510 may adjust the height of the substrate chuck 2300 to a second height such that the gap between the backplane substrate 3000 and the deposition mask 4000 becomes several tens of μm, e.g., about 10 μm to about 50 μm, for example. In an embodiment, the hexapod actuator 2510 may adjust the height of the backplane substrate 3000 such that the gap between the first measurement electrodes 3100 and the second measurement electrodes 4600 becomes several tens of μm, e.g., about 10 μm to about 50 μm, for example.

In an embodiment, after the height of the substrate chuck 2300 is adjusted to the second height, the parallelism between the substrate chuck 2300 and the mask chuck 2400 may be secondarily adjusted. In an embodiment, although not shown, a plurality of second gap sensors (not shown) may be arranged on the edge portions of the substrate chuck 2300, and the second gap sensors may measure the distance to the mask chuck 2400 through the through-holes penetrating the edge portions of the substrate chuck 2300, for example. The hexapod actuator 2510 may adjust the inclination of the substrate chuck 2300 based on the measurement values of the second gap sensors, so that the parallelism between the substrate chuck 2300 and the mask chuck 2400 may be secondarily adjusted. At this time, the second gap sensors may have a resolution higher than that of the gap sensors 2700. In an embodiment, capacitive proximity sensors may be used as the gap sensors 2700, and confocal sensors may be used as the second gap sensors, for example. By secondarily adjusting the parallelism between the substrate chuck 2300 and the mask chuck 2400 as described above, the parallelism between the backplane substrate 3000 and the deposition mask 4000 may be adjusted more precisely.

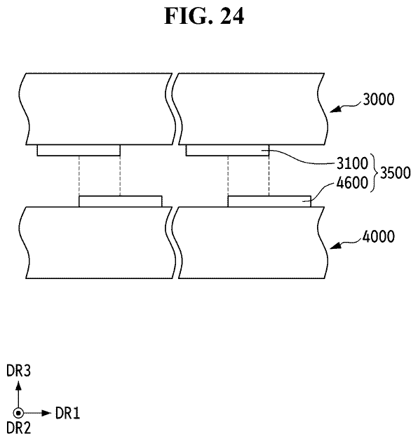

FIGS. 24 and 25 are schematic diagrams illustrating states in which the first measurement electrodes and the second measurement electrodes illustrated in FIGS. 15 and 16 face each other.

Referring to FIGS. 24 and 25, when the backplane substrate 3000 is disposed on the deposition mask 4000 as described above, the first measurement electrodes 3100 and the second measurement electrodes 4600 may face each other, thereby forming the capacitors 3500 including the first measurement electrodes 3100 and the second measurement electrodes 4600 between the backplane substrate 3000 and the deposition mask 4000. When the first measurement electrodes 3100 and the second measurement electrodes 4600 face each other, the capacitance between the first measurement electrodes 3100 and the second measurement electrodes 4600 may be proportional to the area where the first measurement electrodes 3100 and the second measurement electrodes 4600 face each other. In an embodiment, when the first measurement electrodes 3100 and the second measurement electrodes 4600 are misaligned in the third direction DR3 as illustrated in FIG. 24, the capacitance between the first measurement electrodes 3100 and the second measurement electrodes 4600 may decrease, and when the first measurement electrodes 3100 and the second measurement electrodes 4600 are aligned with each other in the third direction DR3 as illustrated in FIG. 25, the capacitance between the first measurement electrodes 3100 and the second measurement electrodes 4600 may increase, for example.

In an embodiment, the capacitance between the first measurement electrodes 3100 and the second measurement electrodes 4600 may be measured to align the backplane substrate 3000 and the deposition mask 4000 with each other. Further, the azimuth and position of the backplane substrate 3000 and/or the deposition mask 4000 may be adjusted such that the capacitance between the first measurement electrodes 3100 and the second measurement electrodes 4600 becomes maximum, thereby aligning the backplane substrate 3000 and the deposition mask 4000 with each other. In an embodiment, the hexapod actuator 2510 may rotate and horizontally move the substrate chuck 2300 such that the capacitance between the first measurement electrodes 3100 and the second measurement electrodes 4600 becomes maximum, for example. In another embodiment, the piezo actuator 2610 may rotate and horizontally move the mask chuck 2400 such that the capacitance between the first measurement electrodes 3100 and the second measurement electrodes 4600 becomes maximum.

In an embodiment, the gap between the backplane substrate 3000 and the deposition mask 4000 may be maintained constant while aligning the backplane substrate 3000 and the deposition mask 4000 with each other. In an embodiment, the height of the substrate chuck 2300, i.e., the position of the substrate chuck 2300 in the third direction, may be maintained constant while aligning the backplane substrate 3000 and the deposition mask 4000 with each other, for example.

FIGS. 26 to 29 are schematic plan views illustrating a method of aligning a backplane substrate and a deposition mask with each other using the first measurement electrodes and the second measurement electrodes illustrated in FIGS. 15 and 16.

Referring to FIGS. 26 to 29, in an embodiment, the first measurement electrodes 3100 and the second measurement electrodes 4600 may each have a square shape, and may have the same area (or size). In another embodiment, the first measurement electrodes 3100 and the second measurement electrodes 4600 may each have a circular shape, and may have the same area (or size). In an embodiment, when the first measurement electrodes 3100 and the second measurement electrodes 4600 are misaligned with each other in the third direction DR3 as illustrated in FIG. 26, i.e., when the first measurement electrodes 3100 and the second measurement electrodes 4600 partially overlap each other in the third direction DR3, the capacitance values between the first measurement electrodes 3100 and the second measurement electrodes 4600 may be different from each other.

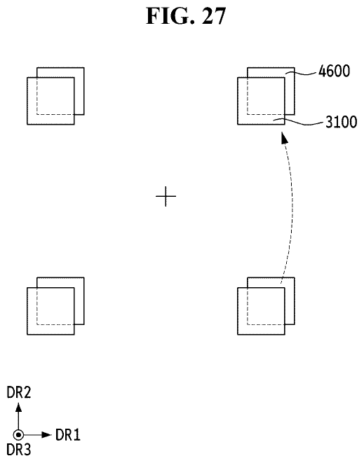

In an embodiment, the hexapod actuator 2510 may rotate the substrate chuck 2300 such that the capacitance values between the first measurement electrodes 3100 and the second measurement electrodes 4600 become all equal in order to perform azimuth alignment between the backplane substrate 3000 and the deposition mask 4000 as illustrated in FIG. 27. In an embodiment, when the azimuth of the backplane substrate 3000 becomes equal to the azimuth of the deposition mask 4000, all the areas where the first measurement electrodes 3100 and the second measurement electrodes 4600 overlap each other in the third direction DR3 may become the same and, thus, all the capacitance values between the first measurement electrodes 3100 and the second measurement electrodes 4600 may become the same, for example.

In an embodiment, the deposition apparatus 2000 may include a controller 2900 (refer to FIG. 14) for controlling the operation of the substrate chuck 2300, the mask chuck 2400, the substrate chuck driver 2500, the mask chuck driver 2600, or the like. In an embodiment, the capacitance values between the first measurement electrodes 3100 and the second measurement electrodes 4600 may be measured by the sensor 2800, and the controller 2900 may control the operation of the substrate chuck driver 2500 and/or the mask chuck driver 2600 based on the capacitance values measured by the sensor 2800, for example. In an embodiment, the substrate chuck driver 2500 and the mask chuck driver 2600 may be collectively referred to as a chuck driver.

In an embodiment, the hexapod actuator 2510 may rotate the substrate chuck 2300 in a clockwise direction or a counterclockwise direction, and the capacitance values between the first measurement electrodes 3100 and the second measurement electrodes 4600 may be measured by the sensor 2800, for example. While rotating the substrate chuck 2300, all the capacitance values between the first measurement electrodes 3100 and the second measurement electrodes 4600 may be changed, and the controller 2900 may detect the azimuth of the substrate chuck 2300 at which the capacitance values between the first measurement electrodes 3100 and the second measurement electrodes 4600 become all equal. Further, the controller 2900 may control the operation of the substrate chuck driver 2500 such that the substrate chuck 2300 has the detected azimuth, thereby performing the azimuth alignment between the backplane substrate 3000 and the deposition mask 4000.

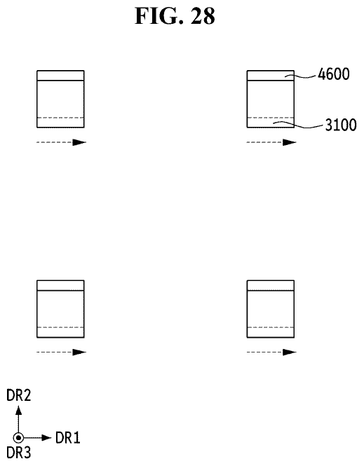

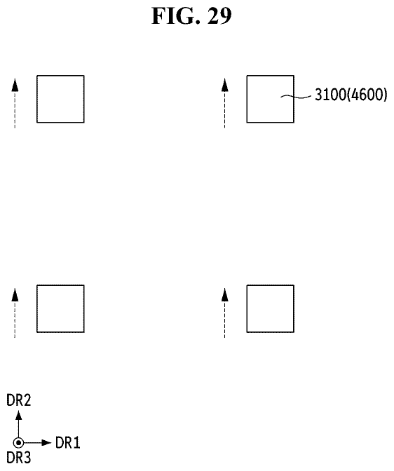

In an embodiment, the hexapod actuator 2510 may move the substrate chuck 2300 in the first direction DR1 and the second direction DR2 such that all the capacitance values between the first measurement electrodes 3100 and the second measurement electrodes 4600 become maximum in order to perform positional alignment between the backplane substrate 3000 and the deposition mask 4000, as illustrated in FIGS. 28 and 29.

In an embodiment, the hexapod actuator 2510 may move the substrate chuck 2300 in the first direction DR1 as illustrated in FIG. 28, and the capacitance values between the first measurement electrodes 3100 and the second measurement electrodes 4600 may be measured by the sensor 2800, for example. While moving the substrate chuck 2300 in the first direction DR1, the capacitance values between the first measurement electrodes 3100 and the second measurement electrodes 4600 may be changed, and the controller 2900 may detect a first direction position of the substrate chuck 2300 at which all the capacitance values between the first measurement electrodes 3100 and the second measurement electrodes 4600 become maximum. Further, the controller 2900 may control the operation of the substrate chuck driver 2500 such that the substrate chuck 2300 is moved to the detected first direction position, so that first direction positional alignment between the backplane substrate 3000 and the deposition mask 4000 may be performed.

Further, the hexapod actuator 2510 may move the substrate chuck 2300 in the second direction DR2 as illustrated in FIG. 29, and the capacitance values between the first measurement electrodes 3100 and the second measurement electrodes 4600 may be measured by the sensor 2800. While moving the substrate chuck 2300 in the second direction DR2, the capacitance values between the first measurement electrodes 3100 and the second measurement electrodes 4600 may be changed, and the controller 2900 may detect a second direction position of the substrate chuck 2300 at which all the capacitance values between the first measurement electrodes 3100 and the second measurement electrodes 4600 become maximum. Further, the controller 2900 may control the operation of the substrate chuck driver 2500 such that the substrate chuck 2300 is moved to the detected second direction position, so that second direction positional alignment between the backplane substrate 3000 and the deposition mask 4000 may be performed.

In another embodiment, the piezo actuator 2610 may rotate the mask chuck 2400 such that the capacitance values between the first measurement electrodes 3100 and the second measurement electrodes 4600 become all equal in order to perform azimuth alignment between the backplane substrate 3000 and the deposition mask 4000. Further, the piezo actuator 2610 may move the mask chuck 2400 in the first direction DR1 and the second direction DR2 such that all the capacitance values between the first measurement electrodes 3100 and the second measurement electrodes 4600 become maximum in order to perform positional alignment between the backplane substrate 3000 and the deposition mask 4000. At this time, the capacitance values between the first measurement electrodes 3100 and the second measurement electrodes 4600 may be measured by the sensor 2800, and the operation of the piezo actuator 2610 may be controlled by the controller 2900.

In another embodiment, the azimuth alignment and positional alignment between the backplane substrate 3000 and the deposition mask 4000 may be performed by the hexapod actuator 2510 and the piezo actuator 2610. In an embodiment, the hexapod actuator 2510 may rotate the substrate chuck 2300 and, at the same time, the piezo actuator 2610 may move the mask chuck 2400, for example. In this case, the controller 2900 may detect the azimuth of the backplane substrate 3000 and the position of the deposition mask 4000 at which all the capacitance values between the first measurement electrodes 3100 and the second measurement electrodes 4600 become maximum. In an alternative embodiment, the hexapod actuator 2510 may move the substrate chuck 2300 and, at the same time, the piezo actuator 2610 may rotate the mask chuck 2400. In this case, the controller 2900 may detect the position of the backplane substrate 3000 and the azimuth of the deposition mask 4000 at which all the capacitance values between the first measurement electrodes 3100 and the second measurement electrodes 4600 become maximum.

Further, as described above, after the azimuth alignment between the backplane substrate 3000 and the deposition mask 4000 is performed, the positional alignment between the backplane substrate 3000 and the deposition mask 4000 is performed. However, unlike the above, the azimuth alignment between the backplane substrate 3000 and the deposition mask 4000 may be performed after the positional alignment between the backplane substrate 3000 and the deposition mask 4000 is performed.

In an embodiment, the hexapod actuator 2510 may move the substrate chuck 2300 in the first direction DR1 and the second direction DR2, and the capacitance values between the first measurement electrodes 3100 and the second measurement electrodes 4600 may be measured by the sensor 2800, for example. While moving the substrate chuck 2300 in the first direction DR1 and the second direction DR2, the capacitance values between the first measurement electrodes 3100 and the second measurement electrodes 4600 may be changed, and the controller 2900 may detect the position of the substrate chuck 2300 at which the capacitance values between the first measurement electrodes 3100 and the second measurement electrodes 4600 become all equal. Further, the controller 2900 may control the operation of the substrate chuck driver 2500 such that the substrate chuck 2300 is moved to the detected position, thereby performing positional alignment between the backplane substrate 3000 and the deposition mask 4000.

Subsequently, the hexapod actuator 2510 may rotate the substrate chuck 2300 in a clockwise direction or a counterclockwise direction, and the capacitance values between the first measurement electrodes 3100 and the second measurement electrodes 4600 may be measured by the sensor 2800. While rotating the substrate chuck 2300, all the capacitance values between the first measurement electrodes 3100 and the second measurement electrodes 4600 may be changed, and the controller 2900 may detect the azimuth of the substrate chuck 2300 at which the capacitance values between the first measurement electrodes 3100 and the second measurement electrodes 4600 become all maximum. Further, the controller 2900 may control the operation of the substrate chuck driver 2500 such that the substrate chuck 2300 has the detected azimuth, thereby performing the azimuth alignment between the backplane substrate 3000 and the deposition mask 4000.

In another embodiment, the positional alignment and azimuth alignment between the backplane substrate 3000 and the deposition mask 4000 may be performed by the mask chuck driver 2600. In an embodiment, the positional alignment and azimuth alignment between the backplane substrate 3000 and the deposition mask 4000 may be sequentially performed by the piezo actuator 2610, for example.

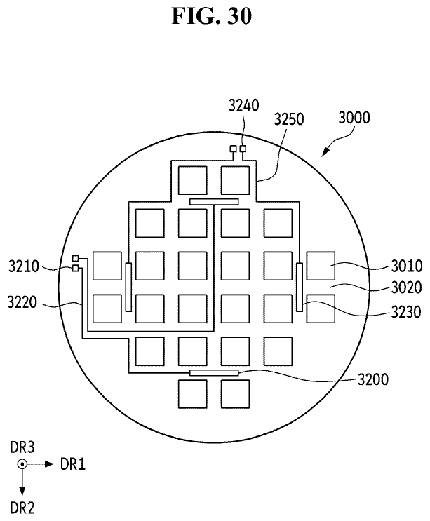

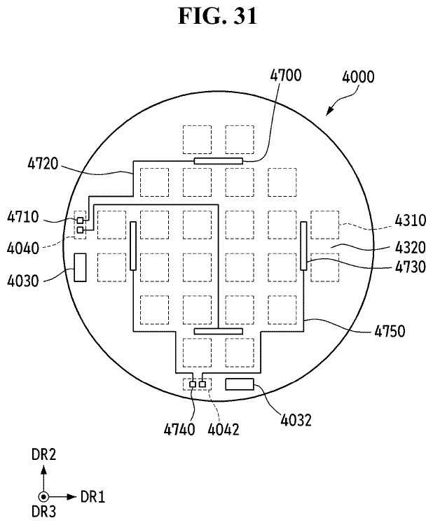

FIG. 30 is a schematic bottom view illustrating another embodiment of the backplane substrate illustrated in FIG. 15. FIG. 31 is a schematic plan view illustrating another embodiment of the deposition mask shown in FIG. 16.

Referring to FIG. 30, the backplane substrate 3000 may include at least one first measurement electrode 3200 and at least one third measurement electrode 3230. In an embodiment, the backplane substrate 3000 may include the first measurement electrodes 3200 extending in the first direction DR1 and arranged on the scribe lane region 3020 and the third measurement electrodes 3230 extending in the second direction DR2 and arranged on the scribe lane region 3020, for example. As illustrated, the backplane substrate 3000 includes two first measurement electrodes 3200 and two third measurement electrodes 3230, but the number of first measurement electrodes 3200 and third measurement electrodes 3230 may be changed and the scope of the disclosure may not be limited thereby.

The backplane substrate 3000 may include first contact pads 3210, third contact pads 3240, first connection lines 3220, and third connection lines 3250. In an embodiment, the first contact pads 3210 and the third contact pads 3240 may be arranged on the edge portions of the backplane substrate 3000, for example. The first connection lines 3220 may be arranged on the scribe lane region 3020 and may connect the first measurement electrodes 3200 and the first contact pads 3210. The third connection lines 3250 may be arranged on the scribe lane region 3020 and may connect the third measurement electrodes 3230 and the third contact pads 3240.

In an embodiment, except the first and third measurement electrodes 3200 and 3230, the first and third contact pads 3210 and 3240, and the first and third connection lines 3220 and 3250, remaining (the other) elements of the backplane substrate 3000 are substantially the same as those described above with reference to FIG. 15, so that detailed description thereof will be omitted.

Referring to FIG. 31, the deposition mask 4000 may include at least one second measurement electrode 4700 and at least one fourth measurement electrode 4730. In an embodiment, the deposition mask 4000 may include the second measurement electrodes 4700 respectively corresponding to the first measurement electrodes 3200 and the fourth measurement electrodes 4730 respectively corresponding to the third measurement electrodes 3230, for example.

The second measurement electrodes 4700 may be arranged at the same position as the first measurement electrodes 3200 in a plan view and may have the same shape and size as the first measurement electrodes 3200. In an embodiment, the second measurement electrodes 4700 may be arranged on the grid region 4320 of the deposition mask 4000 and may have a quadrangular shape, e.g., rectangular shape or a bar shape extending in the first direction DR1, for example. The fourth measurement electrodes 4730 may be arranged at the same position as the third measurement electrodes 3230 in a plan view and may have the same shape and size as the third measurement electrodes 3230. In an embodiment, the fourth measurement electrodes 4730 may be arranged on the grid region 4320 of the deposition mask 4000 and may have a quadrangular shape, e.g., rectangular shape or a bar shape extending in the second direction DR2, for example. As illustrated, the deposition mask 4000 includes two second measurement electrodes 4700 and two fourth measurement electrodes 4730, but the number of second measurement electrodes 4700 and fourth measurement electrodes 4730 may be changed and the scope of the disclosure is not limited thereby.

The deposition mask 4000 may include second contact pads 4710, fourth contact pads 4740, second connection lines 4720, and fourth connection lines 4750. In an embodiment, the second contact pads 4710 and the fourth contact pads 4740 may be arranged on the edge portions of the deposition mask 4000, for example. The second connection lines 4720 may be arranged on the grid region 4320 and may connect the second measurement electrodes 4700 and the second contact pads 4710. The fourth connection lines 4750 may be arranged on the grid region 4320 and may connect the fourth measurement electrodes 4730 and the fourth contact pads 4740.

In an embodiment, except the second and fourth measurement electrodes 4700 and 4730, the second and fourth contact pads 4710 and 4740, and the second and fourth connection lines 4720 and 4750, remaining (the other) elements of the deposition mask 4000 are substantially the same as those described above with reference to FIGS. 16 to 18, so that detailed description thereof will be omitted.

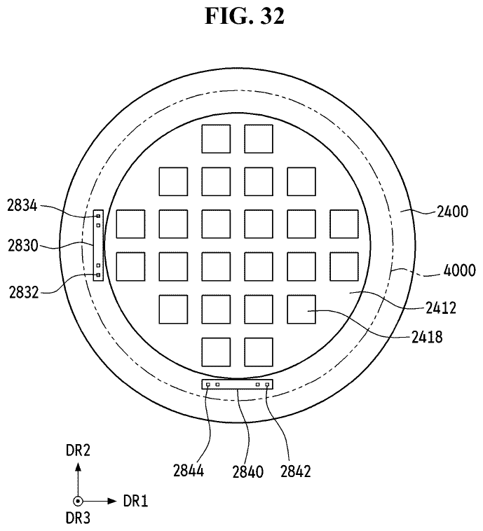

FIG. 32 is a schematic plan view illustrating another embodiment of the sensor shown in FIG. 20.

Referring to FIG. 32, the deposition apparatus 2000 may include a first sensor 2830 for measuring capacitance values between the first measurement electrodes 3200 and the second measurement electrodes 4700 and a second sensor 2840 for measuring capacitance values between the third measurement electrodes 3230 and the fourth measurement electrodes 4730. In an embodiment, the first sensor 2830 and the second sensor 2840 may be disposed in the mask chuck 2400 and, to this end, slots into which the first sensor 2830 and the second sensor 2840 are respectively inserted may be provided at the edge portions of the mask chuck 2400, for example.

The first sensor 2830 may include first probe pins 2832 connected to the first contact pads 3210 and second probe pins 2834 connected to the second contact pads 4710, and the deposition mask 4000 may define a first through-opening 4030 through which the first probe pins 2832 pass and a first contact opening 4040 into which the second probe pins 2834 are inserted. The second sensor 2840 may include third probe pins 2842 connected to the third contact pads 3240 and fourth probe pins 2844 connected to the fourth contact pads 4740, and the deposition mask 4000 may define a second through-opening 4032 through which the third probe pins 2842 pass and a second contact opening 4042 through which the fourth probe pins 2844 are inserted.

In an embodiment, each of the first sensor 2830 and the second sensor 2840 is substantially the same as the sensor 2800 described above with reference to FIG. 20, so that detailed description thereof will be omitted. Each of the first through-opening 4030 and the second through-opening 4032 is substantially the same as the through-opening 4010 described above with reference to FIGS. 21 and 22, so that detailed description thereof will be omitted. In addition, each of the first contact opening 4040 and the second contact opening 4042 is substantially the same as the contact opening 4020 described above with reference to FIGS. 21 and 23, so that detailed description thereof will be omitted.

In another embodiment, although not shown, the capacitance values between the first measurement electrodes 3200 and the second measurement electrodes 4700 and the capacitance values between the third measurement electrodes 3230 and the fourth measurement electrodes 4730 may be measured using one sensor (not shown). In this case, the sensor may include the first probe pins 2832 connected to the first contact pads 3210, the second probe pins 2834 connected to the second contact pads 4710, the third probe pins 2842 connected to the third contact pads 3240, and the fourth probe pins 2844 connected to the fourth contact pads 4740. Further, the deposition mask 4000 may define a through-opening (not shown) through which the first probe pins 2832 and the third probe pins 2842 pass, and a contact opening (not shown) through which the second probe pins 2834 and the fourth probe pins 2844 are inserted.

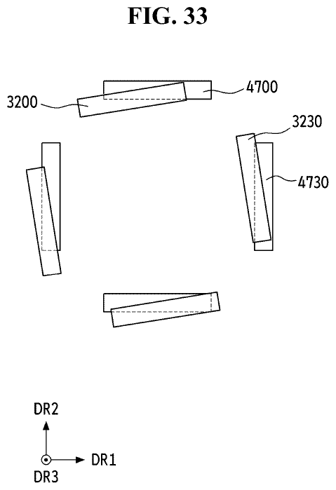

FIGS. 33 to 36 are schematic plan views illustrating a method of aligning a backplane substrate and a deposition mask with each other using the first, second, third, and fourth measurement electrodes illustrated in FIGS. 30 and 31.

Referring to FIG. 33, when the first measurement electrodes 3200 and the second measurement electrodes 4700 are misaligned with each other in the third direction DR3, and the third measurement electrodes 3230 and the fourth measurement electrodes 4730 are misaligned with each other in the third direction DR3, the capacitance values between the first measurement electrodes 3200 and the second measurement electrodes 4700 and the capacitance values between the third measurement electrodes 3230 and the fourth measurement electrodes 4730 may be different from each other.

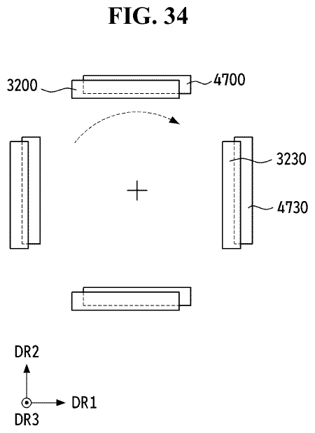

Referring to FIG. 34, the hexapod actuator 2510 may rotate the substrate chuck 2300 such that the capacitance values between the first measurement electrodes 3200 and the second measurement electrodes 4700 become equal and the capacitance values between the third measurement electrodes 3230 and the fourth measurement electrodes 4730 become equal in order to perform azimuth alignment between the backplane substrate 3000 and the deposition mask 4000. At this time, the capacitance values between the first measurement electrodes 3200 and the second measurement electrodes 4700 may be different from the capacitance values between the third measurement electrodes 3230 and the fourth measurement electrodes 4730.

In an embodiment, when the azimuth of the backplane substrate 3000 becomes equal to the azimuth of the deposition mask 4000, the areas where the first measurement electrodes 3200 and the second measurement electrodes 4700 overlap each other in the third direction DR3 may become equal, and the areas where the third measurement electrodes 3230 and the fourth measurement electrodes 4730 overlap each other in the third direction DR3 may become equal, for example. Accordingly, the capacitance values between the first measurement electrodes 3200 and the second measurement electrodes 4700 may become equal, and the capacitance values between the third measurement electrodes 3230 and the fourth measurement electrodes 4730 may become equal.

In an embodiment, the capacitance values between the first measurement electrodes 3200 and the second measurement electrodes 4700 may be measured by the first sensor 2830, and the capacitance values between the third measurement electrodes 3230 and the fourth measurement electrodes 4730 may be measured by the second sensor 2840. The controller 2900 may control the operation of the hexapod actuator 2510 based on the capacitance values measured by the first sensor 2830 and the second sensor 2840.

In an embodiment, the hexapod actuator 2510 may rotate the substrate chuck 2300 in a clockwise direction or a counterclockwise direction, for example. While rotating the substrate chuck 2300, the capacitance values between the first measurement electrodes 3200 and the second measurement electrodes 4700 may be measured by the first sensor 2830, and the capacitance values between the third measurement electrodes 3230 and the fourth measurement electrodes 4730 may be measured by the second sensor 2840. The controller 2900 may detect the azimuth of the substrate chuck 2300 at which the capacitance values between the first measurement electrodes 3200 and the second measurement electrodes 4700 become equal and the capacitance values between the third measurement electrodes 3230 and the fourth measurement electrodes 4730 become equal. Further, the controller 2900 may control the operation of the substrate chuck driver 2500 such that the substrate chuck 2300 has the detected azimuth, thereby performing the azimuth alignment between the backplane substrate 3000 and the deposition mask 4000.

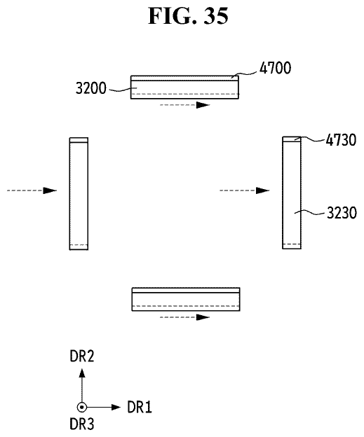

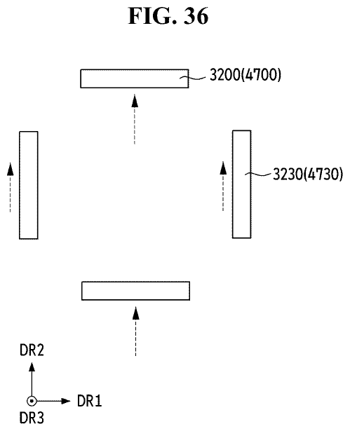

In an embodiment, the hexapod actuator 2510 may move the substrate chuck 2300 in the first direction DR1 and the second direction DR2 such that all the capacitance values between the first measurement electrodes 3200 and the second measurement electrodes 4700 and all the capacitance values between the third measurement electrodes 3230 and the fourth measurement electrodes 4730 become maximum in order to perform positional alignment between the backplane substrate 3000 and the deposition mask 4000, as shown in FIGS. 35 and 36.

In an embodiment, the hexapod actuator 2510 may move the substrate chuck 2300 in the first direction DR1 as shown in FIG. 35, for example. While moving the substrate chuck 2300 in the first direction DR1, the capacitance values between the first measurement electrodes 3200 and the second measurement electrodes 4700 may be measured by the first sensor 2830, and the capacitance values between the third measurement electrodes 3230 and the fourth measurement electrodes 4730 may be measured by the second sensor 2840. The controller 2900 may detect the first direction position of the substrate chuck 2300 at which all the capacitance values between the first measurement electrodes 3200 and the second measurement electrodes 4700 and all the capacitance values between the third measurement electrodes 3230 and the fourth measurement electrodes 4730 become maximum. Further, the controller 2900 may control the operation of the substrate chuck driver 2500 such that the substrate chuck 2300 is moved to the detected first direction position, so that first direction positional alignment between the backplane substrate 3000 and the deposition mask 4000 may be performed.

Further, the hexapod actuator 2510 may move the substrate chuck 2300 in the second direction DR2 as shown in FIG. 36. While moving the substrate chuck 2300 in the second direction DR2, the capacitance values between the first measurement electrodes 3200 and the second measurement electrodes 4700 may be measured by the first sensor 2830, and the capacitance values between the third measurement electrodes 3230 and the fourth measurement electrodes 4730 may be measured by the second sensor 2840. The controller 2900 may detect the second direction position of the substrate chuck 2300 at which all the capacitance values between the first measurement electrodes 3200 and the second measurement electrodes 4700 and all the capacitance values between the third measurement electrodes 3230 and the fourth measurement electrodes 4730 become maximum. Further, the controller 2900 may control the operation of the substrate chuck driver 2500 such that the substrate chuck 2300 is moved to the detected second direction position, so that second direction positional alignment between the backplane substrate 3000 and the deposition mask 4000 may be performed.

In another embodiment, the azimuth alignment and positional alignment between the backplane substrate 3000 and the deposition mask 4000 may be performed by the mask chuck driver 2600. In this case, the capacitance values between the first measurement electrodes 3200 and the second measurement electrodes 4700 and the capacitance values between the third measurement electrodes 3230 and the fourth measurement electrodes 4730 may be measured by the first sensor 2830 and the second sensor 2840, respectively, and the controller 2900 may control the operation of the piezo actuator 2610 based on the capacitance values measured by the first sensor 2830 and the second sensor 2840.

In another embodiment, the azimuth alignment and positional alignment between the backplane substrate 3000 and the deposition mask 4000 may be performed by the hexapod actuator 2510 and the piezo actuator 2610. In an embodiment, the hexapod actuator 2510 may rotate the substrate chuck 2300 and, at the same time, the piezo actuator 2610 may move the mask chuck 2400, for example. In this case, the controller 2900 may detect the azimuth of the backplane substrate 3000 and the position of the deposition mask 4000 at which all the capacitance values between the first measurement electrodes 3200 and the second measurement electrodes 4700 and all the capacitance values between the third measurement electrodes 3230 and the fourth measurement electrodes 4730 become maximum. In an alternative embodiment, the hexapod actuator 2510 may move the substrate chuck 2300 and, at the same time, the piezo actuator 2610 may rotate the mask chuck 2400. In this case, the controller 2900 may detect the position of the backplane substrate 3000 and the azimuth of the deposition mask 4000 at which all the capacitance values between the first measurement electrodes 3200 and the second measurement electrodes 4700 and all the capacitance values between the third measurement electrodes 3230 and the fourth measurement electrodes 4730 become maximum.

Further, as described above, after the azimuth alignment between the backplane substrate 3000 and the deposition mask 4000 is performed, the positional alignment between the backplane substrate 3000 and the deposition mask 4000 is performed. However, unlike the above, the azimuth alignment between the backplane substrate 3000 and the deposition mask 4000 may be performed after the positional alignment between the backplane substrate 3000 and the deposition mask 4000 is performed.

In an embodiment, the hexapod actuator 2510 may move the substrate chuck 2300 in the first direction DR1 and the second direction DR2, and the capacitance values between the first measurement electrodes 3200 and the second measurement electrodes 4700 and the capacitance values between the third measurement electrodes 3230 and the fourth measurement electrodes 4730 may be measured by the first sensor 2830 and the second sensor 2840, for example. While moving the substrate chuck 2300 in the first direction DR1 and the second direction DR2, the capacitance values between the first measurement electrodes 3200 and the second measurement electrodes 4700 and the capacitance values between the third measurement electrodes 3230 and the fourth measurement electrodes 4730 may be changed, and the controller 2900 may detect the position of the substrate chuck 2300 at which the capacitance values between the first measurement electrodes 3200 and the second measurement electrodes 4700 become equal and the capacitance values between the third measurement electrodes 3230 and the fourth measurement electrodes 4730 become equal. Further, the controller 2900 may control the operation of the substrate chuck driver 2500 such that the substrate chuck 2300 is moved to the detected position, thereby performing positional alignment between the backplane substrate 3000 and the deposition mask 4000.

Next, the hexapod actuator 2510 may rotate the substrate chuck 2300 in a clockwise direction or a counterclockwise direction, and the capacitance values between the first measurement electrodes 3200 and the second measurement electrodes 4700 and the capacitance values between the third measurement electrodes 3230 and the fourth measurement electrodes 4730 may be measured by the first sensor 2830 and the second sensor 2840. While rotating the substrate chuck 2300, the capacitance values between the first measurement electrodes 3200 and the second measurement electrodes 4700 and the capacitance values between the third measurement electrodes 3230 and the fourth measurement electrodes 4730 may be changed, and the controller 2900 may detect the azimuth of the substrate chuck 2300 at which all the capacitance values between the first measurement electrodes 3200 and the second measurement electrodes 4700 and all the capacitance values between the third measurement electrodes 3230 and the fourth measurement electrodes 4730 become maximum. Further, the controller 2900 may control the operation of the substrate chuck driver 2500 such that the substrate chuck 2300 has the detected azimuth, thereby performing the azimuth alignment between the backplane substrate 3000 and the deposition mask 4000.

In another embodiment, the positional alignment and azimuth alignment between the backplane substrate 3000 and the deposition mask 4000 may be performed by the mask chuck driver 2600. In an embodiment, the positional alignment and azimuth alignment between the backplane substrate 3000 and the deposition mask 4000 may be sequentially performed by the piezo actuator 2610, for example.

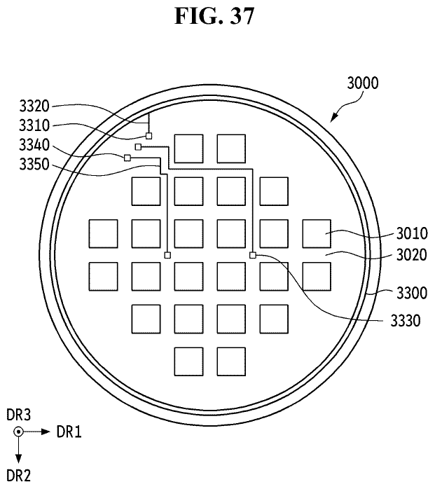

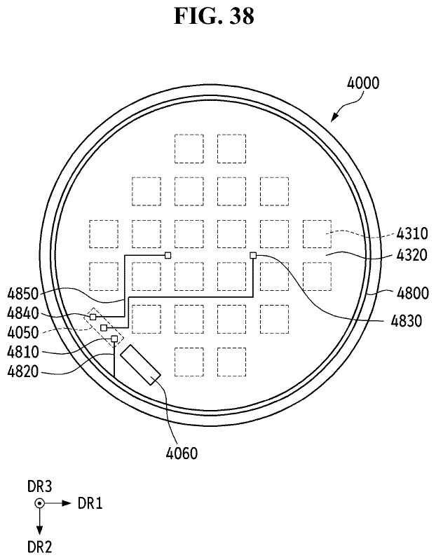

FIG. 37 is a schematic bottom view illustrating another embodiment of the backplane substrate illustrated in FIG. 15. FIG. 38 is a schematic plan view illustrating another embodiment of the deposition mask shown in FIG. 16.

Referring to FIG. 37, the backplane substrate 3000 may include a first measurement electrode 3300 and at least one third measurement electrode 3330. In an embodiment, the backplane substrate 3000 may include the first measurement electrode 3300 disposed on the edge portion and having a circular ring shape and the third measurement electrodes 3330 arranged on the scribe lane region 3020, for example. As illustrated, the backplane substrate 3000 includes two third measurement electrodes 3330, but the number of third measurement electrodes 3330 may be changed and the scope of the disclosure is not limited thereby.

The backplane substrate 3000 may include a first contact pad 3310, third contact pads 3340, a first connection line 3320, and third connection lines 3350. In an embodiment, the first contact pad 3310 and the third contact pads 3340 may be arranged on the edge portions of the backplane substrate 3000, for example. The first connection line 3320 may connect the first measurement electrode 3300 and the first contact pad 3310. The third connection lines 3350 may be arranged on the scribe lane region 3020 and may connect the third measurement electrodes 3330 and the third contact pads 3340.

In an embodiment, except the first and third measurement electrodes 3300 and 3330, the first and third contact pads 3310 and 3340, and the first and third connection lines 3320 and 3350, remaining (the other) elements of the backplane substrate 3000 are substantially the same as those described above with reference to FIG. 15, so that detailed description thereof will be omitted.

Referring to FIG. 38, the deposition mask 4000 may include a second measurement electrode 4800 and at least one fourth measurement electrode 4830. In an embodiment, the deposition mask 4000 may include the second measurement electrodes 4800 having a circular ring shape corresponding to that of the first measurement electrode 3300 and the fourth measurement electrodes 4830 respectively corresponding to the third measurement electrodes 3330, for example.

The second measurement electrode 4800 may be disposed at the same position as the first measurement electrode 3300 in a plan view and may have the same shape and size as the first measurement electrode 3300. In an embodiment, the second measurement electrode 4800 may be disposed on the edge portion of the deposition mask 4000 and may have a circular ring shape, for example. The fourth measurement electrodes 4830 may be disposed at the same position as the third measurement electrodes 3330 in a plan view and may have the same shape and size as the third measurement electrodes 3330. In an embodiment, the fourth measurement electrodes 4830 may be arranged on the grid region 4320 of the deposition mask 4000 and may have a circular shape, a square shape, a quadrangular shape, e.g., rectangular shape, or a bar shape in a plan view, for example. As illustrated, the deposition mask 4000 includes two fourth measurement electrodes 4830, but the number of the fourth measurement electrodes 4830 may be changed and the scope of the disclosure is not limited thereby.

The deposition mask 4000 may include a second contact pad 4810, fourth contact pads 4840, a second connection line 4820, and fourth connection lines 4850. In an embodiment, the second contact pad 4810 and the fourth contact pads 4840 may be arranged on the edge portions of the deposition mask 4000, for example. The second connection line 4820 may connect the second measurement electrode 4800 and the second contact pad 4810. The fourth connection lines 4850 may be arranged on the grid region 4320 and may connect the fourth measurement electrodes 4830 and the fourth contact pads 4840.

In an embodiment, except the second and fourth measurement electrodes 4800 and 4830, the second and fourth contact pads 4810 and 4840, and the second and fourth connection lines 4820 and 4850, remaining (the other) elements of the deposition mask 4000 are substantially the same as those described above with reference to FIGS. 16 to 18, so that detailed description thereof will be omitted.

In an embodiment, the deposition apparatus 2000 may include a sensor (not shown) for measuring capacitance values between the first measurement electrode 3300 and the second measurement electrode 4800 and capacitance values between the third measurement electrodes 3330 and the fourth measurement electrodes 4830. The sensor may include a first probe pin connected to the first contact pad 3310, a second probe pin connected to the second contact pad 4810, third probe pins connected to the third contact pads 3340, and fourth probe pins connected to the fourth contact pads 4840. Further, the deposition mask 4000 may define a through-opening 4050 through which the first probe pin and the third probe pins pass, and a contact opening 4060 through which the second probe pins and the fourth probe pins are inserted. The first, second, third and fourth probe pins are similar to those described above with reference to FIGS. 21 to 23, so that detailed description thereof will be omitted.

In another embodiment, the deposition apparatus 2000 may include a first sensor (not shown) for measuring a capacitance value between the first measurement electrode 3300 and the second measurement electrode 4800, and a second sensor (not shown) for measuring capacitance values between the third measurement electrodes 3330 and the fourth measurement electrodes 4830. The first sensor and the second sensor may be configured substantially the same as the first sensor 2830 and the second sensor 2840 described above with reference to FIG. 32, so that detailed description of the first sensor and the second sensor will be omitted.

In an embodiment, after the backplane substrate 3000 is disposed on the deposition mask 4000, the positional alignment between the backplane substrate 3000 and the deposition mask 4000 may be performed. In an embodiment, the hexapod actuator 2510 may move the substrate chuck 2300 in the first direction DR1 and the second direction DR2 such that the capacitance value between the first measurement electrode 3300 and the second measurement electrode 4800 becomes maximum, for example. The capacitance value between the first measurement electrode 3300 and the second measurement electrode 4800 may be measured by the sensor or the first sensor, and the controller 2900 may control the operation of the hexapod actuator 2510 based on the capacitance value between the first measurement electrode 3300 and the second measurement electrode 4800.

After the positional alignment between the backplane substrate 3000 and the deposition mask 4000 is performed, the azimuth alignment between the backplane substrate 3000 and the deposition mask 4000 may be performed. In an embodiment, the hexapod actuator 2510 may rotate the substrate chuck 2300 such that the capacitance values between the third measurement electrodes 3330 and the fourth measurement electrodes 4830 become maximum, for example. The capacitance values between the third measurement electrodes 3330 and the fourth measurement electrodes 4830 may be measured by the sensor or the second sensor, and the controller 2900 may control the operation of the hexapod actuator 2510 based on the capacitance values between the third measurement electrodes 3330 and the fourth measurement electrodes 4800. In this case, since each of the first measurement electrode 3300 and the second measurement electrode 4800 has a circular ring shape, the capacitance value between the first measurement electrode 3300 and the second measurement electrode 4800 may be maintained constant while performing the azimuth alignment between the backplane substrate 3000 and the deposition mask 4000.

Referring back to FIG. 14, after the backplane substrate 3000 and the deposition mask 4000 are aligned with each other as described above, the hexapod actuator 2510 may adjust the gap between the backplane substrate 3000 and the deposition mask 4000, for example. In an embodiment, the hexapod actuator 2510 may adjust the height of the substrate chuck 2300 such that the gap between the backplane substrate 3000 and the deposition mask 4000 becomes about several μm, e.g., about 3 μm to about 7μm.

In another embodiment, the hexapod actuator 2510 may adjust the height of the substrate chuck 2300 such that the backplane substrate 3000 is brought into close contact with the deposition mask 4000. In an embodiment, the height of the substrate chuck 2300 may be adjusted such that the first measurement electrodes 3100 and the second measurement electrodes 4600 are brought into contact with each other. In this case, all the first measurement electrodes 3100 may be electrically connected to the second measurement electrodes 4600. However, when any one of the first measurement electrodes 3100 is not electrically connected to the corresponding second measurement electrode 4600, it may be determined that warpage has occurred in the deposition mask 4000, and in this case, the controller 2900 may stop the deposition process.

After the gap between the backplane substrate 3000 and the deposition mask 4000 is adjusted as described above, the deposition source 2200 may provide a vapor deposition material toward the deposition mask 4000, and the vapor deposition material may be deposited on the backplane substrate 3000 through the pixel openings 4312 of the deposition mask 4000. In an embodiment, the deposition source 2200 may evaporate an organic material for forming light-emitting layers on the backplane substrate 3000, and the evaporated organic material may be deposited on the electrode patterns of the backplane substrate 3000 through the pixel openings 4312 of the deposition mask 4000, for example.

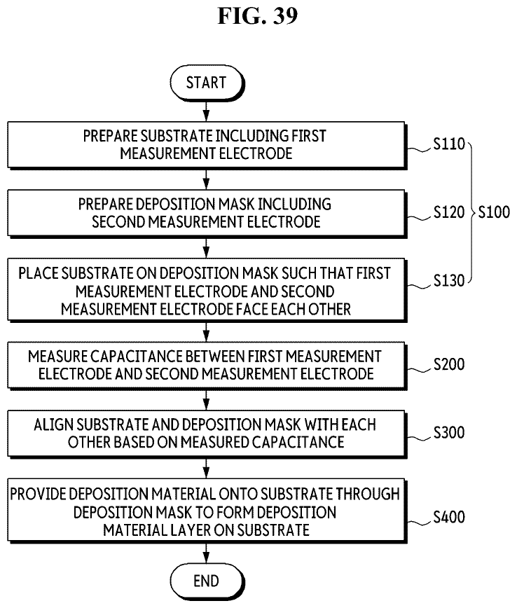

FIG. 39 is a flowchart illustrating an embodiment of a deposition method according to the disclosure.

Referring to FIG. 39, in operation S100, a capacitor 3500 (refer to FIGS. 24 and 25) may be formed between the backplane substrate 3000 and the deposition mask 4000. In an embodiment, in operation S110, the backplane substrate 3000 including at least one first measurement electrode 3100 (refer to FIG. 15) may be prepared, in operation S120, the deposition mask 4000 including at least one second measurement electrode 4600 (refer to FIG. 16) may be prepared, and in operation S130, the backplane substrate 3000 may be placed on the deposition mask 4000 such that at least one first measurement electrode 3100 and at least one second measurement electrode 4600 face each other. Accordingly, at least one capacitor 3500 including at least one first measurement electrode 3100 and at least one second measurement electrode 4600 may be formed between the backplane substrate 3000 and the deposition mask 4000.

In an embodiment, the plurality of first measurement electrodes 3100 may be arranged on the backplane substrate 3000 as described above with reference to FIG. 15, and the plurality of second measurement electrodes 4600 may be arranged on the deposition mask 4000 to respectively correspond to the first measurement electrodes 3100 as described above with reference to FIG. 16, for example. The backplane substrate 3000 and the deposition mask 4000 may be arranged such that the first measurement electrodes 3100 and the second measurement electrodes 4600 face each other by the substrate chuck 2300, the mask chuck 2400, the substrate chuck driver 2500, and the mask chuck driver 2600 as described above with reference to FIG. 14, so that the capacitors 3500 including the first measurement electrodes 3100 and the second measurement electrodes 4600 may be formed as illustrated in FIGS. 24 and 25.

Although not illustrated in FIG. 39, the deposition method in an embodiment may further include a step of adjusting the parallelism between the backplane substrate 3000 and the deposition mask 4000. In an embodiment, as described above with reference to FIG. 19, the parallelism between the substrate chuck 2300 and the mask chuck 2400 may be adjusted using the gap sensors 2700, so that the parallelism between the backplane substrate 3000 and the deposition mask 4000 may be adjusted, for example.

Referring to FIG. 39, in operation S200, the capacitance of the capacitors 3500 formed between the backplane substrate 3000 and the deposition mask 4000 may be measured. In an embodiment, the backplane substrate 3000 and/or the deposition mask 4000 may be moved using the substrate chuck driver 2500 and/or the mask chuck driver 2600, and the capacitance between the first measurement electrodes 3100 and the second measurement electrodes 4600 may be measured using the sensor 2800 (refer to FIGS. 19 to 23) while moving the backplane substrate 3000 and/or the deposition mask 4000, for example. In an embodiment, the backplane substrate 3000 or the deposition mask 4000 may be rotated by the substrate chuck driver 2500 or the mask chuck driver 2600, and the backplane substrate 3000 or the deposition mask 4000 may be moved by the substrate chuck driver 2500 or the mask chuck driver 2600, for example. At this time, the gap between the backplane substrate 3000 and the deposition mask 4000 may be maintained constant.

In an embodiment, while rotating the backplane substrate or the deposition mask by the substrate chuck driver 2500 or the mask chuck driver 2600, the capacitance values between the first measurement electrodes 3100 and the second measurement electrodes 4600 may be measured by the sensor 2800. Further, while moving the backplane substrate 3000 or the deposition mask 4000 in the first direction DR1 and the second direction DR2 by the substrate chuck driver 2500 or the mask chuck driver 2600, the capacitance values between the first measurement electrodes 3100 and the second measurement electrodes 4600 may be measured by the sensor 2800. At this time, the gap between the backplane substrate 3000 and the deposition mask 4000 may be maintained constant. That is, the backplane substrate 3000 and the deposition mask 4000 do not move in the third direction DR3.

In operation S300, the backplane substrate 3000 and the deposition mask 4000 may be aligned with each other based on the capacitance of the capacitors 3500 measured by the sensor 2800. In an embodiment, the substrate chuck driver 2500 and/or the mask chuck driver 2600 may move the backplane substrate 3000 and/or the deposition mask 4000 such that the capacitance of the capacitors 3500 becomes maximum, thereby aligning the backplane substrate 3000 and the deposition mask 4000 with each other, for example. In an embodiment, the position and angle of the backplane substrate 3000 or the deposition mask 4000 may be adjusted such that the capacitance values between the first measurement electrodes 3100 and the second measurement electrodes 4600 become maximum, thereby aligning the backplane substrate 3000 and the deposition mask 4000 with each other, for example.

In an embodiment, the first measurement electrodes 3100 and the second measurement electrodes 4600 may have the same shape and the same size. In an embodiment, as described above with reference to FIGS. 26 and 27, the substrate chuck driver 2500 or the mask chuck driver 2600 may rotate the backplane substrate 3000 or the deposition mask 4000. While rotating the backplane substrate 3000 or the deposition mask 4000, the capacitance values between the first measurement electrodes 3100 and the second measurement electrodes 4600 may be measured by the sensor 2800. The azimuth of the backplane substrate 3000 or the deposition mask 4000 at which the capacitance values between the first measurement electrodes 3100 and the second measurement electrodes 4600 become all equal may be detected by the controller 2900. The operation of the substrate chuck driver 2500 or the mask chuck driver 2600 may be controlled by the controller 2900 such that the backplane substrate 3000 or the deposition mask 4000 has the detected azimuth, thereby performing the azimuth alignment between the backplane substrate 3000 and the deposition mask 4000.

Additionally, as described above with reference to FIGS. 28 and 29, the substrate chuck driver 2500 or the mask chuck driver 2600 may move the backplane substrate 3000 or the deposition mask 4000 in the first direction DR1 and the second direction DR2. While moving the backplane substrate 3000 or the deposition mask 4000, the capacitance values between the first measurement electrodes 3100 and the second measurement electrodes 4600 may be measured by the sensor 2800. The position of the backplane substrate 3000 or the deposition mask 4000 at which all the capacitance values between the first measurement electrodes 3100 and the second measurement electrodes 4600 become maximum may be detected by the controller 2900. The operation of the substrate chuck driver 2500 or the mask chuck driver 2600 may be controlled by the controller 2900 such that the backplane substrate 3000 or the deposition mask 4000 is moved to the detected position, thereby performing the positional alignment between the backplane substrate 3000 and the deposition mask 4000.

In another embodiment, after the positional alignment between the backplane substrate 3000 and the deposition mask 4000 is performed, the azimuth alignment between the backplane substrate 3000 and the deposition mask 4000 may be performed. In an embodiment, the substrate chuck driver 2500 or the mask chuck driver 2600 may move the backplane substrate 3000 or the deposition mask 4000 in the first direction DR1 and the second direction DR2. While moving the backplane substrate 3000 or the deposition mask 4000, the capacitance values between the first measurement electrodes 3100 and the second measurement electrodes 4600 may be measured by the sensor 2800. The position of the backplane substrate 3000 or the deposition mask 4000 at which the capacitance values between the first measurement electrodes 3100 and the second measurement electrodes 4600 become all equal may be detected by the controller 2900. The operation of the substrate chuck driver 2500 or the mask chuck driver 2600 may be controlled by the controller 2900 such that the backplane substrate 3000 or the deposition mask 4000 is moved to the detected position, thereby performing the positional alignment between the backplane substrate 3000 and the deposition mask 4000.

Subsequently, the substrate chuck driver 2500 or the mask chuck driver 2600 may rotate the backplane substrate 3000 or the deposition mask 4000. While rotating the backplane substrate 3000 or the deposition mask 4000, the capacitance values between the first measurement electrodes 3100 and the second measurement electrodes 4600 may be measured by the sensor 2800. The azimuth of the backplane substrate 3000 or the deposition mask 4000 at which all the capacitance values between the first measurement electrodes 3100 and the second measurement electrodes 4600 become maximum may be detected by the controller 2900. The operation of the substrate chuck driver 2500 or the mask chuck driver 2600 may be controlled by the controller 2900 such that the backplane substrate 3000 or the deposition mask 4000 has the detected azimuth, thereby performing the azimuth alignment between the backplane substrate 3000 and the deposition mask 4000.

In an embodiment, as described above with reference to FIGS. 30 and 31, the backplane substrate 3000 may include the first measurement electrodes 3200 extending in the first direction DR1 and the third measurement electrodes 3230 extending in the second direction DR2, and the deposition mask 4000 may include the second measurement electrodes 4700 extending in the first direction DR1 and the fourth measurement electrodes 4730 extending in the second direction DR2.

In an embodiment, the substrate chuck driver 2500 or the mask chuck driver 2600 may rotate the backplane substrate 3000 or the deposition mask 4000, for example. While rotating the backplane substrate 3000 or the deposition mask 4000, the capacitance values between the first measurement electrodes 3200 and the second measurement electrodes 4700 and the capacitance values between the third measurement electrodes 3230 and the fourth measurement electrodes 4730 may be measured by the first sensor 2830 (refer to FIG. 32) and the second sensor 2840 (refer to FIG. 32). The azimuth of the backplane substrate 3000 or the deposition mask 4000 at which the capacitance values between the first measurement electrodes 3200 and the second measurement electrodes 4700 become equal and the capacitance values between the third measurement electrodes 3230 and the fourth measurement electrodes 4730 become equal may be detected by the controller 2900. The operation of the substrate chuck driver 2500 or the mask chuck driver 2600 may be controlled by the controller 2900 such that the backplane substrate 3000 or the deposition mask 4000 has the detected azimuth, thereby performing the azimuth alignment between the backplane substrate 3000 and the deposition mask 4000.

Subsequently, the substrate chuck driver 2500 or the mask chuck driver 2600 may move the backplane substrate 3000 or the deposition mask 4000 in the first direction DR1 and the second direction DR2. While moving the backplane substrate 3000 or the deposition mask 4000, the capacitance values between the first measurement electrodes 3200 and the second measurement electrodes 4700 and the capacitance values between the third measurement electrodes 3230 and the fourth measurement electrodes 4730 may be measured by the first sensor 2830 and the second sensor 2840. The position of the backplane substrate 3000 or the deposition mask 4000 at which the capacitance values between the first measurement electrodes 3200 and the second measurement electrodes 4700 and the capacitance values between the third measurement electrodes 3230 and the fourth measurement electrodes 4730 become all maximum and become all equal may be detected by the controller 2900. The operation of the substrate chuck driver 2500 or the mask chuck driver 2600 may be controlled by the controller 2900 such that the backplane substrate 3000 or the deposition mask 4000 is moved to the detected position, thereby performing the positional alignment between the backplane substrate 3000 and the deposition mask 4000.

In another embodiment, after the positional alignment between the backplane substrate 3000 and the deposition mask 4000 is performed, the azimuth alignment between the backplane substrate 3000 and the deposition mask 4000 may be performed. The substrate chuck driver 2500 or the mask chuck driver 2600 may move the backplane substrate 3000 or the deposition mask 4000 in the first direction DR1 and the second direction DR2. While moving the backplane substrate 3000 or the deposition mask 4000, the capacitance values between the first measurement electrodes 3200 and the second measurement electrodes 4700 and the capacitance values between the third measurement electrodes 3230 and the fourth measurement electrodes 4730 may be measured by the first sensor 2830 and the second sensor 2840. The position of the backplane substrate 3000 or the deposition mask 4000 at which the capacitance values between the first measurement electrodes 3200 and the second measurement electrodes 4700 become equal and the capacitance values between the third measurement electrodes 3230 and the fourth measurement electrodes 4730 become equal may be detected by the controller 2900. The operation of the substrate chuck driver 2500 or the mask chuck driver 2600 may be controlled by the controller 2900 such that the backplane substrate 3000 or the deposition mask 4000 is moved to the detected position, thereby performing the positional alignment between the backplane substrate 3000 and the deposition mask 4000.

Subsequently, the substrate chuck driver 2500 or the mask chuck driver 2600 may rotate the backplane substrate 3000 or the deposition mask 4000. While rotating the backplane substrate 3000 or the deposition mask 4000, the capacitance values between the first measurement electrodes 3200 and the second measurement electrodes 4700 and the capacitance values between the third measurement electrodes 3230 and the fourth measurement electrodes 4730 may be measured by the first sensor 2830 and the second sensor 2840. The azimuth of the backplane substrate 3000 or the deposition mask 4000 at which the capacitance values between the first measurement electrodes 3200 and the second measurement electrodes 4700 and the capacitance values between the third measurement electrodes 3230 and the fourth measurement electrodes 4730 become all maximum and become all equal may be detected by the controller 2900. The operation of the substrate chuck driver 2500 or the mask chuck driver 2600 may be controlled by the controller 2900 such that the backplane substrate 3000 or the deposition mask 4000 has the detected azimuth, thereby performing the azimuth alignment between the backplane substrate 3000 and the deposition mask 4000.

In an embodiment, as described above with reference to FIGS. 37 and 38, the backplane substrate 3000 may include the first measurement electrode 3300 having a circular ring shape and the third measurement electrodes 3330, and the deposition mask 4000 may include the second measurement electrode 4800 having a circular ring shape and corresponding to the first measurement electrode 3300 and the fourth measurement electrodes 4830 corresponding to the third measurement electrodes 3330.

In an embodiment, after the positional alignment between the backplane substrate 3000 and the deposition mask 4000 is performed, the azimuth alignment between the backplane substrate 3000 and the deposition mask 4000 may be performed, for example. The substrate chuck driver 2500 or the mask chuck driver 2600 may move the backplane substrate 3000 or the deposition mask 4000 in the first direction DR1 and the second direction DR2. The controller 2900 may detect the position of the backplane substrate 3000 or the deposition mask 4000 at which the capacitance value between the first measurement electrode 3300 and the second measurement electrode 4800 becomes maximum. Further, the controller 2900 may control the operation of the substrate chuck driver 2500 or the mask chuck driver 2600 such that the backplane substrate 3000 or the deposition mask 4000 is moved to the detected position, thereby performing the positional alignment between the backplane substrate 3000 and the deposition mask 4000.

Subsequently, the substrate chuck driver 2500 or the mask chuck driver 2600 may rotate the backplane substrate 3000 or the deposition mask 4000. The controller 2900 may detect the azimuth of the backplane substrate 3000 or the deposition mask 4000 at which the capacitance values between the third measurement electrodes 3330 and the fourth measurement electrodes 4830 become maximum. In addition, the controller 2900 may control the operation of the substrate chuck driver 2500 or the mask chuck driver 2600 such that the backplane substrate 3000 or the deposition mask 4000 has the detected azimuth, thereby performing the azimuth alignment between the backplane substrate 3000 and the deposition mask 4000.

As described above, after the backplane substrate 3000 and the deposition mask 4000 are aligned with each other, in operation S400, a deposition material may be provided onto the backplane substrate 3000 through the deposition mask 4000, thereby forming a deposition material layer on the backplane substrate 3000. In an embodiment, the deposition source 2200 may evaporate an organic material for forming light-emitting layers on the backplane substrate 3000, and the evaporated organic material may be deposited on the electrode patterns of the backplane substrate 3000 through the pixel openings 4312 of the deposition mask 4000, for example.

By the embodiments of the disclosure as described above, the alignment between the backplane substrate 3000 and the deposition mask 4000 may be performed based on the capacitance between the backplane substrate 3000 and the deposition mask 4000. As a result, the high-resolution cameras and the illumination devices used for detection of general alignment keys may be eliminated, thereby considerably reducing the manufacturing cost of the display panel 100, the display device 20, the electronic device 10, or the like.

The disclosure should not be construed as being limited to the embodiments set forth herein. Rather, these embodiments are provided so that this disclosure will be thorough and complete and will fully convey the concept of the disclosure to those skilled in the art.

While the disclosure has been particularly shown and described with reference to embodiments thereof, it will be understood by those of ordinary skill in the art that various changes in form and details may be made therein without departing from the spirit or scope of the disclosure as defined by the following claims.

What is claimed is:

1. A deposition method comprising:
preparing a substrate comprising at least one first measurement electrode;
preparing a deposition mask comprising at least one second measurement electrode;
placing the substrate on the deposition mask in a manner in which the at least one first measurement electrode and the at least one second measurement electrode face to each other;
measuring a capacitance between the at least one first measurement electrode and the at least one second measurement electrode;
aligning the substrate and the deposition mask with each other based on the measured capacitance; and
providing a deposition material onto the substrate through the deposition mask and forming a deposition material layer on the substrate.

2. The deposition method of claim 1, wherein the measuring the capacitance comprises:
rotating the substrate or the deposition mask;
measuring a first capacitance value between the at least one first measurement electrode and the at least one second measurement electrode while rotating the substrate or the deposition mask;
moving the substrate or the deposition mask while maintaining a constant gap between the substrate and the deposition mask; and
measuring a second capacitance value between the at least one first measurement electrode and the at least one second measurement electrode while moving the substrate or the deposition mask.

3. The deposition method of claim 1, wherein the aligning the substrate and the deposition mask with each other comprises:
adjusting a position and an angle of the substrate or the deposition mask in a manner in which a capacitance value between the at least one first measurement electrode and the at least one second measurement electrode becomes maximum.

4. The deposition method of claim 1, wherein the substrate comprises a plurality of first measurement electrodes,
the deposition mask comprises a plurality of second measurement electrodes,
the substrate is placed on the deposition mask in a manner in which the first measurement electrodes face the second measurement electrodes, respectively, and
the first measurement electrodes and the second measurement electrodes have a same shape.

5. The deposition method of claim 4, wherein the measuring the capacitance comprises:
rotating the substrate or the deposition mask; and
measuring first capacitance values between the first measurement electrodes and the second measurement electrodes while rotating the substrate or the deposition mask, and
the aligning the substrate and the deposition mask with each other comprises:
detecting an azimuth of the substrate or the deposition mask at which the first capacitance values between the first measurement electrodes and the second measurement electrodes become all equal; and
adjusting an azimuth of the substrate or the deposition mask in a manner in which the substrate or the deposition mask has a detected azimuth.

6. The deposition method of claim 5, wherein the measuring the capacitance further comprises:
moving the substrate or the deposition mask while maintaining a constant gap between the substrate and the deposition mask; and
measuring second capacitance values between the first measurement electrodes and the second measurement electrodes while moving the substrate or the deposition mask, and
the aligning the substrate and the deposition mask with each other further comprises:
detecting a position of the substrate or the deposition mask at which the second capacitance values between the first measurement electrodes and the second measurement electrodes become all maximum; and
moving the substrate or the deposition mask to a detected position.

7. The deposition method of claim 4, wherein the measuring the capacitance comprises:
moving the substrate or the deposition mask while maintaining a constant gap between the substrate and the deposition mask; and
measuring first capacitance values between the first measurement electrodes and the second measurement electrodes while moving the substrate or the deposition mask, and
the aligning the substrate and the deposition mask with each other comprises:
detecting a position of the substrate or the deposition mask at which the first capacitance values between the first measurement electrodes and the second measurement electrodes become all equal; and
moving the substrate or the deposition mask to a detected position.

8. The deposition method of claim 7, wherein the measuring the capacitance further comprises:
rotating the substrate or the deposition mask; and
measuring second capacitance values between the first measurement electrodes and the second measurement electrodes while rotating the substrate or the deposition mask, and
the aligning the substrate and the deposition mask with each other further comprises:
detecting an azimuth of the substrate or the deposition mask at which the second capacitance values between the first measurement electrodes and the second measurement electrodes become all maximum; and
adjusting an azimuth of the substrate or the deposition mask in a manner in which the substrate or the deposition mask has a detected azimuth.

9. The deposition method of claim 1, wherein the substrate comprises a plurality of first measurement electrodes and a plurality of third measurement electrodes,
the deposition mask comprises a plurality of second measurement electrodes and a plurality of fourth measurement electrodes,
the substrate is placed on the deposition mask in a manner in which the first measurement electrodes face the second measurement electrodes, respectively, and the plurality of third measurement electrodes face the plurality of fourth measurement electrodes, respectively,
the first measurement electrodes and the second measurement electrodes extend in a first direction, and
the plurality of third measurement electrodes and the plurality of fourth measurement electrodes extend in a second direction perpendicular to the first direction.

10. The deposition method of claim 9, wherein the measuring the capacitance comprises:
rotating the substrate or the deposition mask; and
measuring first capacitance values between the first measurement electrodes and the second measurement electrodes and second capacitance values between the plurality of third measurement electrodes and the plurality of fourth measurement electrodes while rotating the substrate or the deposition mask, and
the aligning the substrate and the deposition mask with each other comprises:
detecting an azimuth of the substrate or the deposition mask at which the first capacitance values between the first measurement electrodes and the second measurement electrodes become equal to each other and the second capacitance values between the plurality of third measurement electrodes and the plurality of fourth measurement electrodes become equal to each other; and
adjusting an azimuth of the substrate or the deposition mask in a manner in which the substrate or the deposition mask has a detected azimuth.

11. The deposition method of claim 10, wherein the measuring the capacitance further comprises:
moving the substrate or the deposition mask while maintaining a constant gap between the substrate and the deposition mask; and
measuring third capacitance values between the first measurement electrodes and the second measurement electrodes and fourth capacitance values between the plurality of third measurement electrodes and the plurality of fourth measurement electrodes while moving the substrate or the deposition mask, and
the aligning the substrate and the deposition mask with each other further comprises:
detecting a position of the substrate or the deposition mask at which the third capacitance values between the first measurement electrodes and the second measurement electrodes and the fourth capacitance values between the plurality of third measurement electrodes and the plurality of fourth measurement electrodes become all maximum and become all equal; and
moving the substrate or the deposition mask to a detected position.

12. The deposition method of claim 9, wherein the measuring the capacitance comprises:
moving the substrate or the deposition mask while maintaining a constant gap between the substrate and the deposition mask; and
measuring first capacitance values between the first measurement electrodes and the second measurement electrodes and second capacitance values between the plurality of third measurement electrodes and the plurality of fourth measurement electrodes while moving the substrate or the deposition mask, and
the aligning the substrate and the deposition mask with each other comprises:
detecting a position of the substrate or the deposition mask at which the first capacitance values between the first measurement electrodes and the second measurement electrodes become equal to each other and the second capacitance values between the plurality of third measurement electrodes and the plurality of fourth measurement electrodes become equal to each other; and
moving the substrate or the deposition mask to a detected position.

13. The deposition method of claim 12, wherein the measuring the capacitance further comprises:
rotating the substrate or the deposition mask; and
measuring third capacitance values between the first measurement electrodes and the second measurement electrodes and fourth capacitance values between the plurality of third measurement electrodes and the plurality of fourth measurement electrodes while rotating the substrate or the deposition mask, and
the aligning the substrate and the deposition mask with each other further comprises:
detecting an azimuth of the substrate or the deposition mask at which the third capacitance values between the first measurement electrodes and the second measurement electrodes and the fourth capacitance values between the plurality of third measurement electrodes and the plurality of fourth measurement electrodes become all maximum and become all equal; and
adjusting an azimuth of the substrate or the deposition mask in a manner in which the substrate or the deposition mask has a detected azimuth.

14. The deposition method of claim 1, wherein the substrate comprises one first measurement electrode and at least one third measurement electrode,
the deposition mask comprises one second measurement electrode and at least one fourth measurement electrode,
the substrate is placed on the deposition mask in a manner in which the first measurement electrode faces the second measurement electrode and the at least one third measurement electrode faces the at least one fourth measurement electrode,
the first measurement electrode and the second measurement electrode have a same circular ring shape, and
the at least one third measurement electrode and the at least one fourth measurement electrode have a same shape.

15. The deposition method of claim 1, further comprising adjusting a parallelism between the substrate and the deposition mask.

16. A deposition apparatus comprising:
a deposition source which provides a deposition material;
a substrate chuck disposed above the deposition source and supporting a substrate comprising at least one first measurement electrode;
a mask chuck disposed between the deposition source and the substrate chuck and supporting a deposition mask comprising at least one second measurement electrode;
a sensor which measures a capacitance between the at least one first measurement electrode and the at least one second measurement electrode; and
a chuck driver which aligns the substrate and the deposition mask with each other based on the capacitance measured by the sensor.

17. The deposition apparatus of claim 16, wherein the substrate further comprises at least one first contact pad and at least one first connection line connecting the at least one first measurement electrode to the at least one first contact pad,
the deposition mask further comprises at least one second contact pad and at least one second connection line connecting the at least one second measurement electrode to the at least one second contact pad, and
the sensor comprises at least one first probe pin connected to the at least one first contact pad and at least one second probe pin connected to the at least one second contact pad.

18. The deposition apparatus of claim 16, wherein the chuck driver moves the substrate chuck or the mask chuck in a manner in which a capacitance between the at least one first measurement electrode and the at least one second measurement electrode becomes maximum and aligns the substrate and the deposition mask with each other.

19. An electronic device comprising:
a display panel comprising:
a substrate comprising at least one first measurement electrode; and
light-emitting layers formed on the substrate by a deposition apparatus, the deposition apparatus comprising:
a deposition source which provides a deposition material;
a substrate chuck disposed above the deposition source and supporting the substrate;
a mask chuck disposed between the deposition source and the substrate chuck and supporting a deposition mask comprising at least one second measurement electrode;
a sensor which measures a capacitance between the at least one first measurement electrode and the at least one second measurement electrode; and
a chuck driver which aligns the substrate and the deposition mask with each other based on the capacitance measured by the sensor.

20. The electronic device of claim 19, further comprising at least one of a processor, a memory, and a power module.
